(19) United States
(12) Patent Application Publication
(10) Pub. No.: US 2024/0153972 A1
(43) Pub. Date: May 9, 2024

(54) IMAGING DEVICE AND MANUFACTURING METHOD THEREOF

(71) Applicant: Panasonic Intellectual Property Management Co., Ltd., Osaka (JP)

(72) Inventor: TAIJI NODA, Osaka (JP)

(21) Appl. No.: 18/542,603

(22) Filed: Dec. 16, 2023

Related U.S. Application Data
(63) Continuation of application No. PCT/JP2022/024463, filed on Jun. 20, 2022.

(30) Foreign Application Priority Data
Jun. 30, 2021 (JP) 2021-108981

(51) Int. Cl. H01L 27/146

(52) U.S. Cl. CPC H01L 27/14616; H01L 27/14683

(57) ABSTRACT

An imaging device includes a pixel region and a first peripheral region. The pixel region includes a pixel substrate portion and a pixel transistor. The pixel transistor is positioned in the pixel substrate portion. The first peripheral region includes a first peripheral substrate portion and at least one first peripheral transistor. The at least one first peripheral transistor is positioned in the first peripheral substrate portion. Signals are communicated between the pixel region and the first peripheral region. The at least one first peripheral transistor includes a first specific layer. The first specific layer is positioned in the first peripheral substrate portion. The first specific layer contains a heavy conductive impurity that is a p-type impurity having an atomic number greater than or equal to that of gallium or that is an n-type impurity having an atomic number greater than or equal to that of arsenic.

### BACKGROUND

### 1. Technical Field

The present disclosure relates to an imaging device and a manufacturing method thereof.

### 2. Description of the Related Art

Image sensors are used in digital cameras and the like. Such image sensors include a charge coupled device (CCD) image sensor and a complementary metal oxide semiconductor (CMOS) image sensor.

In an image sensor according to one example, a photodiode is provided in a semiconductor substrate. In an image sensor according to another example, a photoelectric conversion layer is provided above a semiconductor substrate.

In an imaging device according to a specific example, signal charges are generated by photoelectric conversion. The generated charges are stored in a charge storage node. A signal corresponding to the amount of charges stored in the charge storage node is read through a CCD circuit or a CMOS circuit formed on a semiconductor substrate.

Japanese Unexamined Patent Application Publication No. 2019-24075 describes an imaging device. The imaging device described in Japanese Unexamined Patent Application Publication No. 2019-24075 includes a pixel region and a peripheral region. Examples of transistors are described in Japanese Patent Nos. 5235486 and 3426573 and Journal of Applied Physics, vol. 88 no. 9 pp. 4980-4984 (2000).

### SUMMARY

In one general aspect, the techniques disclosed here feature an imaging device including: a pixel region including a pixel substrate portion and a pixel transistor positioned in the pixel substrate portion; and a first peripheral region that includes a first peripheral substrate portion and at least one first peripheral transistor positioned in the first peripheral substrate portion, and that communicates a signal with the pixel region. The at least one first peripheral transistor includes a first specific layer positioned in the first peripheral substrate portion. The first specific layer contains a heavy conductive impurity that is a p-type impurity having an atomic number greater than or equal to an atomic number of gallium or that is an n-type impurity having an atomic number greater than or equal to an atomic number of arsenic.

It should be noted that general or specific embodiments may be implemented as a system, a method, an integrated circuit, a computer program, a storage medium, or any selective combination thereof.

Additional benefits and advantages of the disclosed embodiments will become apparent from the specification and drawings. The benefits and/or advantages may be individually obtained by the various embodiments and features of the specification and drawings, which need not all be provided in order to obtain one or more of such benefits and/or advantages.

### BRIEF DESCRIPTION OF THE DRAWINGS

FIG. 1 is a diagram schematically illustrating an exemplary configuration of an imaging device according to Embodiment 1;

FIG. 2 is a diagram schematically illustrating an exemplary circuit configuration of the imaging device;

FIG. 3 is a schematic sectional view illustrating a pixel region, a peripheral region, and a blocking region positioned therebetween;

FIG. 4 is a schematic plan view illustrating another example of the shape of the blocking region;

FIG. 5 is a sectional view illustrating a transistor according to a first configuration example;

FIG. 6 is a sectional view illustrating a transistor according to a first modification of the first configuration example;

FIG. 7 is a sectional view illustrating a transistor according to a second modification of the first configuration example;

FIG. 8 is a graph illustrating an impurity concentration profile in a region along a straight line extending in a depth direction of a semiconductor substrate through a source diffusion layer according to a third modification of the first configuration example;

FIGS. 9A to 9E are sectional views illustrating a method for manufacturing a transistor according to the first configuration example;

FIGS. 10A to 10D are sectional views illustrating the method for manufacturing a transistor according to the first configuration example;

FIGS. 11A to 11C are sectional views illustrating the method for manufacturing a transistor according to the first configuration example;

FIGS. 12A and 12B are graphs illustrating an impurity concentration profile in a region along a straight line extending in the depth direction of the semiconductor substrate through an extension formation region according to the first configuration example;

FIG. 13 is a schematic plan view illustrating a transistor in a pixel region and a transistor in a peripheral region;

FIG. 14 is a schematic plan view illustrating the transistor in the pixel region and the transistor in the peripheral region;

FIG. 15 is a schematic plan view illustrating the transistor in the pixel region and the transistor in the peripheral region;

FIG. 16 is a schematic plan view illustrating the transistor in the pixel region and the transistor in the peripheral region;

FIG. 17 is a schematic plan view illustrating the transistor in the pixel region and the transistor in the peripheral region;

FIG. 18 is a schematic plan view illustrating the transistor in the pixel region and transistors in peripheral regions;

FIG. 19 is a schematic plan view illustrating the transistor in the pixel region and the transistors in the peripheral regions;

FIG. 20 is a schematic plan view illustrating the transistor in the pixel region and the transistors in the peripheral regions;

FIG. 21 is a schematic plan view illustrating the transistor in the pixel region and the transistors in the peripheral regions;

FIG. 22 is a schematic plan view illustrating the transistor in the pixel region and the transistors in the peripheral regions;

FIG. 23 is a schematic plan view illustrating the transistor in the pixel region and the transistors in the peripheral regions;

FIG. 24 is a schematic plan view illustrating the transistor in the pixel region and the transistors in the peripheral regions;

FIG. 25 is a schematic diagram of a back side illumination imaging device;

FIG. 26 is a schematic diagram of a back side illumination imaging device;

FIG. 27 is a schematic diagram of a back side illumination imaging device;

FIG. 28 is a schematic diagram illustrating possible shapes of a pixel region and peripheral regions of the imaging device;

FIG. 29 is a schematic diagram illustrating possible shapes of the pixel region and peripheral regions of the imaging device;

FIG. 30 is a schematic diagram illustrating possible shapes of the pixel region and peripheral regions of the imaging device;

FIG. 31 is a schematic diagram illustrating possible shapes of the pixel region and peripheral regions of the imaging device;

FIG. 32 is a schematic diagram of a stacked-chip imaging device;

FIG. 33 is a diagram schematically illustrating an exemplary configuration of an imaging device according to Embodiment 2;

FIG. 34 is a schematic sectional view illustrating a pixel region, a peripheral region, and a blocking region;

FIG. 35 is a schematic plan view illustrating another example of the shape of the blocking region;

FIG. 36 is a schematic perspective view illustrating a transistor in the pixel region and a transistor in the peripheral region;

FIG. 37 is a schematic perspective view illustrating the transistor in the pixel region and the transistor in the peripheral region;

FIG. 38 is a schematic perspective view illustrating the transistor in the pixel region and transistors in the peripheral region;

FIG. 39 is a schematic perspective view illustrating the transistor in the pixel region and transistors in the peripheral region;

FIG. 40 is a schematic perspective view illustrating the transistor in the pixel region and transistors in peripheral regions;

FIG. 41 is a schematic perspective view illustrating the transistor in the pixel region and transistors in the peripheral regions;

FIG. 42 is a schematic perspective view illustrating the transistor in the pixel region and transistors in peripheral regions;

FIG. 43 is a schematic perspective view illustrating the transistor in the pixel region and transistors in the peripheral regions;

FIG. 44 is a schematic diagram of a back side illumination imaging device;

FIG. 45 is a schematic diagram of a back side illumination imaging device;

FIG. 46 is a schematic diagram of a back side illumination imaging device;

FIG. 47 is a schematic diagram illustrating possible shapes of a pixel region and peripheral regions of the imaging device;

FIG. 48 is a schematic diagram illustrating possible shapes of the pixel region and peripheral regions of the imaging device;

FIG. 49 is a schematic diagram illustrating possible shapes of the pixel region and peripheral regions of the imaging device;

FIG. 50 is a schematic diagram illustrating possible shapes of the pixel region and peripheral regions of the imaging device;

FIG. 51 is a schematic diagram illustrating possible shapes of a pixel region and peripheral regions of an imaging device;

FIG. 52A is a schematic sectional view of an imaging device according to a specific example;

FIG. 52B is a schematic perspective view of the imaging device according to the specific example;

FIG. 53A is a schematic sectional view of an imaging device according to a specific example;

FIG. 53B is a schematic perspective view of the imaging device according to the specific example;

FIG. 54A is a schematic sectional view of an imaging device according to a specific example;

FIG. 54B is a schematic perspective view of the imaging device according to the specific example;

FIG. 55A is a schematic sectional view of an imaging device according to a specific example;

FIG. 55B is a schematic perspective view of the imaging device according to the specific example;

FIG. 56A is a schematic sectional view of an imaging device according to a specific example; and

FIG. 56B is a schematic perspective view of the imaging device according to the specific example.

### DETAILED DESCRIPTIONS

### Summary of One Aspect According to Present Disclosure

An imaging device according to a first aspect of the present disclosure includes:
a pixel region including a pixel substrate portion and a pixel transistor positioned in the pixel substrate portion; and
a first peripheral region that includes a first peripheral substrate portion and at least one first peripheral transistor positioned in the first peripheral substrate portion, and that communicates a signal with the pixel region. The at least one first peripheral transistor includes a first specific layer positioned in the first peripheral substrate portion. The first specific layer contains a heavy conductive impurity that is a p-type impurity having an atomic number greater than or equal to an atomic number of gallium or that is an n-type impurity having an atomic number greater than or equal to an atomic number of arsenic.

The technique according to the first aspect is suitable for improving the performance of the imaging device. The heavy conductive impurity may be a p-type impurity having an atomic number greater than or equal to that of gallium or an n-type impurity having an atomic number greater than or equal to that of antimony.

For example, in a second aspect of the imaging device according to the first aspect,
a concentration profile of the heavy conductive impurity in a region along a straight line extending in a depth direction of the first peripheral substrate portion through the first specific layer may have a peak at a position deeper than an upper surface of the first peripheral substrate portion.

The technique according to the second aspect is suitable for improving the performance of the imaging device.

For example, in a third aspect of the imaging device according to the first or second aspect,
the first peripheral substrate portion may include
   a support substrate and
   a film body positioned above the support substrate,
the film body may include
   the first specific layer and
   a low-concentration layer that is positioned above the first specific layer, that has an upper surface of the film body, and that has a conductive impurity concentration lower than a conductive impurity concentration of the support substrate, and
the at least one first peripheral transistor may include the low-concentration layer and the first specific layer in sequence from top to bottom.

The technique according to the third aspect is suitable for improving the performance of the imaging device.

For example, in a fourth aspect of the imaging device according to any one of the first to third aspects,
the heavy conductive impurity may contain at least one selected from the group consisting of gallium, indium, antimony, and bismuth.

Gallium, indium, antimony, and bismuth are examples of a heavy conductive impurity.

For example, in a fifth aspect of the imaging device according to any one of the first to fourth aspects,
the at least one first peripheral transistor and the pixel transistor each may include a gate, and
a gate length of the at least one first peripheral transistor may be shorter than a gate length of the pixel transistor.

The configuration according to the fifth aspect is a configuration example of the imaging device.

For example, in a sixth aspect of the imaging device according to any one of the first to fifth aspects,
the pixel transistor may include a pixel gate insulating film,
the at least one first peripheral transistor may include a first peripheral gate insulating film, and
the first peripheral gate insulating film may be thinner than the pixel gate insulating film.

The configuration according to the sixth aspect is a configuration example of the imaging device.

For example, in a seventh aspect of the imaging device according to any one of the first to sixth aspects,
the at least one first peripheral transistor may include a gate, a channel region positioned below the gate, a first source, a first drain, a first extension diffusion layer, and a first pocket diffusion layer,
the first extension diffusion layer may be adjacent to the first source or the first drain and may be shallower than the first source and the first drain,
the first pocket diffusion layer may be adjacent to the first source or the first drain, and
at least one selected from the group consisting of the channel region, the first extension diffusion layer, the first pocket diffusion layer, the first source, and the first drain may include the first specific layer.

The configuration according to the seventh aspect is a configuration example of the imaging device.

For example, in an eighth aspect of the imaging device according to any one of the first to seventh aspects,
the first specific layer may contain at least one selected from the group consisting of carbon, nitrogen, and fluorine.

For example, in a ninth aspect of the imaging device according to any one of the first to eighth aspects,
the first specific layer may contain at least one selected from the group consisting of germanium, silicon, and argon.

For example, in a tenth aspect of the imaging device according to any one of the first to ninth aspects,
the pixel region may include a charge storage region being an impurity region that stores a charge generated by photoelectric conversion,
the pixel transistor may include a gate and a channel region positioned below the gate, and
a concentration of carbon in the first specific layer may be higher than a concentration of carbon in the charge storage region or a concentration of carbon in the channel region.

The feature of the tenth aspect can be possessed by a high-performance imaging device.

For example, in an eleventh aspect of the imaging device according to any one of the first to tenth aspects,
the first specific layer may include an end-of-range defect.

The end-of-range defect of the eleventh aspect can segregate the heavy conductive impurity.

For example, in a twelfth aspect of the imaging device according to any one of the first to eleventh aspects,
the first specific layer may include a first segregation portion in which the heavy conductive impurity is segregated in a depth direction of the first peripheral substrate portion,
the pixel region may include a charge storage region being an impurity region that stores a charge generated by photoelectric conversion, and
the first segregation portion may be shallower than the charge storage region.

The configuration according to the twelfth aspect is a configuration example of the imaging device.

For example, in a thirteenth aspect of the imaging device according to any one of the first to twelfth aspects,
the at least one first peripheral transistor may include two first peripheral transistors,
the first peripheral region may include a shallow trench isolation structure,
the shallow trench isolation structure may isolate the two first peripheral transistors,
the shallow trench isolation structure may have a trench, and
a range in which the heavy conductive impurity is distributed in the first specific layer of at least one of the two first peripheral transistors may be a range shallower than a bottom of the trench.

The configuration according to the thirteenth aspect is a configuration example of the imaging device.

For example, in a fourteenth aspect of the imaging device according to any one of the first to thirteenth aspects,
the pixel transistor may include a gate, a channel region positioned below the gate, and a pixel specific layer that is positioned in the pixel substrate portion and that contains the heavy conductive impurity, and
the channel region may include the pixel specific layer.

The configuration according to the fourteenth aspect is suitable for improving the performance of the imaging device.

For example, in a fifteenth aspect of the imaging device according to any one of the first to fourteenth aspects,
the imaging device may further include:
a second peripheral region including a second peripheral substrate portion and a second peripheral transistor positioned in the second peripheral substrate portion, in which
the signal may be communicated between the first peripheral region and the pixel region through the second peripheral region,
the at least one first peripheral transistor may include a first source, a first drain, and a first extension diffusion layer,
the first extension diffusion layer may be adjacent to the first source or the first drain and may be shallower than the first source and the first drain,
the second peripheral transistor may include a second source, a second drain, and a second extension diffusion layer,
the second extension diffusion layer may be adjacent to the second source or the second drain and may be shallower than the second source and the second drain,
a concentration of a conductive impurity in the second extension diffusion layer may be lower than a concentration of a conductive impurity in the first extension diffusion layer,
the second extension diffusion layer may be deeper than the first extension diffusion layer,
the at least one first peripheral transistor, the second peripheral transistor, and the pixel transistor each may include a gate,
a gate length of the at least one first peripheral transistor may be shorter than a gate length of the second peripheral transistor, and
a gate length of the pixel transistor may be longer than the gate length of the second peripheral transistor.

The configuration according to the fifteenth aspect is a configuration example of the imaging device.

For example, in a sixteenth aspect of the imaging device according to the fifteenth aspect,
the pixel transistor may further include a channel region positioned below the gate of the pixel transistor,
the second peripheral transistor may further include a second specific layer that is positioned in the second peripheral substrate portion and that contains a conductive impurity,
when at least one type of impurity that suppresses transient enhanced diffusion of the conductive impurity is defined as a diffusion suppression type,
the diffusion suppression type may include at least one selected from the group consisting of carbon, nitrogen, and fluorine,
a concentration of the diffusion suppression type in the first specific layer may be higher than a concentration of the diffusion suppression type in the second specific layer, and
a concentration of carbon in the second specific layer may be higher than a concentration of carbon in the channel region of the pixel transistor.

The configuration according to the sixteenth aspect is a configuration example of the imaging device.

For example, in a seventeenth aspect of the imaging device according to the fifteenth aspect,
the second peripheral transistor may further include a channel region positioned below the gate of the second peripheral transistor, a second pocket diffusion layer, and a second specific layer that is positioned in the second peripheral substrate portion and that contains the heavy conductive impurity,
the second peripheral transistor may be an N-channel transistor, and
at least one selected from the group consisting of the channel region, the second extension diffusion layer, the second pocket diffusion layer, the second source, and the second drain of the second peripheral transistor may include the second specific layer.

The configuration according to the seventeenth aspect is a configuration example of the imaging device.

For example, in an eighteenth aspect of the imaging device according to any one of the fifteenth to seventeenth aspects,
the at least one first peripheral transistor may further include a first peripheral gate insulating film,
the second peripheral transistor may further include a second peripheral gate insulating film,
the first peripheral gate insulating film may be thinner than the second peripheral gate insulating film,
the pixel transistor may further include a pixel gate insulating film, and
the pixel gate insulating film may be thicker than the second peripheral gate insulating film.

The configuration according to the eighteenth aspect is a configuration example of the imaging device.

For example, in a nineteenth aspect of the imaging device according to any one of the first to eighteenth aspects,
the first peripheral region may be positioned outside the pixel region,
the pixel substrate portion and the first peripheral substrate portion may be included in a single semiconductor substrate,
the at least one first peripheral transistor may be a load transistor, and
the pixel region may be connected to the load transistor through a vertical signal line.

The configuration according to the nineteenth aspect is a configuration example of the imaging device.

For example, in a twentieth aspect of the imaging device according to any one of the first to nineteenth aspects,
the pixel substrate portion and the first peripheral substrate portion may be stacked on each other.

The configuration according to the twentieth aspect is a configuration example of the imaging device.

For example, a method for manufacturing an imaging device according to a twenty-first aspect of the present disclosure is a method for manufacturing the imaging device according to any one of the first to twentieth aspects, in which the method may include
forming a film body by epitaxial growth; and
forming the first specific layer by implanting the heavy conductive impurity into the film body.

The manufacturing method according to the twenty-first aspect is an example of the method for manufacturing an imaging device.

An imaging device according to a twenty-second aspect of the present disclosure includes:
a support substrate;
a film body positioned above the support substrate; and
a pixel transistor, in which
the film body includes
   a low-concentration layer including an upper surface of the film body and having a conductive impurity concentration lower than a conductive impurity concentration of the support substrate, and
   a conductive impurity layer that is positioned below the low-concentration layer and that contains a conductive impurity,
the pixel transistor includes the low-concentration layer and the conductive impurity layer in sequence from top to bottom, and
a concentration profile of the conductive impurity in a region along a straight line extending in a depth direction of the film body through the low-concentration layer and the conductive impurity layer has a peak at a position deeper than the upper surface of the film body.

The technique according to the twenty-second aspect is suitable for improving the performance of the imaging device.

For example, in a twenty-third aspect of the imaging device according to the twenty-second aspect,
the conductive impurity layer may contain a heavy conductive impurity that is a p-type impurity an atomic number of which is equal to or greater than an atomic number of gallium or that is an n-type impurity an atomic number of which is equal to or greater than an atomic number of arsenic.

The configuration according to the twenty-third aspect is a configuration example of the imaging device. The heavy conductive impurity may be a p-type impurity having an atomic number greater than or equal to that of gallium or an n-type impurity having an atomic number greater than or equal to that of antimony.

For example, a method for manufacturing an imaging device according to a twenty-fourth aspect of the present disclosure is a method for manufacturing the imaging device according to the twenty-second or twenty-third aspect, in which the method may include:
forming the film body by epitaxial growth; and
forming the conductive impurity layer by implanting the conductive impurity into the film body.

The manufacturing method according to the twenty-fourth aspect is an example of the method for manufacturing an imaging device.

In the imaging device according to any one of the above aspects,
when at least one type of impurity that suppresses transient enhanced diffusion of the conductive impurity is defined as a diffusion suppressing type,
the first specific layer may contain the diffusion-suppressing type.

In the imaging device according to any one of the above aspects,
when at least one type of impurity that causes amorphization of the implanted region is defined as an amorphization type,
the first specific layer may contain the amorphization type, and
the amorphization type may include at least one selected from the group consisting of germanium, silicon, and argon.

In the imaging device according to any one of the above aspects,
the pixel region may include a photoelectric conversion layer stacked on the pixel substrate portion.

In the imaging device according to any one of the above aspects,
the pixel region may include a photodiode.

In the imaging device according to any one of the above aspects,
the second extension diffusion layer may contain nitrogen.

An imaging device according to one aspect of the present disclosure includes:
a pixel region including a pixel substrate portion and at least one pixel transistor positioned in the pixel substrate portion; and
a first peripheral region that includes a first peripheral substrate portion and at least one first peripheral transistor positioned in the first peripheral substrate portion and that communicates a signal with the pixel region, in which
the at least one first peripheral transistor includes a first specific layer that is located in the first peripheral substrate portion and that contains at least one selected from the group consisting of gallium, indium, antimony, and bismuth.

The techniques according to the first to twenty-fourth aspects may be combined as appropriate unless there is any inconsistency.

Hereinafter, embodiments of the present disclosure will be described in detail with reference to the drawings. Noted that the embodiments described below are intended to represent comprehensive or specific examples. Numerical values, shapes, materials, constituent elements, the arrangement and connection of the constituent elements, steps, the order of the steps, and the like described in the following embodiments are mere examples and not intended to limit the present disclosure. Various aspects described herein can be combined with each other unless there is any inconsistency. Among the constituent elements in the following embodiments, constituent elements that are not described in independent claims representing the highest concept will be described as optional constituent elements.

In the following description, constituent elements having substantially the same functions are denoted by common reference numerals, and description thereof may be omitted. Some elements may be omitted to avoid over-complicating the drawings. Regarding various elements of the imaging device, the dimensions, appearance, and the like illustrated in the drawings may differ from the dimensions and appearance of an actual imaging device. That is, the accompanying drawings are merely schematic diagrams for understanding the present disclosure, and do not necessarily strictly reflect the scale and the like of an actual imaging device.

A “plan view” as used herein refers to a view seen in a direction perpendicular to a semiconductor substrate, a first semiconductor substrate, a second semiconductor substrate, a third semiconductor substrate, a pixel substrate portion, a first peripheral substrate portion or a second peripheral substrate portion. In this specification, terms such as “upper”, “lower”, “upper surface”, and “lower surface” are used only to specify the mutual arrangement between members, and not intended to limit the posture when the imaging device is in use.

In this specification, the expression “substrate” may be used such as a “support substrate” and a “semiconductor substrate”. The structure and manufacturing method of the substrate are not particularly limited. The substrate may have a single layer structure or a laminate structure. The laminate structure may include a semiconductor layer, an insulating layer, and the like, for example. The substrate may be a wafer obtained by slicing an ingot, a film deposited by sputtering or the like, or a film grown by epitaxial growth. The substrate can be a plate-like body used in a chip stack structure. The substrate may also be a plate-like body used in a laminate structure manufactured by 3D sequential integration (3DSI), which is a three-dimensional lamination technique. A “depth direction of the substrate” can be read as “a thickness direction of the substrate”.

In this specification, an extension diffusion layer is a concept including a so-called lightly doped drain (LDD) diffusion layer.

In this specification, a “threshold voltage of a transistor” refers to a voltage between a gate and a source of the transistor when a drain current starts to flow through the transistor.

In this specification, there is an expression “a gate length of a peripheral transistor is shorter than a gate length of a pixel transistor”. In this expression, “at least one” can be supplemented such that the gate length of at least one peripheral transistor is shorter than the gate length of at least one pixel transistor. In this supplemented expression, it is not essential that all peripheral transistors and pixel transistors in the imaging device satisfy this magnitude relationship. The same applies to the expressions related to the magnitude relationship of the dimensions of other elements. The same applies to the magnitude relationship of the concentration of impurities such as carbon. The same applies to the magnitude relationship between the elements of the first peripheral transistor and the second peripheral transistor.

In this specification, there is an expression “concentration of a conductive impurity”. When the conductive impurity includes a plurality of types of impurities, the concentration of the conductive impurity refers to a total concentration of the plurality of types of impurities. The same applies to the concentrations of a heavy conductive impurity, a diffusion suppression type, an amorphization type, and the like.

### Embodiment 1

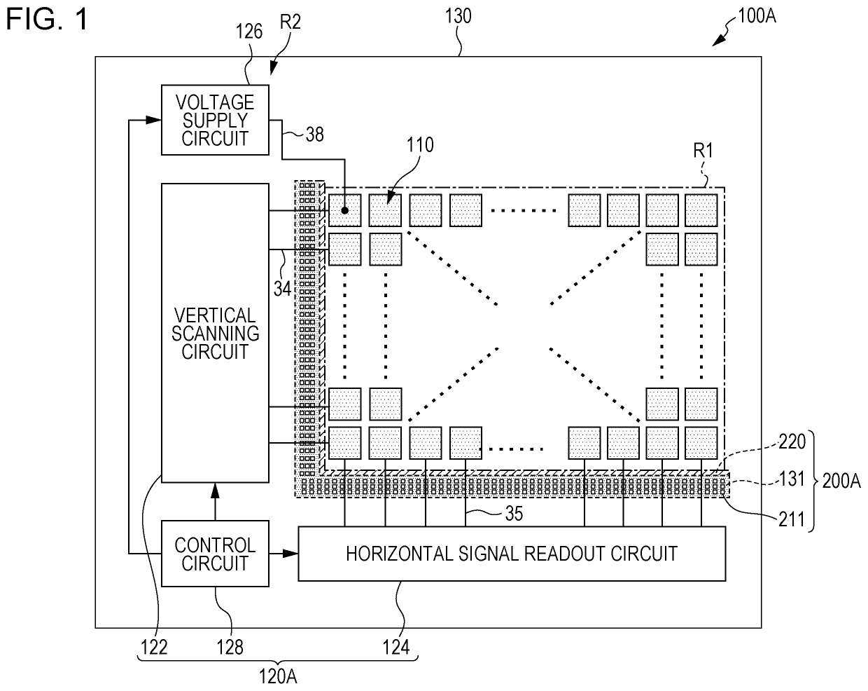

Embodiment 1 of the present disclosure will be described below with reference to FIGS. 1 to 32.

FIG. 1 schematically illustrates an exemplary configuration of an imaging device 100A according to Embodiment 1 of the present disclosure. The imaging device 100A illustrated in FIG. 1 includes a plurality of pixels 110 arranged in a plurality of rows and columns, for example. In the configuration illustrated in FIG. 1, the pixels 110 are arranged in m rows and n columns to form a substantially rectangular pixel region R1. Here, m and n independently represent an integer of 1 or more.

In Embodiment 1, the plurality of pixels 110 each include a photoelectric converter and a readout circuit. The photoelectric converter is supported by a semiconductor substrate 130. The readout circuit is formed on the semiconductor substrate 130 and electrically connected to the photoelectric converter. The plurality of pixels 110 each include an impurity region provided in the semiconductor substrate 130. The impurity region functions as part of a charge storage region that temporarily holds signal charges generated by the photoelectric converter. Instead of providing such a photoelectric converter, a photodiode may be provided in the semiconductor substrate as the photoelectric converter.

The imaging device 100A further includes a peripheral circuit 120A. The peripheral circuit 120A drives the plurality of pixels 110. In the example illustrated in FIG. 1, the peripheral circuit 120A includes a vertical scanning circuit 122, a horizontal signal readout circuit 124, a voltage supply circuit 126, and a control circuit 128. In Embodiment 1, part or all of these circuits are formed on the semiconductor substrate 130 in the same manner as the readout circuit of each pixel. As schematically illustrated in FIG. 1, the peripheral circuit 120A is located in a first peripheral region R2 of the semiconductor substrate 130. The first peripheral region R2 is positioned outside the pixel region R1 including the plurality of pixels 110.

The imaging device 100A further includes a blocking region 200A. The blocking region 200A is provided between the pixel region R1 and the first peripheral region R2. As schematically illustrated in FIG. 1, the blocking region 200A includes an impurity region 131 and a plurality of contact plugs 211. The impurity region 131 is provided in the semiconductor substrate 130. The plurality of contact plugs 211 are provided on the impurity regions 131. The impurity region 131 is typically a p-type diffusion region.

The plurality of contact plugs 211 are electrically connected to the impurity region 131 by being provided on the impurity region 131. As will be described later, the plurality of contact plugs 211 are configured to be able to supply a predetermined voltage to the impurity region 131 through connection with a power source (not illustrated in FIG. 1). That is, when the imaging device 100A is in operation, the impurity region 131 is in a state where a predetermined voltage is applied thereto through the contact plugs 211.

The blocking region 200A also has an element isolation 220. The element isolation 220 is a structure formed in the semiconductor substrate 130 by a shallow trench isolation (STI) process, for example. The element isolation 220 has at least a portion of the semiconductor substrate 130 located between the pixels positioned at the outermost periphery of the pixel region R1 among the plurality of pixels 110 and a digital circuit such as the vertical scanning circuit 122 that operates based on a digital clock. Here, the element isolation 220 is located between the pixels 110 positioned at the outermost periphery of the pixel region R1 and the vertical scanning circuit 122 and between the pixels 110 positioned at the outermost periphery of the pixel region R1 and the horizontal signal readout circuit 124. As will be described later, the element isolation 220 can be provided in the semiconductor substrate 130 so as to surround the pixel region R1 when viewed from above. The element isolation 220 corresponds to a shallow trench isolation structure in the present disclosure.

In a configuration in which a peripheral circuit including a circuit that operates based on a digital clock is formed on a semiconductor substrate provided with an impurity region that temporarily holds signal charges obtained by photoelectric conversion, the circuit that operates based on the digital clock can be a noise source that generates noise at each rise and fall of an input pulse. More specifically, the potential of a signal line that supplies a digital clock to a digital circuit represented by a CMOS logic circuit varies according to the digital clock. Such variation in the potential of the signal line caused by the digital clock changes the substrate potential, possibly resulting in a factor causing unnecessary charges to be generated in wells inside the semiconductor substrate. When such unnecessary charges due to the variation in the substrate potential flow into the impurity region in the pixel that holds the signal charge, an SNR is reduced, causing degradation of an image to be obtained.

In the imaging device 100A illustrated in FIG. 1, on the other hand, the blocking region 200A is disposed between the pixel region R1 including the plurality of pixels 110 and the digital circuit. The blocking region 200A includes the impurity region 131 configured to be connectable to the power source such as the ground by providing the plurality of contact plugs 211. When the imaging device 100A is in operation, the potential of the impurity region 131 in the blocking region 200A can be fixed by connecting a predetermined voltage source to the plurality of contact plugs 211. The potential of the impurity region 131 in the blocking region 200A can be grounded through the plurality of contact plugs 211, for example. In this event, the blocking region 200A functions as a low-impedance path for discharging unnecessary charges generated inside the semiconductor substrate 130. That is, electrostatic coupling between the impurity region in the pixel holding the signal charges and the peripheral circuit 120A can be suppressed, making it possible to advantageously suppress a dark current with a signal line supplying a digital clock as a noise source. Note, however, that the blocking region 200A is not essential.

Here, each of the circuits included in the peripheral circuit 120A will be described in detail. The vertical scanning circuit 122 has connections with a plurality of address signal lines 34. These address signal lines 34 are provided corresponding to each row of the plurality of pixels 110. Each address signal line 34 is connected to one or more pixels belonging to each corresponding row. The vertical scanning circuit 122 controls the timing to read a signal from the pixel 110 to a vertical signal line 35 to be described later by applying a row selection signal to the address signal line 34. The vertical scanning circuit 122 is also called a row scanning circuit. Signal lines connected to the vertical scanning circuit 122 are not limited to the address signal lines 34. A plurality of types of signal lines can be connected to the vertical scanning circuit 122 for each row of the plurality of pixels 110.

As schematically illustrated in FIG. 1, the imaging device 100A also includes a plurality of vertical signal lines 35. The vertical signal line 35 is provided for each column of the plurality of pixels 110. Each vertical signal line 35 is connected to one or more pixels belonging to each corresponding column. These vertical signal lines 35 are connected to the horizontal signal readout circuit 124. The horizontal signal readout circuit 124 sequentially outputs signals read out from the pixels 110 to output lines (not illustrated in FIG. 1). The horizontal signal readout circuit 124 is also called a column scanning circuit.

The control circuit 128 receives command data, clocks, and the like given from outside of the imaging device 100A, for example, to control the whole imaging device 100A. The control circuit 128 typically has a timing generator to supply drive signals to the vertical scanning circuit 122, the horizontal signal readout circuit 124, the voltage supply circuit 126 to be described later, and the like. Arrows extending from the control circuit 128 in FIG. 1 schematically represent the flows of output signals from the control circuit 128. The control circuit 128 may be implemented by a microcontroller including one or more processors, for example. The functions of the control circuit 128 may be implemented by a combination of a general-purpose processing circuit and software, or by specialized hardware for such processing.

In Embodiment 1, the peripheral circuit 120A includes the voltage supply circuit 126 electrically connected to each pixel 110 in the pixel region R1. The voltage supply circuit 126 supplies a predetermined voltage to the pixel 110 through a voltage line 38. The voltage supply circuit 126 is not limited to a specific power supply circuit, but may be a circuit that converts a voltage supplied from a power source such as a battery into a predetermined voltage, or a circuit that generates a predetermined voltage. The voltage supply circuit 126 may be part of the vertical scanning circuit 122 described above. As schematically illustrated in FIG. 1, these circuits included in the peripheral circuit 120A are disposed in the first peripheral region R2 outside the pixel region R1.

Note that the number and arrangement of the pixels 110 are not limited to those in the example illustrated in FIG. 1. For example, the number of the pixels 110 included in the imaging device 100A may be one. In this example, the center of each pixel 110 is positioned at a lattice point of a square lattice. Alternatively, the plurality of pixels 110 may be disposed, for example, such that the center of each pixel 110 is positioned at a lattice point of a triangular lattice, hexagonal lattice or the like. The pixels 110 may be arranged one-dimensionally, for example. In this case, the imaging device 100A can be used as a line sensor.

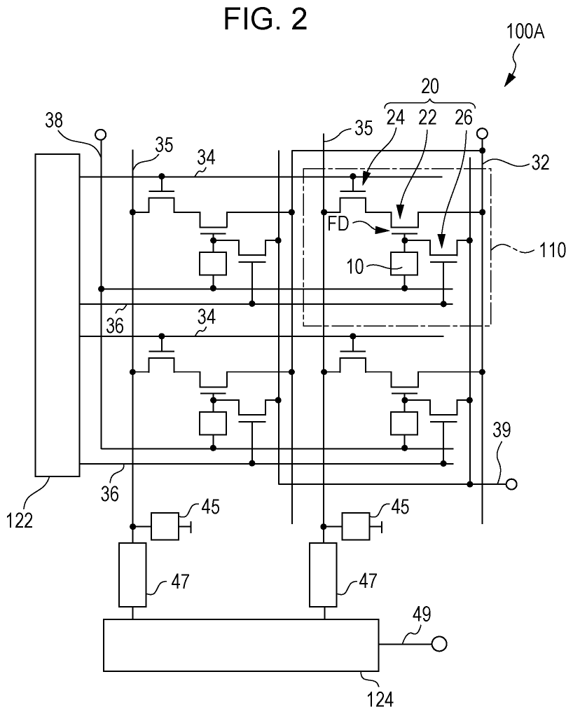

FIG. 2 schematically illustrates an exemplary circuit configuration of the imaging device 100A illustrated in FIG. 1. In FIG. 2, four pixels 110 arranged in two rows and two columns are extracted and illustrated from among the plurality of pixels 110, in order to avoid overcomplicating the drawing. Each of these pixels 110 includes a photoelectric converter 10 supported by the semiconductor substrate 130 and a readout circuit 20 electrically connected to the photoelectric converter 10. As will be described in detail later with reference to the drawings, the photoelectric converter 10 includes a photoelectric conversion layer disposed above the semiconductor substrate 130. The photoelectric converter 10 can also be referred to as a photoelectric conversion structure.

The photoelectric converter 10 of each pixel 110 is connected to the voltage line 38 connected to the voltage supply circuit 126, so that a predetermined voltage can be applied thereto through the voltage line 38 when the imaging device 100A is in operation. For example, when positive charges among the positive and negative charges generated by photoelectric conversion are used as signal charges, a positive voltage of about 10 V, for example, can be applied to the voltage line 38 when the imaging device 100A is in operation. A case where holes are used as signal charges will be described below.

In the configuration illustrated in FIG. 2, the readout circuit 20 includes an amplifier transistor 22, an address transistor 24, and a reset transistor 26. The amplifier transistor 22, address transistor 24, and reset transistor 26 are typically field effect transistors formed on the semiconductor substrate 130. Hereinafter, unless otherwise specified, an example using an N-channel metal oxide semiconductor field effect transistor (MOSFET) as a transistor will be described.

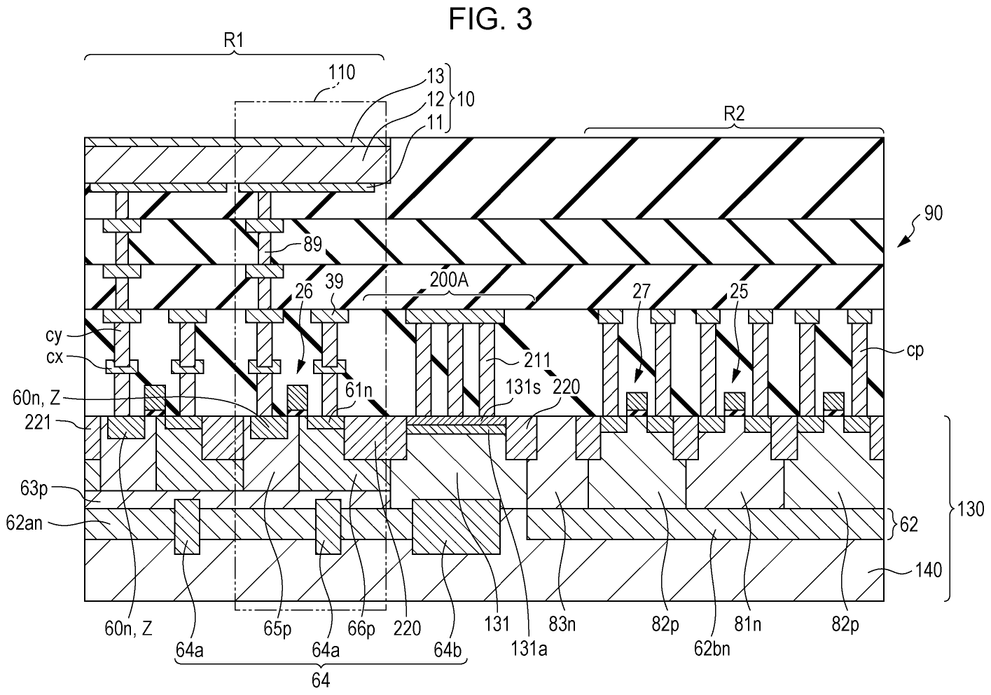

As schematically illustrated in FIG. 2, the amplifier transistor 22 has its gate electrically connected to the photoelectric converter 10. By applying a predetermined voltage from the voltage supply circuit 126 to the photoelectric converter 10 of each pixel 110 through the voltage line 38 during operation, holes, for example, can be stored in a charge storage node FD as signal charges. Here, the charge storage node FD is a node that connects the gate of the amplifier transistor 22 to the photoelectric converter 10. The charge storage node FD has a function of temporarily holding charges generated by the photoelectric converter 10. The charge storage node FD partially includes the impurity region formed in semiconductor substrate 130. Reference numeral Z in FIG. 3 to be described later corresponds to the impurity region included in the charge storage node FD.

As illustrated in FIG. 2, the amplifier transistor 22 of each pixel 110 has its drain connected to a power supply wiring 32. The power supply wiring 32 supplies a power supply voltage VDD to the amplifier transistor 22 when the imaging device 100A is in operation. The power supply voltage VDD is, for example, about 3.3 V. The amplifier transistor 22 has its source, on the other hand, connected to the vertical signal line 35 through the address transistor 24. The amplifier transistor 22 receives the power supply voltage VDD supplied at its drain and thus outputs a signal voltage corresponding to the amount of signal charges stored in the charge storage node FD.

The address transistor 24 is connected between the amplifier transistor 22 and the vertical signal line 35. The address transistor 24 has its gate connected to the address signal line 34. The vertical scanning circuit 122 controls on and off of the address transistor 24 by applying a row selection signal to the address signal line 34. More specifically, the vertical scanning circuit 122 can read the output from the amplifier transistor 22 of the selected pixel 110 to the corresponding vertical signal line 35 by controlling the row selection signal. The address transistor 24 is not limited to the example illustrated in FIG. 2, but may be disposed between the drain of the amplifier transistor 22 and the power supply wiring 32.

A load circuit 45 and a column signal processing circuit 47 are connected to each of the vertical signal lines 35. The load circuit 45 forms a source follower circuit together with the amplifier transistor 22. The column signal processing circuit 47 performs noise suppression signal processing, analog-to-digital conversion, and the like. The noise suppression signal processing is, for example, correlated double sampling. The column signal processing circuit 47 is also called a row signal storage circuit. The horizontal signal readout circuit 124 sequentially reads signals from the plurality of column signal processing circuits 47 to a horizontal common signal line 49. The column signal processing circuit 47 may be part of the horizontal signal readout circuit 124. The load circuit 45 and the column signal processing circuit 47 may be part of the peripheral circuit 120A described above.

In this example, the readout circuit 20 includes the reset transistor 26 in addition to the amplifier transistor 22 and the address transistor 24. One of the drain and source of the reset transistor 26 is part of the charge storage node FD. The other of the drain and source is connected to a reset voltage line 39. The one of the drain and source of the reset transistor 26 corresponds to a charge storage region Z in FIG. 3, more specifically corresponds to an impurity region 60n. The reset voltage line 39 is connected to a reset voltage supply circuit (not illustrated in FIG. 2). A predetermined reset voltage Vref can thus be supplied to the reset transistor 26 of each pixel 110 when the imaging device 100A is in operation. The reset voltage Vref is, for example, 0 V or a voltage near 0 V. As with the voltage supply circuit 126 described above, the reset voltage supply circuit may be configured to be able to apply the predetermined reset voltage Vref to the reset voltage line 39, and its specific configuration is not limited to a specific power supply circuit. The reset voltage supply circuit may be part of the vertical scanning circuit 122. The voltage supply circuit 126 and the reset voltage supply circuit may be independent separate circuits, or may be arranged in the imaging device 100A in the form of a single voltage supply circuit. The reset voltage supply circuit may also be part of the peripheral circuit 120A described above.

The reset transistor 26 has its gate connected to a reset signal line 36. The reset signal line 36 is provided for each row of the plurality of pixels 110, similarly to the address signal line 34, and is connected to the vertical scanning circuit 122 here. As described above, the vertical scanning circuit 122 can select the pixels 110, from which signals are to be read, on a row-by-row basis by applying a row selection signal to the address signal line 34. Similarly, the vertical scanning circuit 122 can turn on the reset transistors 26 in the selected row by applying a reset signal to the gates of the reset transistors 26 through the reset signal line 36. The potential of the charge storage node FD is reset by turning on the reset transistor 26.

### Pixel and Blocking Region

FIG. 3 schematically illustrates a cross section including the pixel region R1, the first peripheral region R2, and the blocking region 200A. Here, two representative pixels, of the plurality of pixels 110, located near the blocking region 200A are illustrated in cross section.

First, focus on the pixel region R1. The photoelectric conversion layer 12 is provided in the pixel region R1. The photoelectric conversion layer 12 is supported by the semiconductor substrate 130. A translucent counter electrode 13 is disposed on the photoelectric conversion layer 12. As illustrated in FIG. 3, the photoelectric conversion layer 12 and the counter electrode 13 are typically provided continuously above the semiconductor substrate 130 over the plurality of pixels 110.

The pixel 110 is a unit structure that constitutes the pixel region R1. The pixel 110 includes the photoelectric converter 10. The photoelectric converter 10 includes a part of the photoelectric conversion layer 12, a part of the counter electrode 13, and a pixel electrode 11. The pixel electrode 11 of the photoelectric converter 10 is positioned between the photoelectric conversion layer 12 and the semiconductor substrate 130. The pixel electrode 11 is made of metal such as aluminum or copper, a metal nitride, polysilicon to which conductivity is imparted by being doped with an impurity, or the like. As schematically illustrated in FIG. 3, the pixel electrode 11 of each pixel 110 is electrically isolated from the pixel electrodes 11 of other adjacent pixels by spatially separating the pixels from each other.

The photoelectric conversion layer 12 of the photoelectric converter 10 is made of an organic material or an inorganic material such as amorphous silicon. The photoelectric conversion layer 12 receives light incident through the counter electrode 13 to generate positive and negative charges through photoelectric conversion. That is, the photoelectric converter 10 has a function of converting light into charges. The photoelectric conversion layer 12 may include a layer made of an organic material and a layer made of an inorganic material.

The counter electrode 13 of the photoelectric converter 10 is made of a transparent conductive material such as indium tin oxide (ITO). The term “translucent” as used herein means that the photoelectric conversion layer 12 at least partially transmits light having an absorbable wavelength. It is not essential that light be transmitted over the entire wavelength range of visible light. Although not illustrated in FIG. 3, the counter electrode 13 is connected to the voltage line 38 described above. When the imaging device 100A is in operation, the potential of the voltage line 38 is controlled to set the potential of the counter electrode 13 to be higher than the potential of the pixel electrode 11, for example. This allows the pixel electrode 11 to selectively collect the positive charges among the positive and negative charges generated through photoelectric conversion. By forming the counter electrode 13 in the form of a single layer continuous across the plurality of pixels 110, a predetermined potential can be collectively applied to the counter electrodes 13 of the plurality of pixels 110 through the voltage line 38.

The plurality of pixels 110 each further include a part of the semiconductor substrate 130. As schematically illustrated in FIG. 3, the semiconductor substrate 130 has a plurality of impurity regions 60n as first impurity regions near its surface. The impurity region 60n functions as one of the drain and source of the reset transistor 26 included in the readout circuit 20 described above. The semiconductor substrate 130 also has an impurity region 61n that is the other of the drain and source of the reset transistor 26. As schematically illustrated in FIG. 3, the impurity region 61n is connected to the reset voltage line 39 described above through a polysilicon plug or the like. Here, the impurity regions 60n and 61n have an n-type conductivity. These plurality of impurity regions 60n and 61n are typically n-type diffusion regions.

As can be understood from above, the semiconductor substrate 130 has a plurality of readout circuits 20 formed therein corresponding to the plurality of pixels 110. The readout circuit 20 of each pixel is electrically isolated from the readout circuits 20 of the other pixels by an element isolation 221 provided in the semiconductor substrate 130.

As illustrated in FIG. 3, an interlayer insulating layer 90 covering the semiconductor substrate 130 is positioned between the photoelectric converter 10 and the semiconductor substrate 130. The interlayer insulating layer 90 generally includes a plurality of insulating layers and a plurality of wiring layers. A plurality of wiring layers disposed in the interlayer insulating layer 90 may include a wiring layer having the address signal line 34, the reset signal line 36, and the like as part thereof, a wiring layer having the vertical signal line 35, the power supply wiring 32, the reset voltage line 39, and the like as part thereof, and the like. The number of insulating layers and the number of wiring layers in the interlayer insulating layer 90 are not limited to those in this example but can be set arbitrarily.

A conductive structure 89 for electrically connecting the pixel electrode 11 of the photoelectric converter 10 to the readout circuit 20 formed on the semiconductor substrate 130 is provided inside the interlayer insulating layer 90. As schematically illustrated in FIG. 3, the conductive structure 89 includes traces and vias disposed in the interlayer insulating layer 90. These traces and vias are typically formed of metal such as copper or tungsten or metal compound such as metal nitride and metal oxide. The conductive structure 89 also includes a contact plug cx connected to the impurity region 60n described above. The contact plug cx connected to the impurity region 60n is typically a polysilicon plug doped with an impurity such as phosphorus to enhance conductivity. Although not illustrated in FIG. 3, the conductive structure 89 also has electrical connection with a gate electrode of the amplifier transistor 22. A plug cy is connected to the contact plug ex. Tungsten, copper, and the like are examples of metal that can be contained in the plug cy.

Next, focus on the semiconductor substrate 130. The semiconductor substrate 130 includes a support substrate 140 and one or more semiconductor layers formed on the support substrate 140. In the example illustrated in FIG. 3, the semiconductor substrate 130 includes an n-type impurity layer 62 provided on the support substrate 140. A p-type silicon substrate is described below as an example of the support substrate 140. The support substrate 140 may have a lower electrical resistivity than the impurity layer 62. The semiconductor substrate 130 may be a silicon-on-insulator (SOI) substrate, or a substrate having a film provided on its surface by epitaxial growth or the like.

First, focus on the pixel region R1 in the configuration illustrated in FIG. 3. The semiconductor substrate 130 includes an n-type semiconductor layer 62an and a p-type semiconductor layer 63p. The n-type semiconductor layer 62an is provided on the support substrate 140. The p-type semiconductor layer 63p is provided on the n-type semiconductor layer 62an. The n-type semiconductor layer 62an located between the support substrate 140 and the p-type semiconductor layer 63p is part of the impurity layer 62 described above. When the imaging device 100A is in operation, the potential of the impurity layer 62 is controlled via a well contact (not illustrated in FIG. 3). The impurity layer 62 partially including the n-type semiconductor layer 62an positioned in the pixel region R1 is provided inside the semiconductor substrate 130. This makes it possible to suppress the inflow of minority carriers from the support substrate 140 or the peripheral circuit into the charge storage region where signal charges are stored.

In the configuration illustrated in FIG. 3, the semiconductor substrate 130 further includes a p-type semiconductor layer 66p and a p-type impurity region 65p. The p-type semiconductor layer 66p is provided on the p-type semiconductor layer 63p. The p-type impurity region 65p is provided in the p-type semiconductor layer 66p. In this example, the impurity region 60n having connection with the conductive structure 89 is provided in the p-type impurity region 65p. A junction capacitance formed by a pn junction between the impurity region 60n and the p-type impurity region 65p serving as a p-well functions as a capacitance that stores at least part of the signal charges collected by the pixel electrode 11. That is, the impurity region 60n constitutes a charge storage region that temporarily holds signal charges. The impurity region 61n, on the other hand, is provided in the p-type semiconductor layer 66p. Here, the p-type impurity region 65p has an impurity concentration lower than that of the p-type semiconductor layer 66p.

The semiconductor substrate 130 also includes a plurality of p-type regions 64. The plurality of p-type regions 64 are provided so as to penetrate the impurity layer 62. The p-type region 64 has a relatively high impurity concentration. Two regions having a common conductivity type separated by the impurity layer 62 can be electrically connected to each other by providing the p-type regions 64.

The plurality of p-type regions 64 include a plurality of p-type regions 64a and one or more p-type regions 64b. The p-type regions 64a are positioned inside the pixel region R1 when viewed in the direction normal to the semiconductor substrate 130. The p-type region 64b is positioned below the plurality of contact plugs 211 in the blocking region 200A. The p-type regions 64a are formed between the p-type semiconductor layer 63p and the support substrate 140 so as to penetrate the n-type semiconductor layer 62an, thus electrically connecting the p-type semiconductor layer 63p and the support substrate 140. The p-type region 64b, on the other hand, is electrically connected to the impurity region 131 by having its one end reach the impurity region 131 of the blocking region 200A, thus electrically connecting the impurity region 131 and the support substrate 140.

Therefore, an electrical path is formed in the semiconductor substrate 130 from the impurity region 131 of the blocking region 200A to the p-type semiconductor layer 63p through the p-type region 64b, the support substrate 140, and the p-type regions 64a. As described above, the plurality of contact plugs 211 are connected to the impurity region 131 of the blocking region 200A. These contact plugs 211 are configured to be connectable to a power source (not illustrated) such as ground. For example, the potential of the impurity region 131 in the blocking region 200A can be grounded through a plurality of contact plugs 211. By connecting an appropriate power source to the plurality of contact plugs 211 in the blocking region 200A, the potentials of the p-type impurity region 65p and p-type semiconductor layer 66p can be controlled through the p-type semiconductor layer 63p by using the electrical path including the impurity region 131, the p-type region 64b, the support substrate 140, and the p-type region 64a.

In the example illustrated in FIG. 3, an impurity region 131a having a relatively high impurity concentration is formed in a portion of the impurity region 131 located near the surface of the semiconductor substrate 130. The contact plugs 211 are typically made of metal. By providing the impurity region 131a having the relatively high impurity concentration in the impurity region 131 and connecting the plurality of contact plugs 211 to the impurity region 131a, the effect of reducing contact resistance between the plurality of contact plugs 211 and the impurity region 131 can be achieved.

In this example, a silicide layer 131s is further formed between the plurality of contact plugs 211 and the impurity region 131. By providing the silicide layer 131s near the surface of the semiconductor substrate 130 in the impurity region 131a and connecting the plurality of contact plugs 211 thereto, the contact resistance can be further reduced.

Next, focus on the first peripheral region R2 of the semiconductor substrate 130. As described above, circuits for driving the plurality of pixels 110 and circuits for processing signals read from the plurality of pixels 110 are formed in the first peripheral region R2. The first peripheral region R2 includes, for example, a plurality of transistors 25 and a first peripheral transistor 27, which constitute a logic circuit such as a multiplexer. As schematically illustrated in FIG. 3, here, an n-type semiconductor layer 62bn, which is another part of the impurity layer 62, is formed on the support substrate 140. On the n-type semiconductor layer 62bn, an n-type impurity region 81n and a p-type impurity region 82p are formed as wells. The transistor 25 has its drain and source located in the n-type impurity region 81n, while the first peripheral transistor 27 has its drain and source located in the p-type impurity region 82p. The n-type semiconductor layer 62bn is separated from the n-type semiconductor layer 62an across the entire circumference of the pixel region R1 by interposing a part of the support substrate 140 therebetween. A predetermined voltage is supplied to the n-type semiconductor layer 62bn by connecting a power source (not illustrated). Hereinafter, the n-type impurity region 81n may be referred to as an n-type well and the p-type impurity region 82p may be referred to as a p-type well.

The n-type semiconductor layer 62an in the pixel region R1 and the n-type semiconductor layer 62bn in the first peripheral region R2 may have the same depth or different depths.

In the configuration illustrated in FIG. 3, contact plugs cp are connected to the drain, source, and gate electrodes of peripheral transistors such as the transistors 25 and first peripheral transistor 27.

In the example illustrated in FIG. 3, the blocking region 200A further includes an n-type impurity region 83n positioned near the boundary with the first peripheral region R2. The n-type impurity region 83n is positioned on the n-type semiconductor layer 62bn in the impurity layer 62 and has electrical connection with the n-type semiconductor layer 62bn. A plug may be provided in the n-type impurity region 83n. The potentials of the n-type impurity region 83n and the n-type semiconductor layer 62bn can be controlled by connecting an appropriate power source to the plug connected to the n-type impurity region 83n.

The impurity layers and impurity regions located above the support substrate 140 are each typically formed by ion implantation of an impurity into a film obtained by epitaxial growth on the support substrate 140. The p-type regions 64a of the p-type region 64 located in the pixel region R1 can be formed at positions not overlapping the element isolation in the pixel in a plan view.

In this embodiment, the blocking region 200A is formed between the pixel region R1 and the first peripheral region R2. As described above, the blocking region 200A includes the element isolation 220 located between the pixel region R1 and the first peripheral region R2, and the impurity region 131 in which the plurality of contact plugs 211 are disposed. Since the blocking region 200A includes at least the impurity region 131, a dopant in the impurity region 131 can be used to exert a so-called gettering effect. For example, it is known that the image quality is degraded when a metal impurity is diffused into a region of a semiconductor substrate where pixels are disposed, which supports a photoelectric conversion layer. Having the dopant in the impurity region 131 function as a gettering center can suppress the diffusion of the metal impurity into the charge storage region and avoid image quality degradation due to the diffusion of the metal impurity.

Examples of a p-type impurity, that is, dopant for a silicon substrate are boron, indium, and gallium. Examples of an n-type dopant are phosphorus, arsenic, antimony, and bismuth. Among these, the p-type dopant is known to exert the gettering effect on most metals, and is therefore suitable as a dopant for the impurity region 131. In an exemplary embodiment of the present disclosure, the p-type is chosen as the conductivity type of the impurity region 131 of the blocking region 200A. The blocking region 200A including the impurity region 131 doped with a p-type impurity, for example, is disposed between the pixel region R1 and the first peripheral region R2. This can effectively suppress the diffusion of a metal impurity into the pixel region R1. More specifically, the diffusion of the metal impurity into the charge storage region of the pixel 110 can be suppressed, and thus the image quality degradation due to the diffusion of the metal impurity can be suppressed.

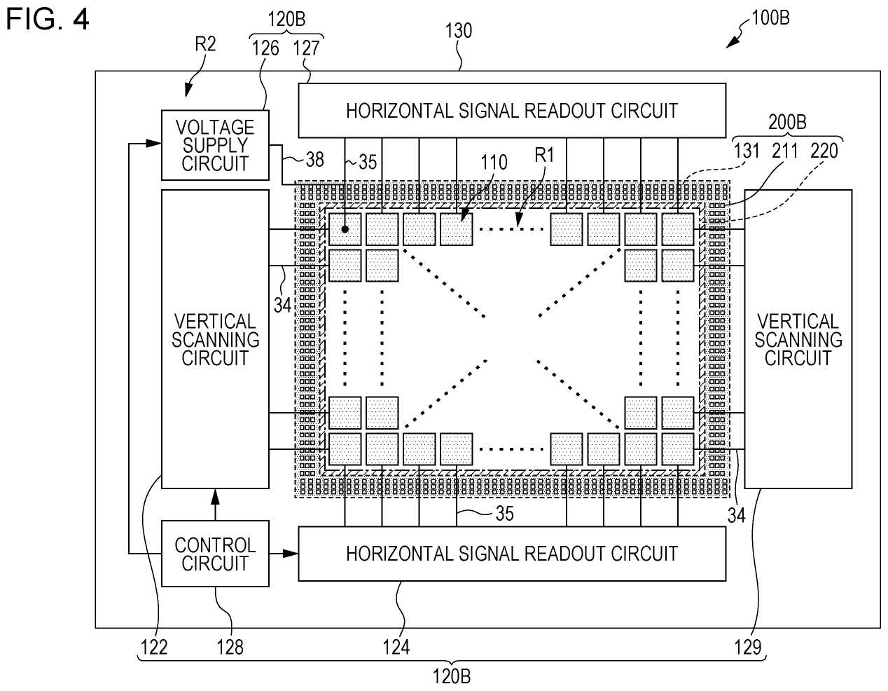

FIG. 4 illustrates another example of the shape of the blocking region. Compared to the imaging device 100A illustrated in FIG. 1, an imaging device 100B illustrated in FIG. 4 includes a blocking region 200B that surrounds a pixel region R1 in a rectangular shape, instead of the blocking region 200A. Compared to the blocking region 200A described above, an impurity region 131 in the blocking region 200B surrounds the pixel region R1 in a seamless loop in a plan view. In this example, again, a plurality of contact plugs 211 are connected to the impurity region 131, as schematically illustrated in FIG. 4. In this example, an element isolation 220 in the blocking region 200B also surrounds the pixel region R1 in a seamless loop inside the impurity region 131. In such a configuration, it can be said that the element isolation 220 defines the boundary between the pixel region R1 and a first peripheral region R2.

A peripheral circuit 120B provided in the first peripheral region R2 includes a second vertical scanning circuit 129 and a second horizontal signal readout circuit 127 in addition to a vertical scanning circuit 122, a horizontal signal readout circuit 124, a voltage supply circuit 126, and a control circuit 128. The second vertical scanning circuit 129 is disposed opposite to the vertical scanning circuit 122 across the pixel region R1. As illustrated in FIG. 4, the second vertical scanning circuit 129 is also connected to address signal lines 34 provided corresponding to each row of a plurality of pixels 110. Similarly, the second horizontal signal readout circuit 127 is disposed opposite to the horizontal signal readout circuit 124 across the pixel region R1, and is connected to vertical signal lines 35 provided corresponding to each column of the plurality of pixels 110.

For example, the vertical scanning circuit 122 performs a row selection operation for the pixels in the left half of the pixel region R1. The second vertical scanning circuit 129 performs a row selection operation of the pixels in the right half of the pixel region R1. The horizontal signal readout circuit 124 processes signals read from the pixels in the lower half of the pixel region R1. The second horizontal signal readout circuit 127 processes signals read from the pixels in the upper half of the pixel region R1. The pixel region R1 is thus partitioned and the signals are read by the plurality of vertical scanning circuits and horizontal signal readout circuits. This can speed up operations such as reducing a frame rate.

In the configuration illustrated in FIG. 4, the vertical scanning circuits 122 and 129 and the horizontal signal readout circuits 124 and 127 are arranged along the four sides of the rectangular pixel region R1. In other words, in this example, the blocking region 200B is interposed between the vertical scanning circuit 122 and a set of pixels 110, between the second vertical scanning circuit 129 and a set of pixels 110, between the horizontal signal readout circuit 124 and a set of pixels 110, and between the second horizontal signal readout circuit 127 and a set of pixels 110.

The blocking region 200B is formed in the semiconductor substrate 130 so as to have a shape surrounding the pixel region R1 including the plurality of arrays of pixels 110 in a plan view. This makes it possible to more effectively suppress the movement of charges between the charge storage regions of the pixels and the circuits formed in the first peripheral region R2. As in the example illustrated in FIG. 4, when the circuit group constituting the peripheral circuit is disposed so as to surround the rectangular pixel region R1, for example, it is not essential in the embodiment of the present disclosure that the blocking region surrounds the pixel region R1 in a seamless loop in a plan view. For example, the blocking region may include a plurality of portions each including the element isolation 220 and the impurity region 131 and arranged to surround the pixel region R1 as a whole. Such a configuration can also expect the same effect as in the case of providing a blocking region so as to surround the pixel region R1 in a seamless loop in a plan view. The blocking region 200B may be omitted.

### Transistor in First Peripheral Region R2

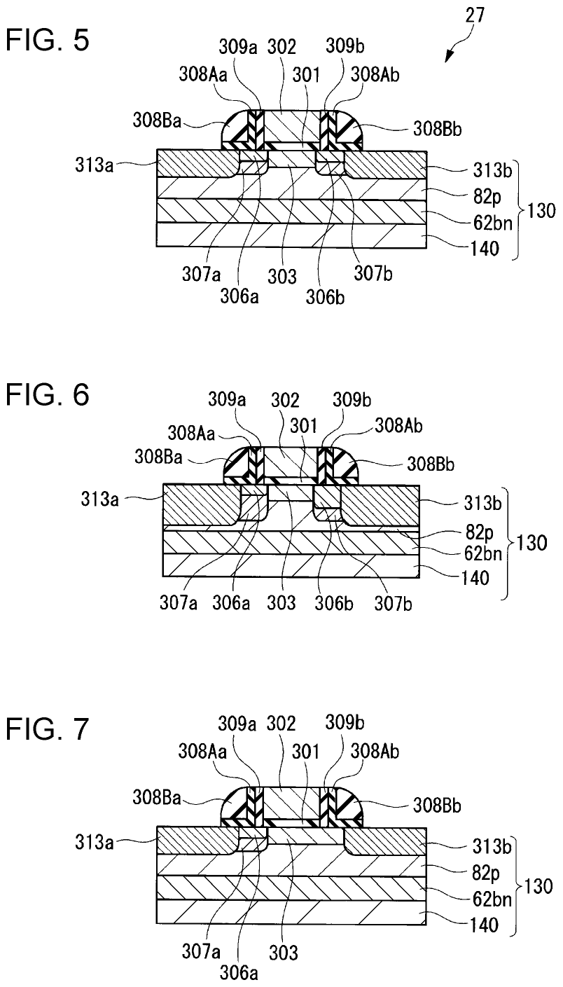

As described above, the first peripheral region R2 includes the first peripheral transistor 27. Hereinafter, configuration examples of the first peripheral transistor 27 according to the embodiment will be described with reference to FIGS. 5 to 12.

FIG. 5 illustrates a sectional view configuration of the first peripheral transistor 27 according to a first configuration example. To be more specific, the first peripheral transistor 27 is an MIS transistor, more specifically a MOSFET. The first peripheral transistor 27 is also an n-type transistor.

As illustrated in FIG. 5, a gate insulating film 301 made of silicon oxide (SiO₂) is provided on a main surface of a semiconductor substrate 130 made of, for example, p-type silicon (Si), and a gate electrode 302 made of polysilicon or a metal gate is formed thereon. In an upper part of the semiconductor substrate 130, a p-type channel diffusion layer 303 having boron (B), for example, diffused therein and a p-type impurity region 82p are formed. The p-type channel diffusion layer 303 is a p-type well having boron (B), for example, diffused therein and having a deeper junction depth than the p-type channel diffusion layer 303. In the semiconductor substrate 130, a support substrate 140, an n-type semiconductor layer 62bn, and the p-type impurity region 82p, which is the p-type well, are stacked in this order.

In a region of the p-type channel diffusion layer 303 in a gate length direction, first extension diffusion layers 306a and 306b are formed, which are n-type extension high-concentration diffusion layers having arsenic (As), for example, diffused therein as an n-type impurity and having a relatively shallow junction. Below the first extension diffusion layers 306a and 306b, first pocket diffusion layers 307a and 307b are formed, respectively, which are p-type pocket diffusion layers having indium (In), for example, diffused therein as a p-type impurity.

In the first extension diffusion layers 306a and 306b, phosphorus (P) may be diffused instead of or together with arsenic (As). The first extension diffusion layers 306a and 306b may also contain carbon (C). Carbon (C) can suppress transient enhanced diffusion (hereinafter abbreviated as TED) of phosphorus. This can maintain a shallow impurity concentration profile in the first extension diffusion layers 306a and 306b. This is advantageous from the viewpoint of realizing the first peripheral transistor 27 with high driving force.

Carbon can also suppress TED of boron. For example, the p-type channel diffusion layer 303 may contain boron and carbon. In this configuration example, the TED of boron can be suppressed by carbon in the p-type channel diffusion layer 303. This is advantageous from the viewpoint of realizing the first peripheral transistor 27 with small variations in threshold voltage.

In a manufacturing process of the imaging device, heat treatment may be performed for the purpose of heating the pixel region R1. This heat treatment may also heat the first peripheral region R2. However, the above diffusion suppressing effect by carbon suppresses redistribution of the impurity in the first peripheral transistor 27 in the first peripheral region R2 even when the first peripheral region R2 is heated by such heat treatment. When the first extension diffusion layers 306a and 306b contain phosphorus and carbon, for example, carbon can suppress the redistribution of phosphorus, thus maintaining shallow junctions. When the p-type channel diffusion layer 303 contains boron and carbon, carbon can suppress the redistribution of boron.

The first extension diffusion layers 306a and 306b containing carbon can also exert the effect of suppressing the occurrence of residual defects in the first extension diffusion layers 306a and 306b. An end-of-range (EOR) defect is an example of the residual defect. The EOR defect is a defect layer formed in a region just below an amorphous crystal (a/c) interface before heat treatment when the semiconductor substrate 130 made of silicon is heat-treated in an amorphous state.

The mechanism of TED suppression by carbon implantation is as follows. Carbon forms a carbon-interstitial silicon complex, cluster or the like with excess point defects that cause TED, thereby suppressing the excess point defects. Considering that such excess point defects can grow to generate secondary defects such as dislocation loops, it can be said that carbon suppresses crystal defects. For example, a crystal layer in which the formation of residual defect layers such as secondary defects is suppressed is formed in an extension formation region of the semiconductor substrate 130. This makes it possible to suppress the occurrence of junction leakage due to the residual defect layers.

In this configuration example, the first pocket diffusion layers 307a and 307b contain indium as a p-type impurity. Indium has a large mass number and a small diffusion coefficient. In this configuration example, the interface between the semiconductor substrate 130 and the gate insulating film 301 is an Si/SiO₂ interface. The segregation coefficient of the Si/SiO₂ interface with respect to indium makes it difficult for indium to pile up on the surface side of the semiconductor substrate 130. This makes it difficult to form a rising concentration distribution on the surface side. Therefore, a concentration distribution with a reduced concentration on the surface is likely to be formed. These properties of indium can make the indium concentration profile a super steep retrograde profile (SSRP) in a region along a straight line extending in the depth direction of the semiconductor substrate 130 through the first pocket diffusion layer 307a. The SSRP is a shallow and steep impurity concentration profile with a low surface concentration in the semiconductor substrate 130. The same applies to the impurity concentration profile in a region along a straight line extending in the depth direction of the semiconductor substrate 130 through the first pocket diffusion layer 307b.

Specifically, immediately after the implantation of indium ions, which are heavy ions, an impurity concentration profile that is shallow and steep and has a low surface concentration in the semiconductor substrate 130 is formed. With the large mass number, indium hardly diffuses, making it unlikely for the as-implanted concentration profile immediately after implantation to be significantly changed by diffusion. It is also unlikely that indium piled up on the surface of the semiconductor substrate 130 will raise the indium concentration on the surface. Therefore, in this configuration example, the SSRP of indium as described above for the first pocket diffusion layers 307a and 307b can be realized in the resultant imaging device.

Various advantages are obtained by the SSRP as described above for the first pocket diffusion layers 307a and 307b. For example, when the SSRP is formed, the concentration of indium as an impurity in the surface of the semiconductor substrate 130 can be reduced. This prevents the transfer of charges between the source and drain of the first peripheral transistor 27 from being hindered by the impurity in this surface portion. In other words, charge mobility is less likely to degrade. Therefore, the driving force of the first peripheral transistor 27 is less likely to be reduced. The low impurity concentration in the surface portion makes it less likely for impurity fluctuations in the surface portion to cause variations in the threshold voltage of the first peripheral transistor 27. For this reason, this configuration is advantageous from the viewpoint of realizing the first peripheral transistor 27 with high driving force and less variations in threshold voltage. This advantage is more likely to be received particularly when a fine peripheral device is configured in the first peripheral region R2.

When the variation in the threshold voltage of the first peripheral transistor 27 is small, there is no need to set a wide design margin for the first peripheral transistor 27. In addition, the Pelgrom coefficient is also reduced. Here, the threshold variation of a transistor can be expressed by σvt=Avt/√(Lg·Wg) and is proportional to the reciprocal of the square root of the product of gate length (Lg) and gate width (Wg). The slope Avt in this event is known as the Pelgrom coefficient. This makes it possible to select a small-sized (specifically, small area) transistor with a small gate length (Lg) and/or gate width (Wg).

Also, when the variation in the threshold voltage of the first peripheral transistor 27 is small, the number of variations in size to be included in the first peripheral transistor 27 is easily reduced. A case is considered, for example, where the variation in the threshold voltage of the first peripheral transistor 27 is small and other characteristics of the first peripheral transistor 27 are also good. The size of the transistor to realize suitable characteristics of the transistor differs for each characteristic. For example, the transistor size to achieve a good Pelgrom coefficient, transistor size to achieve a good transconductance (gm), and transistor size to achieve a good drain conductance (gds) are different from each other. However, the small variation in the threshold voltage of the first peripheral transistor 27 reduces the necessity for the first peripheral transistor 27 to include variations with different sizes for each characteristic. This can reduce the number of first peripheral transistors 27 arranged in the first peripheral region, thus reducing the area of the first peripheral region.

Note that indium tends to segregate in EOR defects. In this configuration example, an EOR defect exists in the portion just below the first extension diffusion layers 306a and 306b, which is where indium segregates.

In regions outside the first extension diffusion layers 306a and 306b in the semiconductor substrate 130, an n-type source diffusion layer 313a and an n-type drain diffusion layer 313b are formed, which are connected to the first extension diffusion layers 306a and 306b and have a larger junction depth than the first extension diffusion layers 306a and 306b. In this configuration example, the n-type source diffusion layer 313a and the n-type drain diffusion layer 313b contain carbon (C). Note, however, that one or both of the n-type source diffusion layer 313a and the n-type drain diffusion layer 313b do not need to contain carbon (C).

Insulating offset spacers 309a and 309b are formed on both side surfaces of the gate electrode 302. The offset spacers 309a and 309b contain indium and carbon. First sidewalls 308Aa and 308Ab with an L-shaped cross section are also formed, which extend from the outer side surfaces of the offset spacers 309a and 309b to the upper portions of the inner ends of the n-type source diffusion layer 313a and the n-type drain diffusion layer 313b above the semiconductor substrate 130. Insulating second sidewalls 308Ba and 308Bb are formed outside the first sidewalls 308Aa and 308Ab, respectively.

In the first configuration example, boron ions are used as an impurity in the p-type channel diffusion layer 303. Alternatively, p-type element ions having a higher atomic number than boron ions may be used instead of or together with the boron ions. The p-type element ions having a higher atomic number than boron ions are, for example, indium ions.

When the p-type channel diffusion layer 303, which is a channel region, contains indium, the concentration profile of indium can be SSRP in a region along a straight line extending in the depth direction of the semiconductor substrate 130 through the channel diffusion layer 303. The SSRP for the channel diffusion layer 303 makes it possible to set the threshold voltage while reducing the surface impurity concentration. This makes it possible to suppress decrease in carrier mobility caused by impurity scattering in the channel diffusion layer 303 and to suppress impurity fluctuations in the surface of the semiconductor substrate 130. This configuration is also advantageous from the viewpoint of realizing the first peripheral transistor 27 with high driving force and less variations in threshold voltage.

An impurity that can be used as the impurity for the p-type channel diffusion layer 303 may be used as an impurity for the first pocket diffusion layers 307a and 307b. An impurity that can be used as the impurity for the first pocket diffusion layers 307a and 307b may also be used as the impurity for the p-type channel diffusion layer 303. In addition to indium, gallium and the like can be used as impurities of elements having a high atomic number, which can be contained in the p-type channel diffusion layer 303 and the first pocket diffusion layers 307a and 307b.

In addition, impurities that contribute to suppressing TED are not limited to carbon. At least one selected from the group consisting of nitrogen, fluorine, germanium, silicon, and argon may be used instead of or together with carbon. Nitrogen, fluorine, germanium, silicon, argon, and the like can also contribute to TED suppression. Specifically, as with carbon, impurities such as nitrogen and fluorine also form an impurity-interstitial silicon or impurity-atomic vacancy complex, cluster or the like with excess point defects that cause TED, thereby suppressing the excess point defects. More specifically, excess point defects are suppressed by forming complexes such as carbon-interstitial silicon, nitrogen-interstitial silicon, fluorine-interstitial silicon, and fluorine-atomic vacancy. Germanium, silicon, argon, and the like contribute to TED suppression through pre-amorphization. In addition, at least one element selected from the group consisting of group 14, group 17, and group 18 elements having no conductivity may be used as an impurity that contributes to TED suppression.

In the first configuration example, the first peripheral transistor 27 is an N-channel MIS transistor. Note, however, that a configuration in which the first peripheral transistor 27 is a P-channel MIS transistor may also be employed. When first peripheral transistor 27 is the P-channel MIS transistor, group III elements having a higher atomic number than boron (B) ions, such as indium (In) ions and gallium ions, can be used other than the boron ions, as the p-type impurity ions forming the extension diffusion layer. In the case of the P-channel MIS transistor, group V elements having a higher atomic number than arsenic (As) ions, such as antimony (Sb) ions and bismuth (Bi) ions, or a combination thereof can be used other than the arsenic ions or phosphorus (P) ions, for example, for the n-type pocket diffusion layer. This configuration can also suppress TED in the n-type pocket diffusion layer. For example, TED of boron can be suppressed by including carbon or the like in the n-type pocket diffusion layer along with boron. Indium also causes TED through interstitial silicon, although to a lesser extent than boron. Therefore, TED of indium can be suppressed by co-implanting carbon or the like together with indium. Such TED suppression can reduce variations in the threshold voltage caused by the impurity concentration profile in the pocket diffusion layer. As the p-type impurity ions forming the extension diffusion layer, one of the above impurities may be used, or two or more of them may be used in combination. The same applies to the elements used for the n-type pocket diffusion layer.

### First Modification of First Configuration Example

FIG. 6 illustrates a sectional view configuration of a transistor according to a first modification of the first configuration example. As illustrated in FIG. 6, in the transistor according to the first modification, impurity concentration profiles of first extension diffusion layers 306a and 306b, which are n-type extension high-concentration diffusion layers, are asymmetric with respect to the gate electrode 302. As illustrated in FIG. 6, the profile of the first extension diffusion layer is shallower and steeper in the source region than in the drain region. This increases a carrier concentration gradient between the source region and the channel region, thus improving the driving force in the MIS transistor. In addition, the profile of the first extension diffusion layer is deeper in the drain region than in the source region. This suppresses the generation of hot carriers as compared with a symmetrical, shallow and steep profile structure. Note that the transistor having the structure illustrated in FIG. 6 can be fabricated with reference to Japanese Patent No. 5235486, for example.

In the example illustrated in FIG. 6, the first extension diffusion layer 306a is shallower than the first extension diffusion layer 306b. Note, however, that a configuration in which the first extension diffusion layer 306b is shallower than the first extension diffusion layer 306a may also be adopted.

### Second Modification of First Configuration Example

FIG. 7 illustrates a sectional view configuration of a transistor according to a second modification of the first configuration example. As illustrated in FIG. 7, the transistor according to the second modification includes an N-type extension high-concentration diffusion layer only on one side of the n-type source diffusion layer 313a and the n-type drain diffusion layer 313b.

In the example illustrated in FIG. 7, the transistor according to the second modification includes a first extension diffusion layer 306a, which is an n-type extension high-concentration diffusion layer, adjacent to the n-type source diffusion layer 313a, and does not include a first extension diffusion layer adjacent to the n-type drain diffusion layer 313b. Note, however, that a configuration can also be employed in which the transistor does not include the first extension diffusion layer adjacent to the n-type source diffusion layer 313a and includes the first extension diffusion layer 306b adjacent to the n-type drain diffusion layer 313b.

As illustrated in FIG. 7, the transistor according to the second modification includes a p-type pocket diffusion layer only on one side of the n-type source diffusion layer 313a and the n-type drain diffusion layer 313b. Specifically, the transistor according to the second modification includes a first pocket diffusion layer 307a adjacent to the n-type source diffusion layer 313a, and does not include a first pocket diffusion layer adjacent to the n-type drain diffusion layer 313b. Note, however, that a configuration can also be employed in which the transistor does not include the first pocket diffusion layer adjacent to the n-type source diffusion layer 313a and includes the first pocket diffusion layer 307b adjacent to the n-type drain diffusion layer 313b.

### Third Modification of First Configuration Example

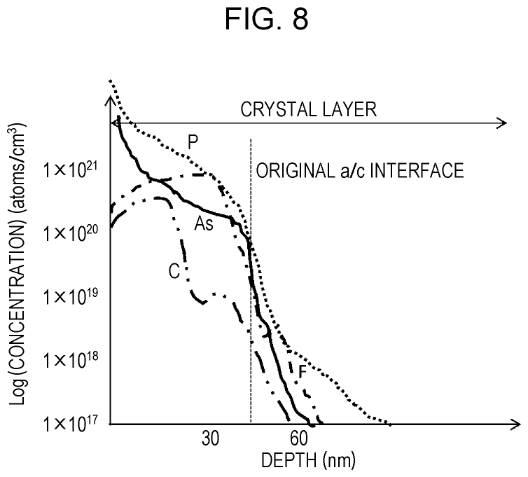

In a third modification of the first configuration example, the n-type source diffusion layer 313a and the n-type drain diffusion layer 313b contain fluorine (F) and carbon (C). Fluorine can cause partial amorphization of the semiconductor substrate 130. Fluorine can also suppress transient enhanced diffusion (TED) of impurities. FIG. 8 illustrates an example of impurity concentration distribution in a region along a straight line extending in the depth direction of the semiconductor substrate 130 through the n-type source diffusion layer 313a. The vertical axis represents the concentrations of arsenic (As), phosphorus (P), fluorine (F), and carbon (C) on a logarithmic scale. The concentration distribution of FIG. 8 relates to the case where fluorine and carbon are implanted for amorphization and diffusion suppression of impurities and are diffused during annealing. In FIG. 8, the solid line indicates the concentration distribution of arsenic (As). The dotted line indicates the concentration distribution of phosphorus (P). The dashed-dotted line indicates the concentration distribution of fluorine (F). The dashed-two dotted line indicates the concentration distribution of carbon (C). In the example of FIG. 8, the fluorine concentration distribution has a segregation near the original a/c interface location. In this example, the impurity concentration distribution in the region along the straight line extending in the depth direction of the semiconductor substrate 130 through the n-type drain diffusion layer 313b is also the distribution illustrated in FIG. 8.

According to the third modification, the diffusion of impurities is suppressed after the annealing. Even when the first peripheral region R2 is heated during heat treatment for the pixel region R1, redistribution of the impurities can be kept within a small range.

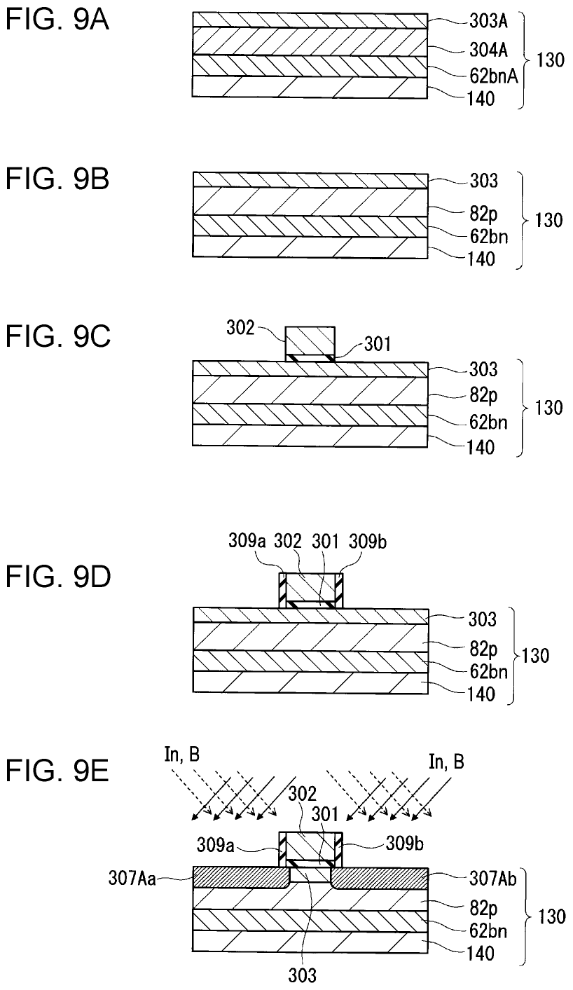

A method for manufacturing the transistor illustrated in FIG. 5 will be described below with reference to FIGS. 9A to 11C. FIGS. 9A to 11C are sectional views illustrating a method for manufacturing the transistor illustrated in FIG. 5.

FIGS. 9A to 9E, FIGS. 10A to 10D, and FIGS. 11A to 11C each illustrate a sectional configuration in order of steps of the method for manufacturing a MIS transistor according to the first configuration example.

First, as illustrated in FIG. 9A, impurity ions are implanted into the channel formation region of the semiconductor substrate 130 made of p-type silicon. This ion implantation is phosphorus (P) ion implantation with an implantation energy of 1000 keV and an implantation dose of 3×10¹²/cm². This implantation forms an n-type well impurity-implanted layer 62bnA.

Next, as illustrated in FIG. 9A, impurity ions are implanted into the channel formation region of the semiconductor substrate 130 made of p-type silicon to form a p-type well impurity-implanted layer 304A. This ion implantation includes, for example, a first stage, a second stage, and a third stage. The first-stage ion implantation is boron (B) ion implantation with an implantation energy of 250 keV and an implantation dose of 1×10¹³/cm². The second-stage ion implantation is boron (B) ion implantation with an implantation energy of 100 keV and an implantation dose of 1×10¹³/cm². The third-stage ion implantation is boron (B) ion implantation with an implantation energy of 50 keV and an implantation dose of 1×10¹³/cm². Thereafter, boron (B) ions are implanted into the semiconductor substrate 130 with an implantation energy of about 10 keV and an implantation dose of about 5×10¹²/cm² to form a p-type channel impurity-implanted layer 303A on the p-type well impurity-implanted layer 304A. In this event, a silicon oxide film may be deposited on the surface of the semiconductor substrate 130 before ion implantation. The order of forming the n-type well impurity-implanted layer 62bnA, p-type well impurity-implanted layer 304A, and p-type channel impurity-implanted layer 303A is not particularly limited.

Next, as illustrated in FIG. 9B, the ion-implanted semiconductor substrate 130 is subjected to first rapid thermal annealing (RTA). In the first rapid thermal annealing, the temperature is raised to about 850° C. to 1050° C. at a temperature increase rate of greater than or equal to about 100° C./sec, for example, about 200° C./sec. The peak temperature is then maintained for up to about 10 seconds or is not maintained. By this first rapid thermal annealing, a p-type channel diffusion layer 303, a p-type impurity region 82p that is a p-type well, and an n-type semiconductor layer 62bn are formed above the semiconductor substrate 130, respectively. Note that the rapid thermal annealing where the peak temperature is not maintained means heat treatment in which the heat treatment temperature drops as it reaches the peak temperature.

Next, as illustrated in FIG. 9C, a gate insulating film 301 made of silicon oxide having a thickness of about 1.5 nm is selectively formed on the semiconductor substrate 130, and a gate electrode 302 made of polysilicon having a thickness of about 100 nm is selectively formed thereon. For the gate insulating film 301, silicon oxide is used here, but a high-k insulating film may also be used, such as silicon oxynitride (SiON), hafnium oxide (HfOₓ), or hafnium silicon oxynitride (HfSiON) may be used. For the gate electrode 302, a metal gate, a laminated film of polysilicon and a metal gate, polysilicon having its upper part silicided, or fully silicided polysilicon can be used in place of polysilicon.

As illustrated in FIG. 9D, an insulating film made of silicon oxide having a thickness of about 8 nm is deposited. Anisotropic etching is then performed to form offset spacers 309a and 309b having a finished thickness of about 4 nm on both sides of the gate electrode 302 and the gate insulating film 301. For the offset spacers 309a and 309b, silicon oxide is used here, but a high-k insulating film such as silicon nitride (SiN) or HfO₂ may also be used.

As illustrated in FIG. 9E, using the offset spacers 309a and 309b and the gate electrode 302 as a mask, indium (In) ions, for example, which are a p-type impurity, are implanted at an angle into the semiconductor substrate 130 with an implantation energy of 55 keV and an implantation dose of about 2×10¹³/cm². Subsequently, boron (B) ions, for example, which are a p-type impurity, are implanted at an angle with an implantation energy of 8 keV and an implantation dose of about 1×10¹³/cm² to form p-type pocket impurity-implanted layers 307Aa and 307Ab. Implanting indium first, which has a large mass number, leads to an effect of suppressing channeling tails due to implantation damage. However, the order of implanting the In ions and B ions is not particularly limited.

In this example, both the In ions and B ions are implanted into the p-type pocket impurity-implanted layers 307Aa and 307Ab. However, only one of the In ions and B ions may be implanted into the p-type pocket impurity-implanted layers 307Aa and 307Ab.

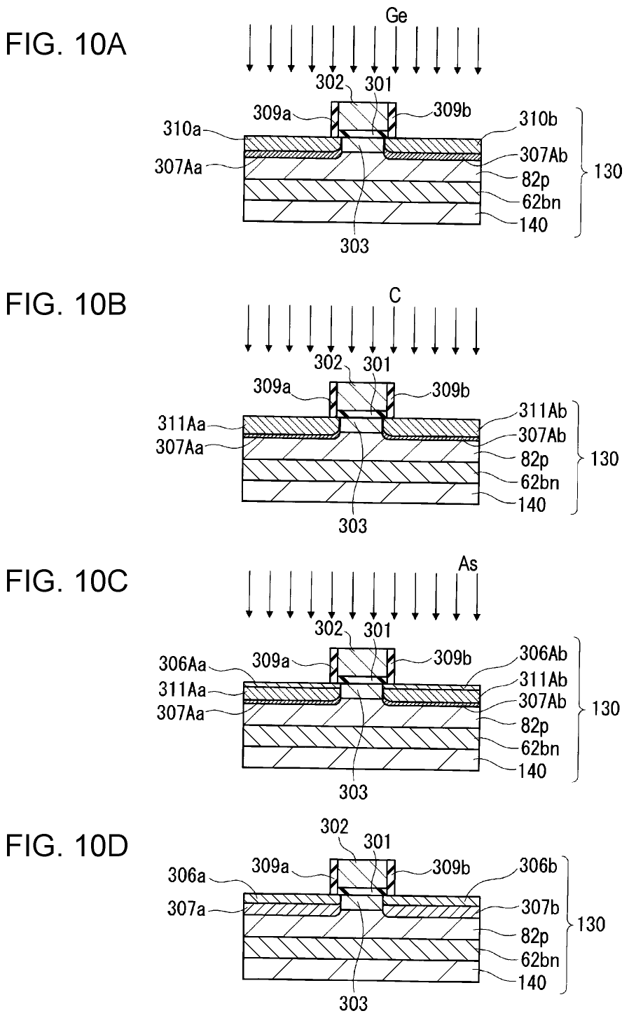

As illustrated in FIG. 10A, using the offset spacers 309a and 309b and the gate electrode 302 as a mask, germanium (Ge) ions are implanted into the semiconductor substrate 130 with an implantation energy of 10 keV and an implantation dose of about 5×10¹⁴/cm² to selectively form amorphous layers 310a and 310b in the semiconductor substrate 130.

As described above, phosphorus (P) may be diffused in the first extension diffusion layers 306a and 306b, instead of or together with arsenic (As). The formation of amorphous layers by Ge ion implantation is particularly beneficial when the first extension diffusion layers 306a and 306b contain phosphorus (P). Note, however, that the formation of amorphous layers by implantation of Ge ions or the like is not essential. For example, when arsenic is diffused in the first extension diffusion layers 306a and 306b, arsenic implantation itself is likely to cause amorphization. For this reason, the formation of amorphous layers by Ge ion implantation is not essential. To form the amorphous layers 310a and 310b, germanium is used here, but silicon (Si), argon (Ar), krypton (Kr), xenon (Xe), carbon (C), or the like may be used.

Next, as illustrated in FIG. 10B, in the state where the amorphous layers 310a and 310b are formed, using the offset spacers 309a and 309b and the gate electrode 302 as a mask, carbon (C) ions are implanted into the semiconductor substrate 130 with an implantation energy of 5 keV and an implantation dose of about 1×10¹⁵/cm² to form carbon-implanted layers 311Aa and 311Ab. The carbon ion implantation may be carried out with an implantation energy of 1 keV to 10 keV and an implantation dose of 1×10¹⁴/cm² to 3×10¹⁵/cm². In this event, molecules containing carbon, such as molecular ions such as C₅H₅ and C₇H₇, may be used instead of carbon ions. Nitrogen ions, fluorine ions, or the like may be used instead of carbon ions, which are impurity ions for preventing diffusion. When carbon or carbon-containing molecular ions are used instead of germanium to form the amorphous layers 310a and 310b, it is also possible to simultaneously perform the step of forming the amorphous layers 310a and 310b and the step of forming the carbon-implanted layers 311Aa and 311Ab. Ions having a relatively large mass number such as indium (In) may be used for p-type pocket impurity implantation to amorphize the semiconductor substrate 130 during pocket implantation.

As illustrated in FIG. 10C, using the offset spacers 309a and 309b and the gate electrode 302 as a mask, arsenic (As) ions, for example, which are an n-type impurity, are implanted into the semiconductor substrate 130 with an implantation energy of 3 keV and an implantation dose of about 8×10¹⁴/cm² to form first n-type impurity-implanted layers 306Aa and 306Ab on the carbon-implanted layers 311Aa and 311Ab. Phosphorus (P), antimony (Sb), bismuth (Bi), or the like may be used instead of arsenic.

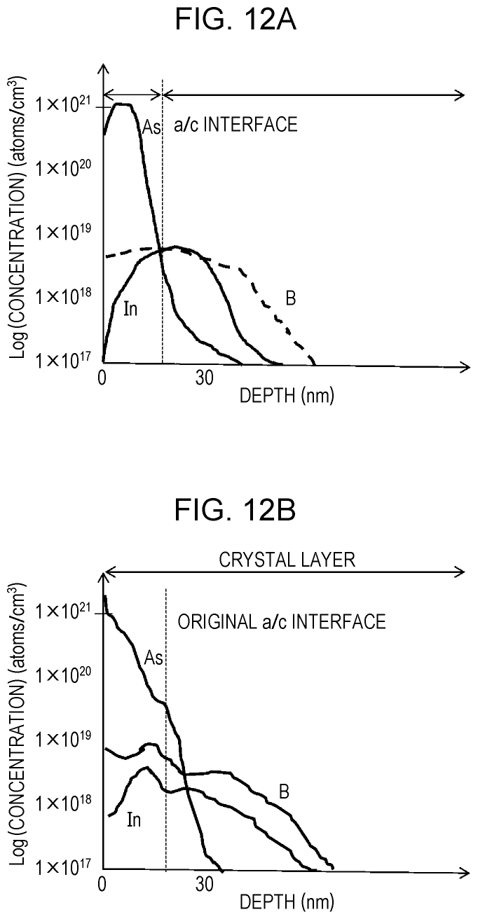

FIGS. 12A and 12B are graphs illustrating an impurity concentration profile in a region along a straight line extending in the depth direction of the semiconductor substrate 130 through the extension formation region according to FIG. 5. Here, the extension formation region is a region where the first extension diffusion layers 306a and 306b are formed or to be formed. FIG. 12A illustrates the concentration distribution (impurity concentration profile) of each impurity (indium (In) and boron (B)) in logarithmic scale in the depth direction of the semiconductor substrate 130 immediately after arsenic ion implantation. The indium distribution after ion implantation has a sharp drop in surface concentration and has a peak concentration at a position slightly deeper than the surface. As illustrated in FIG. 12A, the amorphous layers 310a and 310b has a depth of about 20 nm under the conditions for implanting arsenic and indium according to this example of the manufacturing method. FIGS. 12A and 12B omit the illustration of the concentration distribution of germanium (Ge) and carbon (C). As understood from the above description, the semiconductor substrate 130 may contain other impurities such as fluorine (F).

Next, the semiconductor substrate 130 is subjected to second rapid thermal annealing. In the second rapid thermal annealing, the substrate temperature is raised to 1200° C. to 1350° C. by laser annealing, for example, and is then maintained near the peak temperature for about 1 ms. By this second rapid thermal annealing, first extension diffusion layers 306a and 306b and first pocket diffusion layers 307a and 307b as p-type pocket diffusion layers are formed in the regions of the semiconductor substrate 130 on either side of the gate electrode 302, as illustrated in FIG. 10D. The first extension diffusion layers 306a, 306 are diffusion layers in which arsenic ions are diffused, and have relatively shallow junction surfaces. The first pocket diffusion layers 307a and 307b are diffusion layers in which indium ions and boron ions contained in the p-type pocket impurity-implanted layers 307Aa and 307Ab are diffused. The laser annealing is used here for the second rapid thermal annealing on the millisecond timescale, but so-called millisecond annealing (MSA) such as flash lamp annealing may be used. As for the second rapid thermal annealing, the semiconductor substrate 130 may be subjected to low temperature spike-RTA, for example, which is annealing where the temperature of the semiconductor substrate 130 is raised to about 850° C. to 1050° C. at a temperature increase rate of about 200° C./sec and the peak temperature is maintained for up to about 10 seconds or the peak temperature is not maintained.

FIG. 12B illustrates the concentration distribution, in the depth direction of the semiconductor substrate 130 on the logarithmic scale, of impurities (As, In, and B) contained in the first extension diffusion layers 306a and 306b, which are n-type extension high-concentration diffusion layers formed by the second rapid thermal annealing. After the second rapid thermal annealing, the amorphous layers 310a and 310b formed during ion implantation are restored to crystalline layers. Arsenic diffuses and has a junction depth at a slightly deeper position than immediately after ion implantation. Indium also has a segregated peak near the original amorphous crystal (a/c) interface.

FIG. 12B illustrates the concentration distribution of impurities after being diffused by heat treatment. Boron (B), arsenic (As), and the like may be piled up on the surface of the semiconductor substrate 130 due to surface segregation to the interface between silicon and oxide film during diffusion. In the resultant imaging device, the arsenic concentration profile in the depth direction of the semiconductor substrate 130 is a profile in which the arsenic concentration is at its maximum on the surface of the semiconductor substrate 130. On the other hand, an element with a large mass number such as indium is less affected by the pile-up. Therefore, in this example, even with the pile-up taken into account, the indium concentration profile in the depth direction of the semiconductor substrate 130 has a shape in which the surface concentration distribution shape drops sharply in the resultant imaging device, which is an SSRP. The surface concentration of indium remains low at the Si/SiO₂ interface, thus forming a peak portion due to the electric field effect near the p-n junction with the n-type impurity and a segregation peak portion due to EOR defects formed under the a/c interface after implantation. The presence of a co-implanted impurity such as carbon improves the activation rate of indium, further suppresses the transient enhanced diffusion, and suppresses redistribution of impurities even when additional annealing or the like is performed for the pixel part.

Here, the concept of “pre-amorphization” will be described. It is assumed that a certain region of a semiconductor substrate is amorphized and an impurity having a polarity, that is, a conductivity type is implanted (for example, B ions or the like are implanted) into the region. In this case, it is conceivable that amorphization and impurity implantation are performed in this order. The amorphization in this case may be referred to as pre-amorphization. When ion implantation is performed after the substrate is amorphized, channeling during ion implantation can be suppressed, thus forming a shallow implantation distribution. Specifically, an implantation distribution can be formed in which a so-called tail is small. Then, by performing annealing later, solid phase epitaxial regrowth occurs in which an amorphous layer recovers to a crystalline layer, resulting in a high impurity activation rate and a shallow junction depth. In this example of the manufacturing method, it can be said that pre-amorphization is performed before As ion implantation for forming the first extension diffusion layers 306a and 306b.

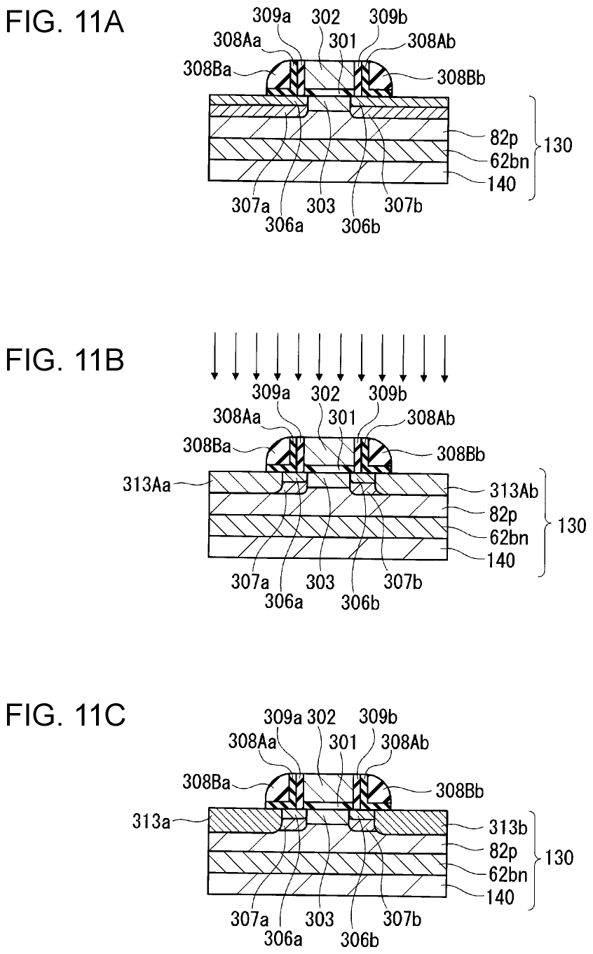

Next, a first insulating film made of silicon oxide having a thickness of about 10 nm and a second insulating film made of silicon nitride having a thickness of about 40 nm are sequentially deposited by chemical vapor deposition (CVD), for example, over the entire surface of the semiconductor substrate 130 including the offset spacers 309a and 309b and the gate electrode 302. Anisotropic etching is then performed on the deposited first and second insulating films, thus forming first sidewalls 308Aa and 308Ab from the first insulating film and second sidewalls 308Ba and 308Bb from the second insulating film on the side surfaces of the gate electrode 302 in the gate length direction, as illustrated in FIG. 11A. Here, the second sidewalls 308Ba and 308Bb may be silicon oxide instead of silicon nitride, or may be formed of a laminated film of silicon oxide and silicon nitride.

As illustrated in FIG. 11B, using the gate electrode 302, offset spacers 309a and 309b, first sidewalls 308Aa and 308Ab, and second sidewalls 308Ba and 308Bb as a mask, arsenic ions, which are an n-type impurity, are implanted with an implantation energy of 30 keV and an implantation dose of about 3×10¹⁵/cm² and then phosphorous ions, which are an n-type impurity, are implanted with an implantation energy of 10 keV and an implantation dose of about 4×10¹⁴/cm² into the semiconductor substrate 130 to form second n-type impurity-implanted layers 313Aa and 313Ab.

As illustrated in FIG. 11C, the semiconductor substrate 130 is then subjected to third rapid thermal annealing. In the third rapid thermal annealing, the substrate temperature is raised to 1200° C. to 1350° C. by laser annealing, for example, and is maintained near the peak temperature for about 1 ms. By this third rapid thermal annealing, an n-type source diffusion layer 313a and an n-type drain diffusion layer 313b, which are n-type high-concentration impurity diffusion layers, are formed in regions of the semiconductor substrate 130 on either side of the first sidewalls 308Aa and 308Ab and the second sidewalls 308Ba and 308Bb. The n-type source diffusion layer 313a and the n-type drain diffusion layer 313b are diffusion layers in which arsenic ions and phosphorus ions are diffused, are connected to the first extension diffusion layers 306a and 306b, and have a deeper junction surface than the first extension diffusion layers 306a and 306b. The laser annealing is used here for the millisecond rapid thermal annealing, but so-called millisecond annealing (MSA) such as flash lamp annealing may be used. As for the third rapid thermal annealing, spike-RTA may be employed, for example, which is annealing where the substrate temperature is raised to about 850° C. to 1050° C. at a temperature increase rate of about 200° C./sec to 250° C./sec and the peak temperature is maintained for up to about 10 seconds or the peak temperature is not maintained.

Note that the second rapid thermal annealing illustrated in FIG. 10D may be omitted. In that case, the third rapid thermal annealing is also used.

According to this manufacturing method, the semiconductor substrate 130 is amorphized with germanium in the step illustrated in FIG. 10A before ion implantation is performed with low energy to form the extension diffusion layers in the step of forming the first n-type impurity-implanted layers 306Aa and 306Ab illustrated in FIG. 10C. Carbon is then implanted as an impurity for preventing diffusion in the step illustrated in FIG. 10B. Carbon has the effect of suppressing transient enhanced diffusion (TED) of impurity atoms.

In the n-type first extension diffusion layers 306a and 306b, as described above, phosphorus (P) may be diffused instead of or together with arsenic (As). Boron can be diffused in the p-type first extension diffusion layers 306a and 306b. Carbon significantly suppresses the diffusion of boron and phosphorus, and is thus effective for the formation of shallow diffusion layers of a p-type field effect transistor (pFET) and an n-type field effect transistor (nFET), respectively.

When carbon is co-implanted into the formation regions of the first extension diffusion layers 306a and 306b, excess point defects in the semiconductor substrate 130 can be removed by the carbon during heat treatment. This may reduce excess point defects introduced by ion implantation. This is advantageous from the viewpoint of suppressing the TED of impurities and keeping the junction depth of each diffusion layer shallow. This effect is particularly beneficial when the impurities are boron and phosphorus or the like.

It can be understood from above that the low-resistance first extension diffusion layers 306a and 306b can be formed by carbon implantation, which have shallow junctions, suppressing junction leakage, and suppressing an increase in resistance value due to dose loss.

As described above, heat treatment is performed to heat the pixel region R1, and the heat treatment may also heat the first peripheral region R2. However, even when such heat treatment is performed, the diffusion suppression effect and related effects based on carbon implantation are obtained.

In one specific example, after the activation heat treatment in FIG. 11C, an interlayer film is deposited in both the pixel region R1 and the first peripheral region R2.

The interlayer film is, for example, a non-doped silicate glass (NSG) film. An opening is then formed in the interlayer film in the pixel region R1. After forming the opening, an impurity region or the like to form the charge storage region Z may be implanted in the pixel region R1. In the pixel region R1, polysilicon is deposited so as to fill the opening, thereby filling an open plug portion. The polysilicon may be doped with phosphorus. Heat treatment is then performed to heat the pixel region R1 including the plug portion. This heat treatment is performed, for example, at 850° C. for about 10 minutes. This heat treatment also heats the first peripheral region R2. In the first peripheral region R2, however, the diffusion suppression effect based on carbon implantation can suppress the redistribution of impurities having a conductivity type, thus maintaining the shallow junction.

The diffusion suppression effect based on carbon implantation is effective even when focusing only on fabrication of the first peripheral transistor 27 in the first peripheral region R2. As described above, the diffusion suppression effect based on carbon implantation can be exerted even when the first peripheral region R2 is heated by an additional step of heat treatment for heating the pixel region R1.

Indium (In) alone may be used as the impurity having the conductivity type of the first pocket diffusion layers 307a and 307b, which are p-type pocket diffusion layers. Indium diffusion can be inhibited by carbon, as with boron diffusion. The activation rate of indium can be enhanced by carbon.

Amorphization may occur during implantation of indium for the first pocket diffusion layers 307a and 307b. To be more specific, while causing amorphization during implantation of indium, it is possible to cause segregation of indium derived from the amorphized portion. For example, such a phenomenon is likely to occur when the indium implantation dose is greater than or equal to 4×10¹³/cm².

The transistor and fabrication method thereof according to the present disclosure can realize a shallow junction and a low resistance for extension diffusion layers accompanying miniaturization, and are useful for a MIS transistor having high driving force and fabrication method thereof.

### Transistors in Pixel Region R1 and First Peripheral Region R2

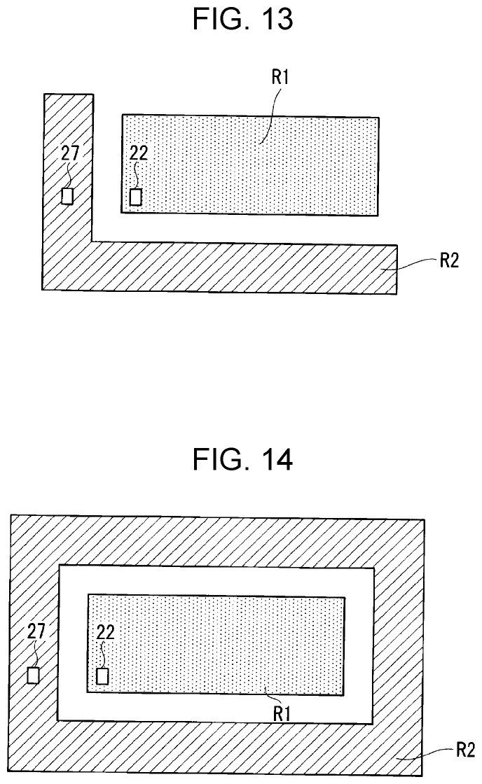

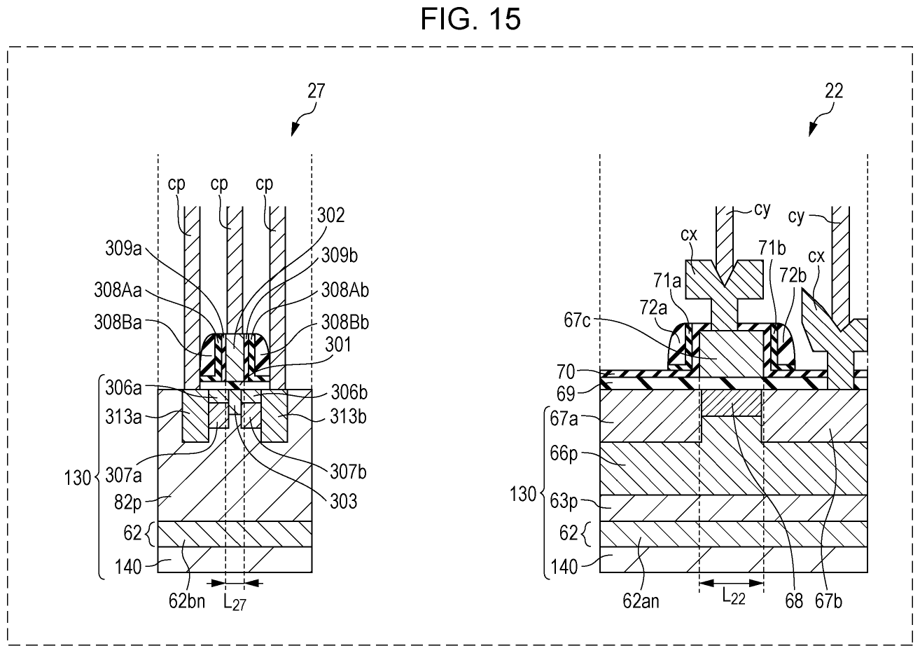

The transistors in the pixel region R1 and the first peripheral region R2 will be further described below with reference to FIGS. 13 to 24. FIGS. 13, 14, 16, 17, 18, 19, 21, and 22 are schematic plan views for explaining transistors in the pixel region and transistors in the peripheral region. FIGS. 15, 20, 23, and 24 are schematic sectional views illustrating transistors in the pixel region and transistors in the peripheral region. FIGS. 13 to 24 omit illustration of the blocking regions 200A and 200B.

Hereinafter, the terms used earlier may be replaced with other terms. For example, one of the n-type source diffusion layer 313a and the n-type drain diffusion layer 313b may be referred to as a source, and the other may be referred to as a drain. The p-type channel diffusion layer 303 may be referred to as a channel region. Note, however, that, hereinafter, the source may be referred to as a source diffusion layer, the drain may be referred to as a drain diffusion layer, and the channel region may be referred to as a channel diffusion layer. The channel region can include part or all of the pocket diffusion layer.

Hereafter, the source of the first peripheral transistor 27 may be referred to as a first source. The drain of the first peripheral transistor 27 may be referred to as a first drain.

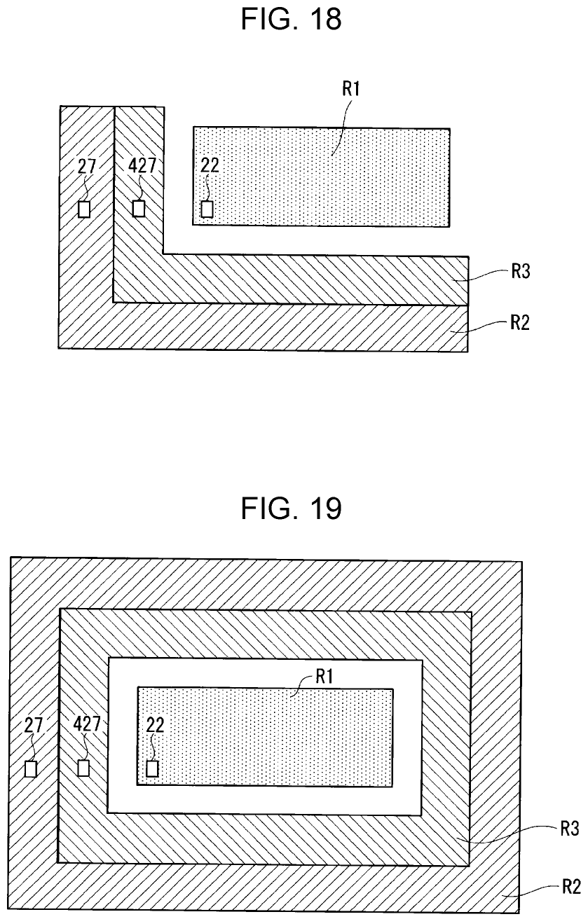

As illustrated in FIGS. 18 and 19, the imaging device may include a second peripheral region R3. In examples of FIGS. 18 and 19, the second peripheral region R3 is positioned between the pixel region R1 and the first peripheral region R2 in a plan view.

One semiconductor substrate 130 may extend in both the pixel region R1 and the first peripheral region R2. Alternatively, the pixel region R1 may be formed using one semiconductor substrate and the first peripheral region R2 may be formed using another semiconductor substrate. One semiconductor substrate 130 may extend across three regions, the pixel region R1, the first peripheral region R2, and the second peripheral region R3. Alternatively, the pixel region R1 may be formed using one semiconductor substrate, the first peripheral region R2 may be formed using another semiconductor substrate, and the second peripheral region R3 may be formed using yet another semiconductor substrate. One semiconductor substrate 130 may extend across the pixel region R1 and the first peripheral region R2, and another semiconductor substrate may be used to form the second peripheral region R3. Alternatively, one semiconductor substrate may be used to form the pixel region R1, and one semiconductor substrate 130 may extend across the first peripheral region R2 and the second peripheral region R3. An imaging device may thus include at least one semiconductor substrate.

Hereinafter, the terms “pixel substrate portion”, “first peripheral substrate portion”, and “second peripheral substrate portion” may be used. The pixel substrate portion refers to a portion of at least one semiconductor substrate 130 belonging to the pixel region R1. The first peripheral substrate portion refers to a portion of the at least one semiconductor substrate 130 belonging to the first peripheral region R2. The second peripheral substrate portion refers to a portion of the at least one semiconductor substrate 130 belonging to the second peripheral region R3.

The pixel substrate portion can be specifically referred to as a pixel semiconductor substrate portion. The first peripheral substrate portion can be specifically referred to as a first semiconductor substrate portion. The second peripheral substrate portion can be specifically referred to as a second semiconductor substrate portion.

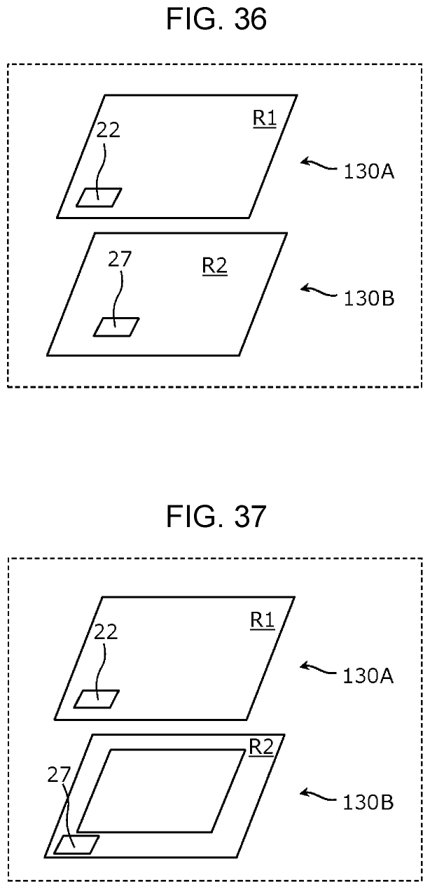

The term “pixel transistor” will be described. A pixel transistor is a transistor included in the pixel region R1. For example, the amplifier transistor 22, the address transistor 24, and the reset transistor 26 may correspond to pixel transistors. FIGS. 13 to 32 illustrate the amplifier transistor 22 as the pixel transistor. The following description is given of a case where the pixel transistor is the amplifier transistor 22. Note, however, that the amplifier transistor 22 can be read as the pixel transistor, address transistor 24 or reset transistor 26 in the following description, unless there is any inconsistency. Elements of transistors such as sources and drains and elements associated with transistors such as traces can also be read appropriately. The same applies to FIGS. 36 to 56B.

A gate insulating film of the pixel transistor may be referred to as a pixel gate insulating film. A gate insulating film of the first peripheral transistor may be referred to as a first peripheral gate insulating film. A gate insulating film of the second peripheral transistor may be referred to as a second peripheral gate insulating film.

FIG. 13 schematically illustrates the amplifier transistor 22 in the pixel region R1 and the first peripheral transistor 27 in the first peripheral region R2 when the configuration of FIG. 1 is adopted. FIG. 14 schematically illustrates the amplifier transistor 22 in the pixel region R1 and the first peripheral transistor 27 in the first peripheral region R2 when the configuration of FIG. 4 is adopted.

In examples of FIGS. 13 and 14, the first peripheral region R2 is positioned outside the pixel region R1. Specifically, the first peripheral region R2 is positioned outside the pixel region R1 in a plan view.

Elements such as an image signal processor (ISP) and a memory may be provided in the first peripheral region R2. In the first peripheral region R2, elements such as ISPs and memories may be stacked in multiple layers.

FIG. 15 illustrates possible configurations of the amplifier transistor 22 in the pixel region R1 and the first peripheral transistor 27 in the first peripheral region R2 in the examples of FIGS. 13 and 14. In the example of FIG. 15, the amplifier transistor 22 is an N-channel MOSFET and the first peripheral transistor 27 is an N-channel MOSFET. Note, however, that the conductivity types of these transistors are not particularly limited as described above. The same applies to transistors 427, 727, and 827 to be described later.

In the example of FIG. 15, the first peripheral transistor 27 is the same as that described with reference to FIG. 5. However, in the example of FIG. 15, it is also possible to adopt other transistors instead of the first peripheral transistor 27. For example, the transistors described with reference to FIG. 6, 7 or 8 can also be adopted.

In the example of FIG. 15, a contact plug cp is connected to the n-type source diffusion layer 313a, which is the first source of the first peripheral transistor 27. A contact plug cp is connected to the n-type drain diffusion layer 313b, which is the first drain of the first peripheral transistor 27. A contact plug cp is connected to the gate electrode 302 of the first peripheral transistor 27.

The contact plugs cp are metal plugs, for example. Examples of metal that can be contained in the contact plugs cp include tungsten, copper, and the like.

In the example of FIG. 15, the amplifier transistor 22 includes a source 67a, a drain 67b, and a gate electrode 67c. The source 67a is an n-type impurity region. The drain 67b is an n-type impurity region. The gate electrode 67c is made of a polysilicon material, for example.

A channel region 68 is formed between the source 67a and the drain 67b. The channel region 68 is an n-type impurity region.

A gate insulating film 69 is formed between the gate electrode 67c and the semiconductor substrate 130, which is the pixel substrate portion. Specifically, the gate insulating film 69 is an oxide film. The gate insulating film 69 contains silicon oxide in one example, and contains silicon dioxide in one specific example.

An offset spacer 70 is formed on the gate electrode 67c and the gate insulating film 69. The offset spacer 70 contains silicon oxide in one example, and contains silicon dioxide in one specific example.

A first sidewall 71a is formed on the offset spacer 70 on the source 67a side. In the example of FIG. 15, the first sidewall 71a has an L-shaped cross section. A second sidewall 72a is formed outside the first sidewall 71a.

A first sidewall 71b is formed on the offset spacer 70 on the drain 67b side. In the example of FIG. 15, the first sidewall 71b has an L-shaped cross section. A second sidewall 72b is formed outside the first sidewall 71b.

The first sidewall 71a contains silicon oxide in one example, and contains silicon dioxide in one specific example. The same applies to the first sidewall 71b. In one example, the second sidewall 72a has a laminated structure including a plurality of insulating layers. In one specific example, the second sidewall 72a includes a silicon dioxide layer and a silicon nitride layer. The same applies to the second sidewall 72b.

A through-hole is formed in the offset spacer 70 on the gate electrode 67c. A contact plug cx is connected to the gate electrode 67c through the through-hole. A through-hole is formed in the gate insulating film 69 and the offset spacer 70 on the drain 67b. A contact plug cx is connected to the drain 67b through the through-hole.

The contact plug cx is a polysilicon plug, for example. The contact plug cx may be doped with an impurity such as phosphorus to enhance the conductivity.

It is also possible to adopt a configuration in which the contact plug cx is connected to the source 67a. Specifically, it is also possible to form a through-hole in the gate insulating film 69 and the offset spacer 70 on the source 67a, and to connect the contact plug cx to the source 67a through the through-hole.

The contact plug cx connected to the gate electrode 67c is connected to a plug cy. The contact plug cx connected to the drain 67b is connected to a plug cy. When there is a contact plug cx connected to the source 67a, the contact plug cx may be connected to the plug cy.

The plug cy is a metal plug, for example. Examples of metal that can be contained in the plug cy include tungsten, copper, and the like.

As can be understood from the description with reference to FIGS. 1 to 15, the imaging device according to this embodiment includes the pixel region R1 and the first peripheral region R2. The pixel region R1 has a pixel substrate portion. The first peripheral region R2 has a first peripheral substrate portion. Signals are transmitted between the pixel region R1 and the first peripheral region R2. Specifically, the first peripheral region R2 is located outside the pixel region R1. More specifically, the first peripheral region R2 is located outside the pixel region R1 in a plan view.

The pixel region R1 has an amplifier transistor 22. The amplifier transistor 22 is provided in the pixel substrate portion. The first peripheral region R2 has a first peripheral transistor 27. The first peripheral transistor 27 is provided in the first peripheral substrate portion. In one example, the first peripheral transistor 27 is a logic transistor. The first peripheral transistor 27 may be a planar transistor or a three-dimensional structure transistor. A first example of the three-dimensional structure transistor is a fin field-effect transistor (FinFET). A second example of the three-dimensional structure transistor is a gate-all-around (GAA) FET such as a nanowire FET. A third example of the three-dimensional structure transistor is a nanosheet FET.

In this embodiment, the amplifier transistor 22 outputs a signal voltage corresponding to signal charges obtained by photoelectric conversion. Photoelectric conversion takes place in the photoelectric conversion layer 12. Specifically, a path for guiding signal charges from the photoelectric conversion layer 12 to the charge storage region Z and a path for guiding signal charges from the charge storage region Z to the gate electrode 67c of the amplifier transistor 22 are formed. In the example of FIG. 3, the charge storage region Z corresponds to the impurity region 60n. As described above, the charge storage region Z is included in the charge storage node FD.

In this embodiment, as illustrated in FIG. 15, a gate length L₂₇ of the first peripheral transistor 27 is shorter than a gate length L₂₂ of the amplifier transistor 22.

A ratio L₂₇/L₂₂ of the gate length L₂₇ of the first peripheral transistor 27 to the gate length L₂₂ of the amplifier transistor 22 is, for example, less than or equal to 0.8, and may be less than or equal to 0.34. This ratio is, for example, more than or equal to 0.01, and may be more than or equal to 0.05.

Here, the gate length refers to the dimension of the gate electrode in the direction from the source to the drain or from the drain to the source. A gate width refers to the dimension of the gate electrode in a direction orthogonal to the direction of the gate length in a plan view. The direction orthogonal to the gate length direction in a plan view may also be referred to as a depth direction.

In this embodiment, the gate insulating film 301 of the first peripheral transistor 27 is thinner than the gate insulating film 69 of the amplifier transistor 22.

A ratio T₃₀₁/T₆₉ of a thickness T₃₀₁ of the gate insulating film 301 of the first peripheral transistor 27 to a thickness T₆₉ of the gate insulating film 69 of the amplifier transistor 22 is, for example, less than or equal to 0.7, or may be less than or equal to 0.36. This ratio is, for example, more than or equal to 0.1, and may be more than or equal to 0.2.

In one example, the first peripheral transistor 27 has a first specific layer. The first specific layer is positioned inside the first peripheral substrate portion. The first specific layer contains a conductive impurity. Specifically, the first specific layer contains a heavy conductive impurity. A configuration in which the first specific layer contains a heavy conductive impurity is suitable for improving the performance of the imaging device. This configuration is specifically suitable for improving the performance of the imaging device, taking into account the presence of the first peripheral transistor 27 in the first peripheral region R2.

The conductive impurity is an impurity having a conductivity type. That is, the conductive impurity is a p-type or an n-type impurity. The conductive impurity can be a p-type impurity. Examples of the p-type conductivity impurity include boron (B), gallium (Ga), indium (In), and the like. The conductive impurity can also be an n-type impurity. Examples of the n-type conductivity impurity include phosphorus (P), arsenic (As), antimony (Sb), bismuth (Bi), and the like.

The heavy conductive impurity refers to a p-type conductivity impurity having an atomic number greater than or equal to that of gallium, and also refers to an n-type conductivity impurity having an atomic number greater than or equal to that of arsenic. Examples of the p-type heavy conductivity impurity include gallium, indium, and the like. Examples of the n-type heavy conductivity impurity include antimony, bismuth, and the like. The heavy conductive impurity may be a p-type impurity having an atomic number greater than or equal to that of gallium or an n-type impurity having an atomic number greater than or equal to that of antimony.

The first peripheral transistor 27 may have an impurity concentration profile in a region along a straight line extending in the depth direction of the first peripheral substrate portion through the first specific layer, in which the concentration of the heavy conductive impurity reaches a peak at a position deeper than the upper surface of the first peripheral substrate portion. This configuration is suitable for improving the performance of the imaging device. Specifically, this configuration can reduce the concentration of the heavy conductive impurity in the upper surface of the first peripheral substrate portion. Therefore, a threshold voltage of the first peripheral transistor 27 is less likely to fluctuate due to fluctuations in the impurity concentration in the upper surface. The straight line passing through the first specific layer may extend between the first source 313a and the first drain 313b of the first peripheral transistor 27. Even in that case, the concentration of the heavy conductive impurity in the upper surface can be reduced, and thus the movement of charges between the first source 313a and the first drain 313b is less likely to be hindered by the impurities in the upper surface. In other words, charge mobility is less likely to degrade. Therefore, the driving force of the first peripheral transistor 27 is less likely to deteriorate. In this context, the upper surface of the first peripheral substrate portion is the main surface on the side where the first peripheral transistor 27 is provided. Specifically, the impurity concentration profile may be a super steep retrograde profile (SSRP).

In an impurity concentration profile in a region along a straight line extending in the depth direction of the first peripheral substrate portion through the first specific layer, the indium concentration may reach a peak at a position deeper than the upper surface of the first peripheral substrate portion. In the impurity concentration profile, the gallium concentration may reach a peak at a position deeper than the upper surface of the first peripheral substrate portion. In the impurity concentration profile, the antimony concentration may reach a peak at a position deeper than the upper surface of the first peripheral substrate portion. In the impurity concentration profile, the bismuth concentration may reach a peak at a position deeper than the upper surface of the first peripheral substrate portion. In the impurity concentration profile, the concentration of the conductive impurity may reach a peak at a position deeper than the upper surface of the first peripheral substrate portion. These impurity concentration profiles may each specifically be the SSRP.

The first peripheral substrate portion includes a support substrate 140 and a film body. The film body is provided above the support substrate 140. The film body includes a low-concentration layer and a first specific layer. The low-concentration layer includes an upper surface of the film body. The concentration of the conductive impurities in the low-concentration layer is lower than the concentration of the conductive impurities in the support substrate 140. The first specific layer is located below the low-concentration layer. The first peripheral transistor 27 includes the low-concentration layer and the first specific layer in this order from top to bottom. This configuration is suitable for improving the performance of the imaging device. Specifically, this configuration can lower the concentration of a heavy conductive impurity in the upper surface of the first peripheral substrate portion. The film body typically has a single crystal structure.

In a first definition, “the concentration of conductive impurities” in the expression “the concentration of conductive impurities in the low-concentration layer is lower than the concentration of conductive impurities in the support substrate 140” is the maximum value of the concentration. In a second definition, “the concentration of conductive impurities” in this expression is the average concentration. In the above example, when it can be said that “the concentration of conductive impurities in the low-concentration layer is lower than the concentration of conductive impurities in the support substrate 140” based on at least one of the first and second definitions, it is assumed that “the concentration of conductive impurities in the low-concentration layer is lower than the concentration of conductive impurities in the support substrate 140”.

The film body is, for example, an epitaxial film. The epitaxial film can be formed by epitaxial growth on the support substrate 140. The epitaxial film immediately after being formed by epitaxial growth has a low impurity concentration. By adjusting the depth of impurity implantation into the epitaxial film, a low-concentration layer having a low conductive impurities concentration and a conductive impurity layer can be formed.

In the examples of FIGS. 5 and 15, the n-type semiconductor layer 62bn and the p-type impurity region 82p can be included in the film body. The upper surface of the p-type impurity region 82p may constitute the upper surface of the low-concentration layer.

The concentration of conductive impurities in the upper surface of the low-concentration layer is less than 5×10¹⁶ atoms/cm³, for example. The low-concentration layer may be a non-doped layer.

In one example, a method for manufacturing an imaging device includes a first step and a second step. In the first step, a film body is formed by epitaxial growth. In the second step, a first specific layer is formed by implanting a heavy conductive impurity into the film body.

In this embodiment, the first specific layer contains a diffusion suppression type. This configuration is suitable for improving the performance of the imaging device. This configuration is specifically suitable for improving the performance of the imaging device, taking into account the presence of the first peripheral transistor 27 in the first peripheral region R2. The diffusion suppression type is at least one type of impurity that suppresses transient enhanced diffusion of conductive impurities. The diffusion suppression type can also inhibit transient enhanced diffusion of a heavy conductive impurity. The diffusion suppression type may include at least one selected from the group consisting of carbon, nitrogen, and fluorine.

In this embodiment, the first specific layer contains an amorphization type. This configuration is suitable for improving the performance of the imaging device. This configuration is specifically suitable for improving the performance of the imaging device, taking into account the presence of the first peripheral transistor 27 in the first peripheral region R2. The amorphization type is at least one type of impurity that causes amorphization of the implantation target. The amorphization type may include at least one selected from the group consisting of germanium, silicon, and argon. The amorphization type may be traces of pre-amorphization that can enhance the effect of suppressing the diffusion of conductive impurities by an impurity exemplified by carbon.

In one example, the first peripheral transistor 27 includes an n-type source diffusion layer 313a as the first source and an n-type drain diffusion layer 313b as the first drain. At least one of the first source or the first drain may include a first specific layer.

In one example, a channel diffusion layer 303 is provided below the gate of the first peripheral transistor 27. The channel diffusion layer 303 may include a first specific layer. The expression “below the gate of the first peripheral transistor 27” as used herein refers to a portion of the charge path between the first source and the first drain, which overlaps the gate electrode 302 in a plan view.

In one example, the first peripheral transistor 27 includes a first extension diffusion layer. The first extension diffusion layer EX1 is adjacent to the first source or the first drain. The first extension diffusion layer is shallower than the first source and the first drain. The first extension diffusion layer includes a first specific layer. The first extension diffusion layer is the first extension diffusion layer 306a or the first extension diffusion layer 306b.

The expression “the extension diffusion layer is adjacent to the source” specifically means that the extension diffusion layer is connected to the source. The same applies to similar expressions such as “the extension diffusion layer is adjacent to the drain”, “the pocket diffusion layer is adjacent to the source”, and “the pocket diffusion layer is adjacent to the drain”. Specifically, it means that those elements are connected.

The expression “the first extension diffusion layer is shallower than the first source and the first drain” means that the deepest part of the first extension diffusion layer is shallower than the deepest part of the first source and the first drain with respect to the depth direction of the first peripheral substrate portion. In this context, “shallow” can also be referred to as “shallow junction depth”. The boundaries between the extension diffusion layer, source, and drain are junctions. The junctions are each a portion where the concentration of an n-type impurity is equal to the concentration of a p-type impurity.

The expression “the first extension diffusion layer includes the first specific layer” is intended to include both a configuration in which the first specific layer is contained within the first extension diffusion layer and a configuration in which the first specific layer protrudes from the first extension diffusion layer. The same applies to similar expressions such as “the first pocket diffusion layer includes the first specific layer”.

In the illustrated example, the first peripheral transistor 27 includes a first extension diffusion layer 306a and a first extension diffusion layer 306b. The first extension diffusion layer 306a is adjacent to the first source. The first extension diffusion layer 306a is shallower than the first source and the first drain. The first extension diffusion layer 306b is adjacent to the first drain. The first extension diffusion layer 306b is shallower than the first source and the first drain. The first extension diffusion layer 306a and the first extension diffusion layer 306b may include a first specific layer.

In one example, the first peripheral transistor 27 includes a first pocket diffusion layer. The first pocket diffusion layer is adjacent to the first source or the first drain. The first pocket diffusion layer may include a first specific layer. The first pocket diffusion layer is a first pocket diffusion layer 307a or a first pocket diffusion layer 307b.

In the illustrated example, the first peripheral transistor 27 includes a first pocket diffusion layer 307a and a first pocket diffusion layer 307b. The first pocket diffusion layer 307a is adjacent to the first source. The first pocket diffusion layer 307b is adjacent to the first drain. The first pocket diffusion layer 307a and the first pocket diffusion layer 307b may include a first specific layer.

Only one selected from the group consisting of the channel diffusion layer 303, the first source, the first drain, the first extension diffusion layer, and the first pocket diffusion layer may include the first specific layer. Specifically, one selected from the group consisting of the channel diffusion layer 303, the first source, the first drain, the first extension diffusion layer 306a, the first extension diffusion layer 306b, the first pocket diffusion layer 307a, and the first pocket diffusion layer 307b may contain the first specific layer.

Two or more selected from the group consisting of the channel diffusion layer 303, the first source, the first drain, the first extension diffusion layer, and the first pocket diffusion layer may include the first specific layer. Specifically, two or more selected from the group consisting of the channel diffusion layer 303, the first source, the first drain, the first extension diffusion layer 306a, the first extension diffusion layer 306b, the first pocket diffusion layer 307a, and the first pocket diffusion layer 307b may include the first specific layer. When two or more selected from the above group include the first specific layer, the type of the first specific layer included therein may be the same or different. For example, the diffusion suppression type of the first source may be carbon, and the diffusion suppression type of the first extension diffusion layer may be nitrogen and fluorine. In this case, the conductive impurities contained therein may have the same conductivity type or different conductivity types. For example, one of the first source and the first pocket diffusion layer may contain boron and have a p-type conductivity, while the other may contain phosphorus and have an n-type conductivity.

As can be understood from the above, the number of first specific layers included in the imaging device may be one or more than one.

An example of a situation where the technique using the first specific layer can contribute to such improvement in performance will be described below.

Heat treatment may be performed during the manufacturing process of the imaging device. The heat treatment can reduce defects in the pixel substrate portion in the pixel region R1. Reducing defects can suppress dark current in the imaging device. In the first peripheral region R2, on the other hand, the necessity of reducing defects is not necessarily high. It may be rather necessary in the first peripheral region R2 to prevent performance degradation of the first peripheral transistor 27 due to diffusion of conductive impurities caused by heat treatment. Such performance degradation is, for example, an unwanted change in threshold voltage of the first peripheral transistor 27.

Particularly, in this embodiment, the first peripheral transistor 27 includes at least one of a first feature or a second feature. The first feature is that the gate length L₂₇ of the first peripheral transistor 27 is shorter than the gate length L₂₂ of the amplifier transistor 22. The second feature is that the gate insulating film 301 of the first peripheral transistor 27 is thinner than the gate insulating film 69 of the amplifier transistor 22. When the first peripheral transistor 27 has a fine structure that includes at least one of the first feature or the second feature, the performance of the first peripheral transistor 27 is easily affected by the diffusion redistribution of the conductive impurities due to additional heat treatment.

In this regard, as described above, the first specific layer contains a heavy conductive impurity in one example of this embodiment. Since the heavy conductive impurity has a large mass number, diffusion of the heavy conductive impurity is less likely to occur, and a situation where the as-implanted concentration profile immediately after the implantation is significantly changed by the diffusion is less likely to occur. The first specific layer includes a diffusion suppression type. The diffusion suppression type can suppress the diffusion of conductive impurities. The diffusion suppressing effect of the heavy conductive impurity and the diffusion suppressing effect of the diffusion suppression type can both prevent the performance degradation of the first peripheral transistor 27. Therefore, it is possible to suppress a disadvantage such as the performance degradation of the first peripheral transistor 27 while receiving the advantage of suppressing the dark current.

Specifically, a first example is considered in which the first specific layer is included in the first extension diffusion layer and the gate length L₂₇ of the first peripheral transistor 27 is shorter than the gate length L₂₂ of the amplifier transistor 22. Heat treatment may be performed in the manufacturing process of the imaging device. The heat treatment can reduce defects in the pixel substrate portion in the pixel region R1. Reducing defects can suppress dark current in the imaging device. When L₂₇<L₂₂, on the other hand, the first peripheral transistor 27 is more likely to exhibit a short-channel effect due to heating than the amplifier transistor 22. The short-channel effect can change the threshold voltage of the transistor from a desired value, resulting in performance degradation of the transistor. As described above, the heat treatment can bring about the advantage of suppressing the dark current in the pixel region R1, and can also bring about the disadvantage of manifesting the short-channel effect in the first peripheral region R2.

In this regard, in the first example, the first extension diffusion layer contains a heavy conductive impurity as the conductive impurity, and further includes the diffusion suppression type. The diffusion suppressing effect based on these can suppress the short-channel effect in the first peripheral transistor 27. Therefore, it is possible to suppress the above disadvantage of the short-channel effect while receiving the advantage of suppressing dark current.

As described above, in the first example, the short-channel effect of the first peripheral transistor 27 due to the heat treatment is suppressed by the diffusion suppression effect that is exerted in the first extension diffusion layer. This means that the margin of thermal budget of heat treatment is increased compared to the case with no diffusion suppression effect. Therefore, by increasing the time, temperature, and the like for heat treatment, the dark current can be suppressed in the pixel region R1 without manifesting the short-channel effect in the first peripheral transistor 27.

A second example is considered in which the first specific layer is included in at least one of the first source or the first drain, and the gate length L₂₇ of the first peripheral transistor 27 is shorter than the gate length L₂₂ of the amplifier transistor 22. In the second example, similarly to the first example, the dark current can be suppressed in the pixel region R1 without manifesting the short-channel effect in the first peripheral transistor 27 by increasing the time, temperature, and the like for heat treatment.

A third example is considered in which the first specific layer is included in the first pocket diffusion layer and the gate length L₂₇ of the first peripheral transistor 27 is shorter than the gate length L₂₂ of the amplifier transistor 22. In the third example, variations in the threshold voltage of the first peripheral transistor 27 can be suppressed by the diffusion suppression effect that is exerted in the first pocket diffusion layer. Therefore, according to the third example, similarly to the first example, the dark current can be suppressed in the pixel region R1 without causing variations in threshold voltage of the first peripheral transistor 27, by increasing the time, temperature, and the like for heat treatment.

A fourth example is considered in which the first specific layer is included in the channel diffusion layer 303 below the gate of the first peripheral transistor 27, and the gate length L₂₇ of the first peripheral transistor 27 is shorter than the gate length L₂₂ of the amplifier transistor 22. In the fourth example, similarly to the first example, the dark current can be suppressed in the pixel region R1 without manifesting the short-channel effect in the first peripheral transistor 27, by increasing the time, temperature, and the like for heat treatment.

As described above, the semiconductor substrate 130 may be a substrate having a film body provided on its surface by epitaxial growth. The same applies to the pixel substrate portion, the first peripheral substrate portion, and the second peripheral substrate portion. The film body derived from epitaxial growth easily reduce unintended carbon content. This can contribute to suppression of dark current in the pixel region R1. This also makes it easier to make a difference in the concentration of the diffusion suppression type such as carbon between the pixel region R1 and the first peripheral region R2.

As described above, the semiconductor substrate 130 may be a p-type silicon substrate. Note, however, that the semiconductor substrate 130 may be an n-type silicon substrate. The same applies to the pixel substrate portion, the first peripheral substrate portion, and the second peripheral substrate portion.

In one example, the photoelectric conversion layer 12 is laminated on the pixel substrate portion. In a typical example, when fabricating the pixel region R1 having such a configuration, the heat treatment as described above is performed. For this reason, the imaging device including the pixel region R1 having this configuration can receive the above effect of suppressing dark current while suppressing performance degradation of the first peripheral transistor 27. Note that “the photoelectric conversion layer 12 is laminated on the pixel substrate portion” is a concept that includes a configuration in which an element such as an insulating layer is interposed between the photoelectric conversion layer 12 and the pixel substrate portion. It can also be said that the photoelectric conversion layer 12 is supported by the pixel substrate portion.

In one example, the pixel substrate portion and the first peripheral substrate portion are included in a single semiconductor substrate 130. In the imaging device having such a configuration, the first peripheral region R2 is easily heated by the heat treatment for heating the pixel region R1. The imaging device having such a configuration easily receives the above effect of suppressing the dark current while suppressing performance degradation of the first peripheral transistor 27. Typically, in the imaging device having such a configuration, the first peripheral region R2 is simultaneously heated in the heat treatment for heating the pixel region R1.

The photoelectric conversion layer 12 may be a panchromatic film. The photoelectric conversion layer 12 may be a film that has no sensitivity to light in some wavelength range, such as an orthochromatic film.

The first source, the first drain, and the first extension diffusion layer may contain conductive impurities of a first conductivity type. The same applies to the first extension diffusion layer 306a and the first extension diffusion layer 306b. On the other hand, the first pocket diffusion layer and the channel diffusion layer 303 may contain conductive impurities of a second conductivity type. The same applies to the first pocket diffusion layer 307a and the first pocket diffusion layer 307b. The first conductivity type is the n-type or p-type. The second conductivity type is opposite to the first conductivity type. The second conductivity type is the p-type or n-type.

In one specific example, the first peripheral transistor 27 is a logic transistor. The first peripheral transistor 27 is capable of digital operations. Speed may be prioritized in such a first peripheral transistor 27. In order for the transistor to operate at high speed, it is advantageous that the transistor is a fine transistor. The fact that the transistor is a fine transistor is also advantageous from the viewpoint of ensuring a high driving force of the transistor. In this respect, the gate length L₂₇ of the first peripheral transistor 27 is shorter than the gate length L₂₂ of the amplifier transistor 22 in this specific example. The gate insulating film 301 of the first peripheral transistor 27 is thinner than the gate insulating film 69 of the amplifier transistor 22. The short gate length L₂₇ and the thin gate insulating film 301 can be advantageous from the viewpoint of operating the first peripheral transistor 27 at high speed and with high driving force. This advantage derived from the short gate length L₂₇ and the thin gate insulating film 301 can be achieved, for example, when the first peripheral transistor 27 is a planar transistor. The first peripheral transistor 27 in this specific example is positioned, for example, between the control section and the pixel driver section.

In one example, the first specific layer contains germanium. As can be understood from the above description, germanium can pre-amorphize the inside of the first peripheral substrate portion during the manufacturing process of the first peripheral transistor 27. In the pre-amorphized region, the effect of suppressing the diffusion of conductive impurities by impurities exemplified by carbon is likely to increase. Germanium in this example can be traces of pre-amorphization that can enhance the effect of suppressing the diffusion of conductive impurities by impurities exemplified by carbon.

The first specific layer may contain silicon, argon, krypton or xenon instead of or together with germanium. More generally, the first specific layer may contain at least one element selected from the group consisting of germanium, silicon, argon, krypton, and xenon. These elements can be traces of pre-amorphization that can enhance the effect of suppressing the diffusion of conductive impurities by impurities exemplified by carbon.

In one example, the first specific layer includes an EOR defect. EOR defects can segregate a heavy conductive impurity. The EOR defect can be traces of pre-amorphization that can enhance the effect of suppressing the diffusion of conductive impurities by impurities exemplified by carbon.

In one example, the first specific layer includes a first segregation portion in which a heavy conductive impurity is segregated in the depth direction of the first peripheral substrate portion. Such a first specific layer may have a portion with a high concentration of the heavy conductive impurity. The first segregation portion may be formed in the EOR defect, for example.

In one example, the first specific layer includes a second segregation portion in which the diffusion-suppression type is segregated in the depth direction of the first peripheral substrate portion. As described above, in the pre-amorphized region in the first peripheral substrate portion, the effect of suppressing the diffusion of conductive impurities by impurities exemplified by carbon is likely to increase. In the manufacturing process of the first peripheral transistor 27, when heat treatment is performed in a state where the first peripheral substrate portion is amorphized, the second segregation portion may be formed in a region just below the amorphous crystal (a/c) interface before the heat treatment. The second segregation portion in this example can be traces of pre-amorphization that can enhance the effect of suppressing the diffusion of conductive impurities by impurities exemplified by carbon.

In the expression “segregation portion”, “segregation” means that impurities are unevenly distributed, and is not intended to limit the formation process of the segregation portion.

The segregation portion will be described using an impurity concentration profile, which is the relationship between the impurity concentration and the depth in the first peripheral substrate portion. When there is a segregation portion, in the above impurity concentration profile, the concentration has a minimum value at a first depth corresponding to the depth of the amorphous crystal (a/c) interface before heat treatment. In the impurity concentration profile, the concentration has a maximum value at a second depth, which is deeper than the first depth. The segregation portion refers to a portion of the first peripheral substrate portion, which is deeper than the first depth and has an impurity concentration higher than the minimum value. In one specific example, the first depth is a position substantially corresponding to the depth of the amorphous crystal (a/c) interface before heat treatment. In the indium concentration profile illustrated in FIG. 12B, the “original a/c interface” substantially corresponds to the first depth and an upward convex portion just below the “original a/c interface” corresponds to the segregation portion.

In this embodiment, the pixel region R1 includes the charge storage region Z. In the charge storage region Z, charges generated by photoelectric conversion are stored. The charge storage region Z is an impurity region. In the example of FIG. 3, the charge storage region Z corresponds to the impurity region 60n. Specifically, the photoelectric converter 10 carries out photoelectric conversion, and the generated charges are sent to the charge storage region Z through the plug cy and the contact plug cx and stored in the charge storage region Z.

In one example, the first segregation portion is shallower than the charge storage region Z. The expression “the first segregation portion is shallower than the charge storage region Z” means that the deepest part of the first segregation portion is shallower than the deepest part of the charge storage region Z in the depth direction of the pixel substrate portion or the first peripheral substrate portion.

In one example, the second segregation portion is shallower than the charge storage region Z. The expression “the second segregation portion is shallower than the charge storage region Z” means that the deepest part of the second segregation portion is shallower than the deepest part of the charge storage region Z in the depth direction of the pixel substrate portion or the first peripheral substrate portion.

In one example, the concentration of carbon in the first specific layer is higher than the concentration of carbon in the charge storage region Z. Carbon in the first specific layer can suppress diffusion of conductive impurities. The presence of carbon in the charge storage region Z, on the other hand, can cause dark current. Therefore, the feature that the concentration of carbon in the first specific layer is higher than the concentration of carbon in the charge storage region Z can be possessed by a high-performance imaging device. In the expression “the concentration of carbon in the first specific layer is higher than the concentration of carbon in the charge storage region Z”, the concentration of carbon in the charge storage region Z may be zero or higher than zero.

The boundary of the charge storage region Z is a junction. As described above, the junction is a portion where the n-type impurity concentration is equal to the p-type impurity concentration.

In a first definition, the “concentration of carbon” in the expression “the concentration of carbon in the first specific layer is higher than the concentration of carbon in the charge storage region Z” is the maximum value of the concentration. In a second definition, the “concentration of carbon” in this expression is the average concentration. In the above example, when it can be said that “the concentration of carbon in the first specific layer is higher than the concentration of carbon in the charge storage region Z” based on at least one of the first definition or the second definition, it is assumed that “the concentration of carbon in the first specific layer is higher than the concentration of carbon in the charge storage region Z”.

A case is considered where the diffusion suppression type is carbon and the first specific layer is included in the first extension diffusion layer. A ratio C2/C1 of the carbon concentration C2 in the first specific layer to the carbon concentration C1 in the charge storage region Z is greater than or equal to 1×105, for example. This ratio is less than or equal to 1×10¹¹, for example.

A case is considered where the diffusion suppression type is carbon and the first specific layer is included in the first extension diffusion layer. The concentration of the conductive impurities in the first extension diffusion layer is more than or equal to 1×10¹⁷ atoms/cm³, for example. The concentration of carbon in the first extension diffusion layer is more than or equal to 1×10¹⁷ atoms/cm³, for example. The concentration of the conductive impurities in the first extension diffusion layer is less than or equal to 1×10²² atoms/cm³, for example. The concentration of carbon in the first extension diffusion layer is less than or equal to 1×10²² atoms/cm³, for example. The same applies to both first extension diffusion layers 306a and 306b.

In one example, the concentration of carbon in the charge storage region Z is substantially zero. Here, the fact that the carbon concentration in the charge storage region Z is substantially zero means that the carbon concentration in the charge storage region Z is less than 5×10¹⁶ atoms/cm³, for example. The charge storage region Z may be free of carbon, which is intentionally provided. The carbon concentration in the charge storage region Z may be zero atoms/cm³.

In one example, the concentration of carbon in the first specific layer is higher than the concentration of carbon in the channel region 68 below the gate of the amplifier transistor 22. This configuration is advantageous from the viewpoint of reducing dark current. The expression “below the gate of the amplifier transistor 22” as used herein refers to a portion of the charge path between the source 67a and the drain 67b, which overlaps the gate electrode 67c in a plan view. In the expression “the concentration of carbon in the first specific layer is higher than the concentration of carbon in the channel region 68 below the gate of the amplifier transistor 22”, the concentration of carbon in the channel region 68 below the gate of the amplifier transistor 22 may be zero or higher than zero.

In a first definition, the “concentration of carbon” in the expression “the concentration of carbon in the first specific layer is higher than the concentration of carbon in the channel region 68 below the gate of the amplifier transistor 22” is the maximum value of the concentration. In a second definition, the “concentration of carbon” in this expression is the average concentration. In the above example, when it can be said that “the concentration of carbon in the first specific layer is higher than the concentration of carbon in the channel region 68 below the gate of the amplifier transistor 22” based on at least one of the first definition or the second definition, it is assumed that “the concentration of carbon in the first specific layer is higher than the concentration of carbon in the channel region 68 below the gate of the amplifier transistor 22”.

In one example, the amplifier transistor 22 has a pixel specific layer. The pixel specific layer is positioned in the pixel substrate portion. The pixel specific layer contains a conductive impurity.

The pixel specific layer and the first specific layer may have the same composition or different compositions of conductive impurities.

The pixel specific layer may contain a heavy conductive impurity. The heavy conductive impurity contained in the pixel specific layer may be the same as or different from a heavy conductive impurity contained in the first specific layer. For example, the heavy conductive impurity in the first specific layer may be indium, and the heavy conductive impurity in the pixel specific layer may be antimony.

The amplifier transistor 22 may have an impurity concentration profile in a region along a straight line extending in the depth direction of the pixel substrate portion through the pixel specific layer, in which the concentration of the heavy conductive impurity reaches a peak at a position deeper than the upper surface of the pixel substrate portion. In this context, the upper surface of the pixel substrate portion is the main surface on which the amplifier transistor 22 is provided. This impurity concentration profile may specifically be an SSRP.

In the impurity concentration profile in the region along the straight line extending in the depth direction of the pixel substrate portion through the pixel specific layer, the indium concentration may reach a peak at a position deeper than the upper surface of the pixel substrate portion. In the impurity concentration profile, the gallium concentration may reach a peak at a position deeper than the upper surface of the pixel substrate portion.

In the impurity concentration profile, the antimony concentration may reach a peak at a position deeper than the upper surface of the pixel substrate portion. In the impurity concentration profile, the bismuth concentration may reach a peak at a position deeper than the upper surface of the pixel substrate portion. In the impurity concentration profile, the concentration of the conductive impurities may reach a peak at a position deeper than the upper surface of the pixel substrate portion. These impurity concentration profiles may each specifically be the SSRP.

The pixel substrate portion has a support substrate 140 and a film body. The film body is provided above the support substrate 140. The film body includes a low-concentration layer and a pixel specific layer. The low-concentration layer includes the upper surface of the film body. The concentration of the conductive impurities in the low-concentration layer is lower than the concentration of the conductive impurities in the support substrate 140. The pixel specific layer is positioned below the low-concentration layer. The amplifier transistor 22 includes a low-concentration layer and a pixel specific layer in this order from top to bottom. The film body of the pixel substrate portion may have features similar to those of the film body of the first peripheral substrate portion.

In one example, at least one of the source 67a or the drain 67b of the amplifier transistor 22 includes a pixel specific layer.

In one example, there is a channel region 68 below the gate of the amplifier transistor 22. The channel region 68 may include a pixel specific layer. The expression “below the gate of the amplifier transistor 22” as used herein refers to a portion of the charge path between the second source 67a and the second drain 67b, which overlaps the gate electrode 67c in a plan view.

A configuration may also be adopted in which the first specific layer of the first peripheral transistor 27 contains a heavy conductive impurity and the amplifier transistor 22 does not contain a heavy conductive impurity in the pixel substrate portion. This configuration can avoid implantation of a heavy conductive impurity into the pixel substrate portion during fabrication of the amplifier transistor 22. The amplifier transistor 22 is thus less likely to have crystal defects.

In one example, the amplifier transistor 22 includes no extension diffusion layer.

As the material of the gate electrode 302 in the first peripheral transistor 27, polysilicon doped with phosphorus can also be used, for example. In that case, however, when the first peripheral region R2 is also heated by heat treatment for heating the pixel region R1, phosphorus may seep into the first peripheral substrate portion. In this regard, a high-k metal gate is formed in the first peripheral transistor 27 in the imaging device according to the example. This makes it possible to suppress or avoid impurities from seeping into the first peripheral substrate portion from the gate electrode 302. This can contribute to suppressing the short-channel effect in the first peripheral transistor 27. Specifically, a high-k metal gate can be formed by combining a gate electrode 302 made of metal and a gate insulating film 301 made of a high-k material. The high-k material refers to a material with a high relative dielectric constant compared to silicon dioxide. Examples of the high-k material include hafnium (Hf), zirconium (Zr), aluminum (Al), and the like. The high-k material may also be referred to as a high dielectric material.

The number of first peripheral transistors 27 in the first peripheral region R2 may be one or more than one.

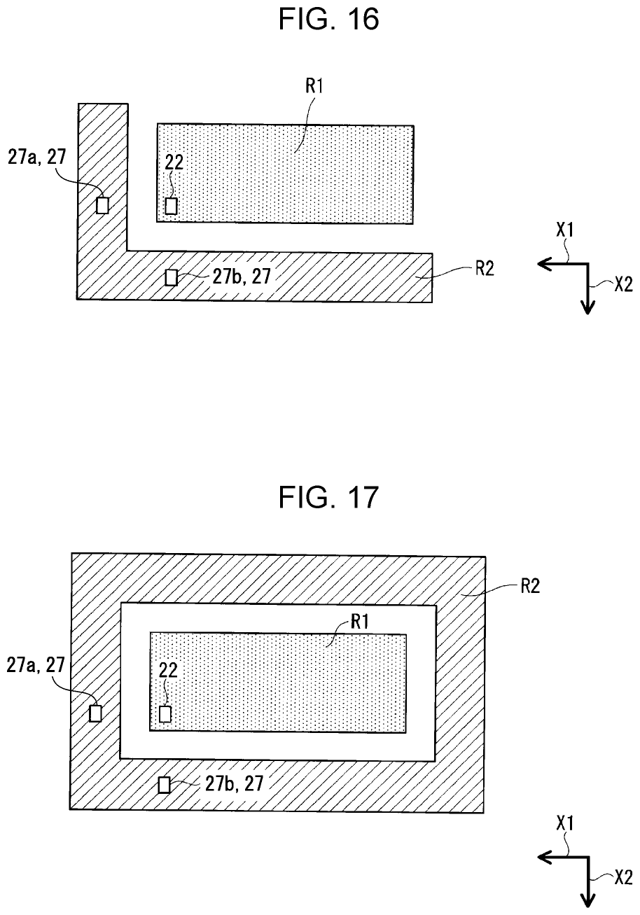

FIG. 16 schematically illustrates the amplifier transistor 22 in the pixel region R1 and the plurality of first peripheral transistors 27 in the first peripheral region R2 when the configuration of FIG. 1 is adopted. FIG. 17 schematically illustrates the amplifier transistor 22 in the pixel region R1 and the plurality of first peripheral transistors 27 in the first peripheral region R2 when the configuration of FIG. 4 is adopted.

In the examples of FIGS. 16 and 17, the plurality of first peripheral transistors 27 are provided in the first peripheral region R2. The plurality of first peripheral transistors 27 include a first direction transistor 27a and a second direction transistor 27b. The first direction transistor 27a is positioned in a first direction X1 from the pixel region R1 in a plan view. The second direction transistor 27b is positioned in a second direction X2 from the pixel region R1 in a plan view. Note that the expression “the plurality of first peripheral transistors 27 are provided” is not meant to imply that these transistors are completely identical. The same applies to “two first peripheral transistors” to be described later.

Note that the first direction X1 and the second direction X2 are different directions from each other. In the examples of FIGS. 16 and 17, the first direction X1 and the second direction X2 are orthogonal to each other.

As illustrated in FIGS. 18 and 19, the imaging device may include a second peripheral region R3. Signal transmission between the first peripheral region R2 and the pixel region R1 is carried out through the second peripheral region R3. In the examples of FIGS. 18 and 19, the second peripheral region R3 is positioned between the pixel region R1 and the first peripheral region R2 in a plan view. Specifically, the second peripheral region R3 is positioned outside the pixel region R1. More specifically, the second peripheral region R3 is positioned outside the pixel region R1 in a plan view.

In the examples of FIGS. 18 and 19, the second peripheral region R3 has a second peripheral transistor 427. The second peripheral transistor 427 is provided in the second peripheral substrate portion. In one example, the second peripheral transistor 427 is a logic transistor. The second peripheral transistor 427 may be a planar transistor or three-dimensional structure transistor. A first example of the three-dimensional structure transistor is a fin field-effect transistor (FinFET). A second example of the three-dimensional structure transistor is a gate-all-around (GAA) FET such as a nanowire FET. A third example of the three-dimensional structure transistor is a nanosheet FET.

In the example of FIG. 18, the first peripheral region R2 and the second peripheral region R3 are L-shaped in a plan view. In the example of FIG. 19, in a plan view, the first peripheral region R2 surrounds the second peripheral region R3, and the second peripheral region R3 surrounds the pixel region R1.

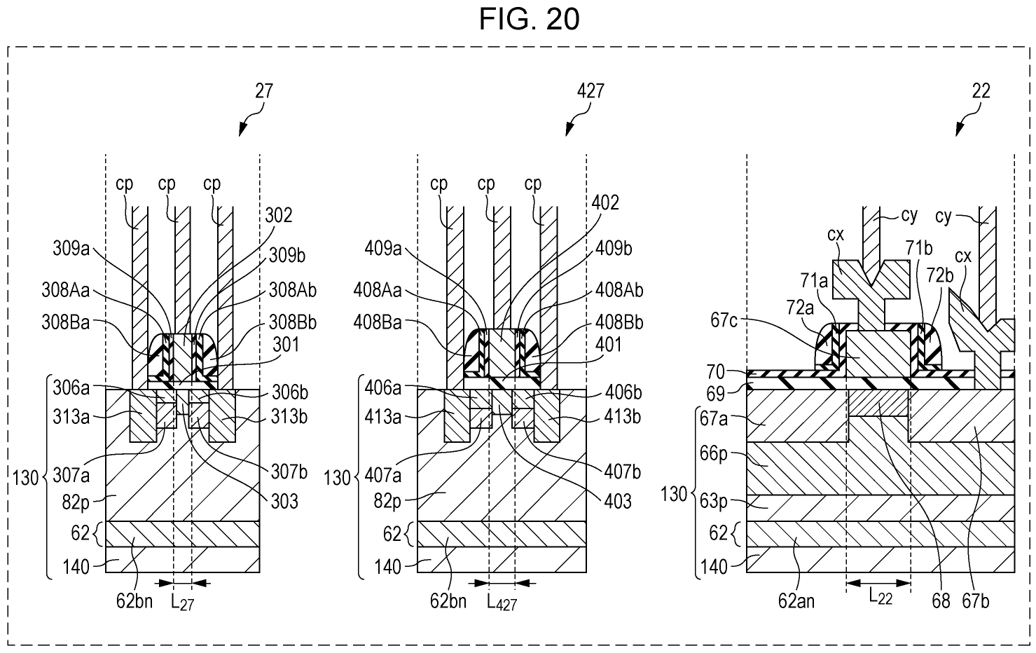

FIG. 20 illustrates a possible configuration of the second peripheral transistor 427 in the second peripheral region R3 in the examples of FIGS. 18 and 19. In the example of FIG. 20, the second peripheral transistor 427 is an N-channel MOSFET.

In the example of FIG. 20, the second peripheral transistor 427 in the second peripheral region R3 has similarities to the first peripheral transistor 27 in the first peripheral region R2. Specifically, the second peripheral transistor 427 is an MIS transistor, as with the first peripheral transistor 27. As with the first peripheral transistor 27, the second peripheral transistor 427 includes a gate electrode 402, a second source 413a, a second drain 413b, second extension diffusion layers 406a and 406b, second pocket diffusion layers 407a and 407b, a channel region 403, a gate insulating film 401, offset spacers 409a and 409b, first sidewalls 408Aa and 408Ab, and second sidewalls 408Ba and 408Bb. As for these constituent elements, the description of the first peripheral transistor 27 can be employed for the description of the second peripheral transistor 427, unless there is any inconsistency.

In one example, the second peripheral transistor 427 has a second specific layer. The second specific layer is positioned inside the second peripheral substrate portion. The second specific layer contains a conductive impurity.

The second specific layer and the first specific layer may have the same composition or different compositions of conductive impurities.

The second specific layer may contain a heavy conductive impurity. The heavy conductive impurity contained in the second specific layer may be the same as or different from the heavy conductive impurity contained in the first specific layer. For example, the heavy conductive impurity in the first specific layer may be indium, and the heavy conductive impurity in the second specific layer may be gallium.

The second peripheral transistor 427 may have an impurity concentration profile in a region along a straight line extending in the depth direction of the second peripheral substrate portion through the second specific layer, in which the concentration of the heavy conductive impurity reaches a peak at a position deeper than the upper surface of the second peripheral substrate portion. In this context, the upper surface of the second peripheral substrate portion is the main surface on which the second peripheral transistor 427 is provided. This impurity concentration profile may specifically be an SSRP.

In the impurity concentration profile in the region along the straight line extending in the depth direction of the second peripheral substrate portion through the second specific layer, the indium concentration may reach a peak at a position deeper than the upper surface of the second peripheral substrate portion. In the impurity concentration profile, the gallium concentration may reach a peak at a position deeper than the upper surface of the second peripheral substrate portion. In the impurity concentration profile, the antimony concentration may reach a peak at a position deeper than the upper surface of the second peripheral substrate portion. In the impurity concentration profile, the bismuth concentration may reach a peak at a position deeper than the upper surface of the second peripheral substrate portion. In the impurity concentration profile, the concentration of the conductive impurities may reach a peak at a position deeper than the upper surface of the second peripheral substrate portion. These impurity concentration profiles may each specifically be the SSRP.

The second peripheral substrate portion has a support substrate 140 and a film body. The film body is provided above the support substrate 140. The film body includes a low-concentration layer and a second specific layer. The low-concentration layer includes the upper surface of the film body. The concentration of the conductive impurities in the low-concentration layer is lower than the concentration of the conductive impurities in the support substrate 140. The second specific layer is positioned below the low-concentration layer. The second peripheral transistor 427 includes a low-concentration layer and a second specific layer in this order from top to bottom. The film body of the second peripheral substrate portion may have features similar to those of the film body of the first peripheral substrate portion.

The second specific layer may contain a diffusion suppression type. The diffusion suppression type contained in the second specific layer may be the same as or different from the diffusion suppression type in the first specific layer. For example, the diffusion suppression type in the first specific layer may be carbon, and the diffusion suppression type in the second specific layer may be nitrogen and fluorine.

In one example, the second peripheral transistor 427 has a second source 413a and a second drain 413b. At least one of the second source 413a or the second drain 413b includes a second specific layer.

In one example, there is a channel region 403 below the gate of the second peripheral transistor 427. The channel region 403 may include a second specific layer.

The expression “below the gate of the second peripheral transistor 427” as used herein refers to a portion of the charge path between the second source 413a and the second drain 413b, which overlaps the gate electrode 402 in a plan view.

In one example, the second peripheral transistor 427 includes a second extension diffusion layer. The second extension diffusion layer is adjacent to the second source 413a or the second drain 413b. The second extension diffusion layer is shallower than the second source 413a and the second drain 413b. The second extension diffusion layer may include a second specific layer. The second extension diffusion layer is the second extension diffusion layer 406a or the second extension diffusion layer 406b.

The expression “the second extension diffusion layer is shallower than the second source 413a and the second drain 413b” means that the deepest part of the second extension diffusion layer is shallower than the deepest part of the second source 413a and the second drain 413b in the depth direction of the second peripheral substrate portion. In this context, “shallow” can also be referred to as “shallow junction depth”.

In the illustrated example, the second peripheral transistor 427 includes the second extension diffusion layer 406a and second extension diffusion layer 406b. The second extension diffusion layer 406a is adjacent to the second source 413a. The second extension diffusion layer 406a is shallower than the second source 413a and the second drain 413b. The second extension diffusion layer 406b is adjacent to the second drain 413b. The second extension diffusion layer 406b is shallower than the second source 413a and the second drain 413b. The second extension diffusion layer 406a and the second extension diffusion layer 406b may include a second specific layer.

In one example, the second peripheral transistor 427 has a second pocket diffusion layer. The second pocket diffusion layer is adjacent to the second source 413a or the second drain 413b. The second pocket diffusion layer may include a second specific layer. The second pocket diffusion layer is the second pocket diffusion layer 407a or the second pocket diffusion layer 407b.

In the illustrated example, the second peripheral transistor 427 includes the second pocket diffusion layer 407a and second pocket diffusion layer 407b. The second pocket diffusion layer 407a is adjacent to the second source 413a. The second pocket diffusion layer 407b is adjacent to the second drain 413b. The second pocket diffusion layer 407a and the second pocket diffusion layer 407b may include a second specific layer.

Only one selected from the group consisting of the channel region 403, the second source 413a, the second drain 413b, the second extension diffusion layer, and the second pocket diffusion layer may include the second specific layer. Specifically, only one selected from the group consisting of the channel region 403, the second source 413a, the second drain 413b, the second extension diffusion layer 406a, the second extension diffusion layer 406b, the second pocket diffusion layer 407a, and the second pocket diffusion layer 407b may include the second specific layer.

Two or more selected from the group consisting of the channel region 403, the second source 413a, the second drain 413b, the second extension diffusion layer, and the second pocket diffusion layer may include a second specific layer. Specifically, two or more selected from the group consisting of the channel region 403, the second source 413a, the second drain 413b, the second extension diffusion layer 406a, the second extension diffusion layer 406b, the second pocket diffusion layer 407a, and the second pocket diffusion layer 407b may include the second specific layer. When two or more selected from the above group include the second specific layer, the diffusion suppression types contained therein may be the same or different. For example, the diffusion suppression type in the second source 413a may be carbon, and the diffusion suppression types in the second extension diffusion layer may be nitrogen and fluorine. In this case, the conductive impurities contained therein may have the same conductivity type or different conductivity types. For example, one of the second source 413a and the second pocket diffusion layer may contain boron and have a p-type conductivity, while the other may contain phosphorus and have an n-type conductivity.

As can be understood from the above description, the number of second specific layers included in the imaging device may be one or more than one.

In one example, the concentration of the conductive impurities in the second extension diffusion layer is lower than the concentration of the conductive impurities in the first extension diffusion layer. The second extension diffusion layer is deeper than the first extension diffusion layer. As described above, the first extension diffusion layer is the first extension diffusion layer 306a or the first extension diffusion layer 306b. The second extension diffusion layer is the second extension diffusion layer 406a or the second extension diffusion layer 406b.

The expression “the second extension diffusion layer is deeper than the first extension diffusion layer” means that the deepest part of the second extension diffusion layer is deeper than the deepest part of the first extension diffusion layer in the depth direction of the first peripheral substrate portion or the second peripheral substrate portion. In this context, “deep” can also be referred to as “deep junction depth”.

In a first definition, the “concentration of the conductive type impurities” in the expression “the concentration of the conductive type impurities in the second extension diffusion layer is lower than the concentration of the conductive type impurities in the first extension diffusion layer” is the maximum value of the concentration. In a second definition, the “concentration of conductive impurities” in this expression is the average concentration. In the above example, when it can be said that “the concentration of the conductive impurities in the second extension diffusion layer is lower than the concentration of the conductive impurities in the first extension diffusion layer” based on at least one of the first definition or the second definition, it is assumed that “the concentration of the conductive impurities in the second extension diffusion layer is lower than the concentration of the conductive impurities in the first extension diffusion layer”. In this expression, the type of conductive impurity in the first extension diffusion layer may be the same as or different from the type of conductive impurity in the second extension diffusion layer. For example, the conductive impurity in the first extension diffusion layer may be boron, and the conductive impurity in the second extension diffusion layer may be indium.

In the illustrated example, the second peripheral transistor 427 has a second extension diffusion layer 406a and a second extension diffusion layer 406b. The second extension diffusion layer 406a is adjacent to the second source 413a. The second extension diffusion layer 406a is shallower than the second source 413a and the second drain 413b. The second extension diffusion layer 406a contains a conductive impurity. The second extension diffusion layer 406b is adjacent to the second drain 413b. The second extension diffusion layer 406b is shallower than the second source 413a and the second drain 413b. The second extension diffusion layer 406b contains a conductive impurity. The concentration of the conductive impurities in the second extension diffusion layer 406a is lower than the concentration of the conductive impurities in the first extension diffusion layer 306a. The second extension diffusion layer 406a is deeper than the first extension diffusion layer 306a. The concentration of the conductive impurities in the second extension diffusion layer 406b is lower than the concentration of the conductive impurities in the first extension diffusion layer 306b. The second extension diffusion layer 406b is deeper than the first extension diffusion layer 306b.

In one example, the gate length L₂₇ of the first peripheral transistor 27 is shorter than the gate length L₄₂₇ of the second peripheral transistor 427. The short gate length L₂₇ of the first peripheral transistor 27 is advantageous for miniaturization of the first peripheral transistor 27, and is advantageous from the viewpoint of operating the first peripheral transistor 27 at high speed. In one specific example, the second peripheral transistor 427 is included in an analog processor and the first peripheral transistor 27 is included in a digital processor. In this specific example, adopting different gate lengths for the first peripheral transistor 27 and the second peripheral transistor 427 allows the digital processor to perform digital processing taking advantage of the high-speed operation of the first peripheral transistor 27 having the short gate length L₂₇. The finer the first peripheral transistor 27, the faster the digital processing can be performed in the digital processor.

The relatively long gate length L₄₂₇ can suppress variations in threshold voltage of the second peripheral transistor 427. This also makes it possible to improve the analog characteristics of the second peripheral transistor 427 in the analog processor.

The ratio L₂₇/L₄₂₇ of the gate length L₂₇ of the first peripheral transistor 27 to the gate length L₄₂₇ of the second peripheral transistor 427 is less than or equal to 0.8, for example, and may be less than or equal to 0.34. This ratio is, for example, more than or equal to 0.01, and may be more than or equal to 0.05.

In one example, the gate length L₂₂ of the amplifier transistor 22 is longer than the gate length L₄₂₇ of the second peripheral transistor 427. The long gate length L₂₂ of the amplifier transistor 22 can be advantageous in improving the characteristics of the amplifier transistor 22. In one specific example, the amplifier transistor 22 is included in the analog processor. In this specific example, the gate length L₂₂ is increased to reduce variations in the threshold voltage of the amplifier transistor 22, thus making it easier to improve the Pelgrom coefficient. This allows the analog processor to perform analog processing taking advantage of good analog characteristics of the amplifier transistor 22.

The ratio L₄₂₇/L₂₂ of the gate length L₄₂₇ of the second peripheral transistor 427 to the gate length L₂₂ of the amplifier transistor 22 is less than or equal to 0.95, for example, and may be less than or equal to 0.9. This ratio is, for example, more than or equal to 0.1, and may be more than or equal to 0.36.

In one example, the gate insulating film 301 of the first peripheral transistor 27 is thinner than the gate insulating film 401 of the second peripheral transistor 427. The thin gate insulating film 301 of the first peripheral transistor 27 is advantageous for miniaturization of the first peripheral transistor 27 and is advantageous from the viewpoint of operating the first peripheral transistor 27 at high speed. In one specific example, the second peripheral transistor 427 is included in the analog processor and the first peripheral transistor 27 is included in the digital processor. In this specific example, adopting different gate insulating film thicknesses for the first peripheral transistor 27 and the second peripheral transistor 427 allows the digital processor to perform digital processing taking advantage of the high-speed operation of the first peripheral transistor 27 having the thin gate insulating film 301. The finer the first peripheral transistor 27, the faster the digital processing can be performed in the digital processor. The relatively thick gate insulating film 401 can suppress variations in threshold voltage of the second peripheral transistor 427. This also makes it possible to improve the analog characteristics of the second peripheral transistor 427 in the analog processor.

The ratio T₃₀₁/T₄₀₁ of the thickness T₃₀₁ of the gate insulating film 301 in the first peripheral transistor 27 to the thickness T₄₀₁ of the gate insulating film 401 in the second peripheral transistor 427 is less than or equal to 0.7, for example, or may be less than or equal to 0.36. This ratio is, for example, more than or equal to 0.1, and may be more than or equal to 0.22.

In one example, the gate insulating film 69 of the amplifier transistor 22 is thicker than the gate insulating film 401 of the second peripheral transistor 427. The thick gate insulating film 69 of the amplifier transistor 22 can be advantageous for improving the characteristics of the amplifier transistor 22. In one specific example, the amplifier transistor 22 is included in the analog processor. In this specific example, the thickness of the gate insulating film 69 is increased to reduce variations in the threshold voltage of the amplifier transistor 22, thus making it easier to improve the Pelgrom coefficient. This allows the analog processor to perform analog processing taking advantage of good analog characteristics of the amplifier transistor 22.

The ratio T₄₀₁/T₆₉ of the thickness T₄₀₁ of the gate insulating film 401 in the second peripheral transistor 427 to the thickness T₆₉ of the gate insulating film 69 in the amplifier transistor 22 is less than 1, for example. This ratio is, for example, more than or equal to 0.68.

In one specific example, the second peripheral transistor 427 is a logic transistor. The second peripheral transistor 427 can perform analog operation while being incorporated in a pixel driver, load cell, column amplifier, comparator, or the like. A wide dynamic range can be advantageous in analog operation. To secure a wide dynamic range, it is advantageous that the transistor has a high operating voltage and a wide voltage range. When the pixel voltage is about 3 V to 3.5 V, for example, it may be advantageous that the operating voltage is 3.3 V. In this respect, the gate length L₄₂₇ of the second peripheral transistor 427 is longer than the gate length L₂₇ of the first peripheral transistor 27 in this specific example. The gate insulating film 401 of the second peripheral transistor 427 is thicker than the gate insulating film 301 of the first peripheral transistor 27. The long gate length L₄₂₇ and the thick gate insulating film 401 are advantageous from the viewpoint of increasing the operating voltage of the second peripheral transistor 427. In the above context, the operating voltage is the drain voltage of a transistor when the transistor is on. The pixel voltage is the voltage of the charge storage node in the pixel.

In this specific example, the operating voltage of the second peripheral transistor 427 is higher than the operating voltage of the first peripheral transistor 27. The operating voltage of the second peripheral transistor 427 is 3.3 V, for example. The operating voltage of the first peripheral transistor 27 is 1.2 V, for example.

In this specific example, the second peripheral transistor 427 has a longer gate length and a thicker gate insulating film than the first peripheral transistor 27, and therefore has a smaller variation in threshold voltage. Such a small variation in threshold voltage is also an advantageous feature. In this specific example, the threshold voltage of the second peripheral transistor 427 is higher than the threshold voltage of the first peripheral transistor 27. The threshold voltage of the second peripheral transistor 427 is about 0.5 V, for example. The threshold voltage of the first peripheral transistor 27 is about 0.3 V, for example.

In one example, the concentration of the diffusion suppression type in the first specific layer is higher than the concentration of the diffusion suppression type in the second specific layer. In the expression “the concentration of the diffusion suppression type in the first specific layer is higher than the concentration of the diffusion suppression type in the second specific layer”, the concentration of the diffusion suppression type in the second specific layer may be zero or higher than zero.

In a first definition, the “concentration of the diffusion suppression type” in the expression “the concentration of the diffusion suppression type in the first specific layer is higher than the concentration of the diffusion suppression type in the second specific layer” is the maximum value of the concentration. In a second definition, the “concentration of diffusion suppression type” in this expression is the average concentration. In the above example, when it can be said that “the concentration of the diffusion suppression type in the first specific layer is higher than the concentration of the diffusion suppression type in the second specific layer” based on at least one of the first definition or the second definition, it is assumed that “the concentration of the diffusion suppression type in the first specific layer is higher than the concentration of the diffusion suppression type in the second specific layer”. In this expression, the diffusion suppression type in the first specific layer may be the same as or different from the diffusion suppression type in the second specific layer. For example, the diffusion suppression type in the first specific layer may be carbon, and the diffusion suppression type in the second specific layer may be nitrogen and fluorine.

The concentration of carbon in the first specific layer may be higher than the concentration of carbon in the second specific layer. The concentration of nitrogen in the first specific layer may be higher than the concentration of nitrogen in the second specific layer. The concentration of fluorine in the first specific layer may be higher than the concentration of fluorine in the second specific layer. The concentration of germanium in the first specific layer may be higher than the concentration of germanium in the second specific layer. The concentration of silicon in the first specific layer may be higher than the concentration of silicon in the second specific layer. The concentration of argon in the first specific layer may be higher than the concentration of argon in the second specific layer.

In one example, the concentration of carbon in the second specific layer is higher than the concentration of carbon in the channel region 68 below the gate of the amplifier transistor 22. As described above, the expression “below the gate of the amplifier transistor 22” refers to the portion of the charge path between the source 67a and the drain 67b, which overlaps the gate electrode 67c in a plan view. In the expression “the concentration of carbon in the second specific layer is higher than the concentration of carbon in the channel region 68 below the gate of the amplifier transistor 22”, the concentration of carbon in the channel region 68 below the gate of the amplifier transistor 22 may be zero or higher than zero.

In a first definition, the “concentration of carbon” in the expression “the concentration of carbon in the second specific layer is higher than the concentration of carbon in the channel region 68 below the gate of the amplifier transistor 22” is the maximum value of the concentration. In a second definition, the “concentration of carbon” in this expression is the average concentration. In the above example, when it can be said that “the concentration of carbon in the second specific layer is higher than the concentration of carbon in the channel region 68 below the gate of the amplifier transistor 22” based on at least one of the first definition or the second definition, it is assumed that “the concentration of carbon in the second specific layer is higher than the concentration of carbon in the channel region 68 below the gate of the amplifier transistor 22”.

In one example, the second extension diffusion layer contains nitrogen.

In the illustrated example, the second extension diffusion layer 406a contains nitrogen. The second extension diffusion layer 406b contains nitrogen.

The nitrogen in the second extension diffusion layer may be derived from ion implantation of nitrogen (N) ions or may be derived from implantation of nitrogen molecules N₂. In the illustrated example, the nitrogen in the second extension diffusion layer 406a may be derived from ion implantation of nitrogen (N) ions or may be derived from implantation of nitrogen molecules N₂. The nitrogen in the second extension diffusion layer 406b may be derived from ion implantation of nitrogen (N) ions or may be derived from implantation of nitrogen molecules N₂. The carbon in the first extension diffusion layers 306a and 306b may be similarly derived from ion implantation.

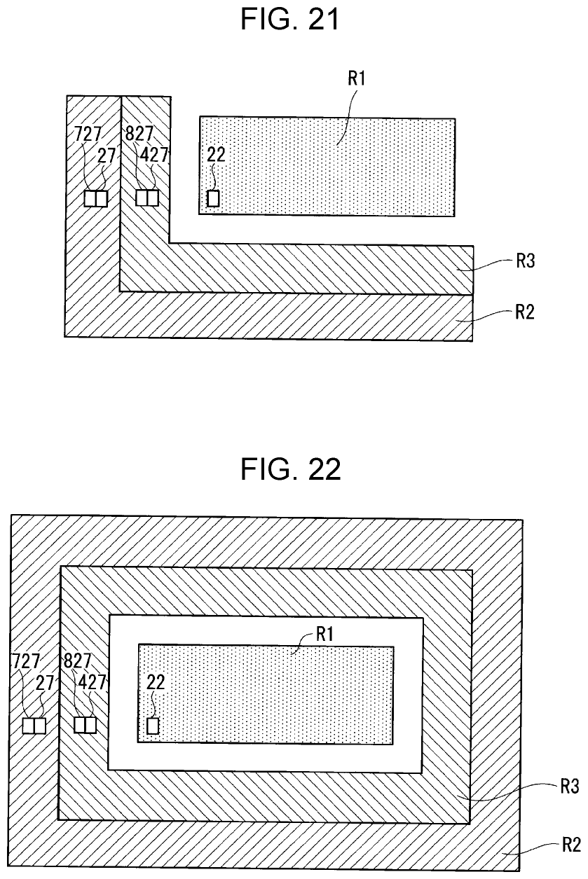

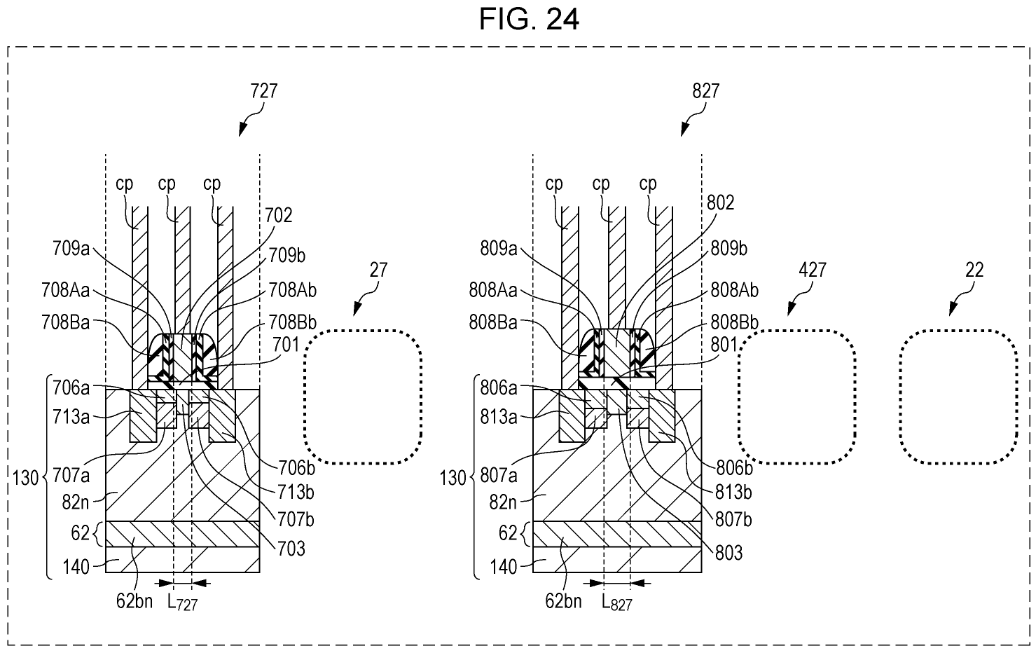

As a matter of course, transistors other than the transistors illustrated in FIGS. 18 to 20 may be provided. In examples illustrated in FIGS. 21 to 24, the first peripheral region R2 has a first peripheral transistor 27 and a first peripheral transistor 727. An element isolation 222 is provided between the first peripheral transistor 27 and the first peripheral transistor 727. The second peripheral region R3 has a second peripheral transistor 427 and a second peripheral transistor 827. The element isolation 222 is provided between the second peripheral transistor 427 and the second peripheral transistor 827. In FIG. 24, the first peripheral transistor 27, the second peripheral transistor 427, and the amplifier transistor 22 are simplified, and the illustration of the element isolation 222 is omitted.

In the examples of FIGS. 21 to 24, the first peripheral transistor 727 has similarities to the first peripheral transistor 27. Specifically, as with the first peripheral transistor 27, the first peripheral transistor 727 is an MIS transistor. As with the first peripheral transistor 27, the first peripheral transistor 727 includes a gate electrode 702, a source 713a, a drain 713b, extension diffusion layers 706a and 706b, pocket diffusion layers 707a and 707b, a channel region 703, a gate insulating film 701, offset spacers 709a and 709b, first sidewalls 708Aa and 708Ab, and second sidewalls 708Ba and 708Bb.

Note, however, that the first peripheral transistor 27 and the first peripheral transistor 727 are transistors having polarities opposite to each other. Specifically, the first peripheral transistor 27 is an N-channel transistor, while the first peripheral transistor 727 is a P-channel transistor. The first source 313a is n-type, while the source 713a is p-type. The first drain 313b is n-type, while the drain 713b is p-type. The first extension diffusion layer 306a is n-type, while the extension diffusion layer 706a is p-type. The first extension diffusion layer 306b is n-type, while the extension diffusion layer 706b is p-type. The first pocket diffusion layer 307a is p-type, while the pocket diffusion layer 707a is n-type. The first pocket diffusion layer 307b is p-type, while the pocket diffusion layer 707b is n-type. The channel diffusion layer 303 is p-type, while the channel region 703 is n-type. As illustrated in FIG. 24, the first peripheral transistor 727 has an n-type impurity region 82n, which is an n-type well.

Hereinafter, the ordinal number “first” may be used for the constituent elements of the first peripheral transistor 727. For example, the source 713a may be referred to as a first source. The drain 713b may be referred to as a first drain.

In the illustrated example, the element isolation 222 is an STI structure. The STI structure has a trench (groove) and a filler that fills the trench. The filler is, for example, an oxide. The depth of the trench is, for example, about 500 nm. The STI structure may be formed in the semiconductor substrate 130 by an STI process.

In the illustrated example, the first peripheral region R2 has two first peripheral transistors 27 and 727 and an element isolation 222 that is the STI structure. The element isolation 222 that is the STI structure isolates the two first peripheral transistors 27 and 727. The element isolation 222, which is the STI structure, has a trench.

In the illustrated example, a distribution range of a heavy conductive impurity in a first specific layer of at least one of the first peripheral transistor 27 or the first peripheral transistor 727 is a range shallower than the bottom of the trench. In this context, the “distribution range of a heavy conductive impurity” refers to a region where the concentration of a heavy conductive impurity is more than or equal to 5×10¹⁶ atoms/cm³. The same applies to a distribution range of indium and the like. The “bottom of the trench” means the deepest portion of the trench in the depth direction of the first peripheral substrate portion.

The distribution range of indium in the first specific layer of at least one of the first peripheral transistor 27 or the first peripheral transistor 727 may be shallower than the bottom of the trench. The distribution range of gallium in the first specific layer of at least one of the first peripheral transistor 27 or the first peripheral transistor 727 may be shallower than the bottom of the trench. The distribution range of antimony in the first specific layer of at least one of the first peripheral transistor 27 or the first peripheral transistor 727 may be shallower than the bottom of the trench. The distribution range of bismuth in the first specific layer of at least one of the first peripheral transistor 27 or the first peripheral transistor 727 may be shallower than the bottom of the trench.

In the illustrated example, a distribution range of the diffusion suppression type in the first specific layer of at least one of the first peripheral transistor 27 or the first peripheral transistor 727 is a range shallower than the bottom of the trench. In this context, the “distribution range of the diffusion suppression type” refers to a region where the concentration of the diffusion suppression type is more than or equal to 5×10¹⁶ atoms/cm³. The same applies to the distribution range of carbon and the like. The “bottom of the trench” means the deepest portion of the trench in the depth direction of the first peripheral substrate portion.

The distribution range of carbon in the first specific layer of at least one of the first peripheral transistor 27 or the first peripheral transistor 727 may be shallower than the bottom of the trench. The distribution range of nitrogen in the first specific layer of at least one of the first peripheral transistor 27 or the first peripheral transistor 727 may be shallower than the bottom of the trench. The distribution range of fluorine in the first specific layer of at least one of the first peripheral transistor 27 or the first peripheral transistor 727 may be shallower than the bottom of the trench.

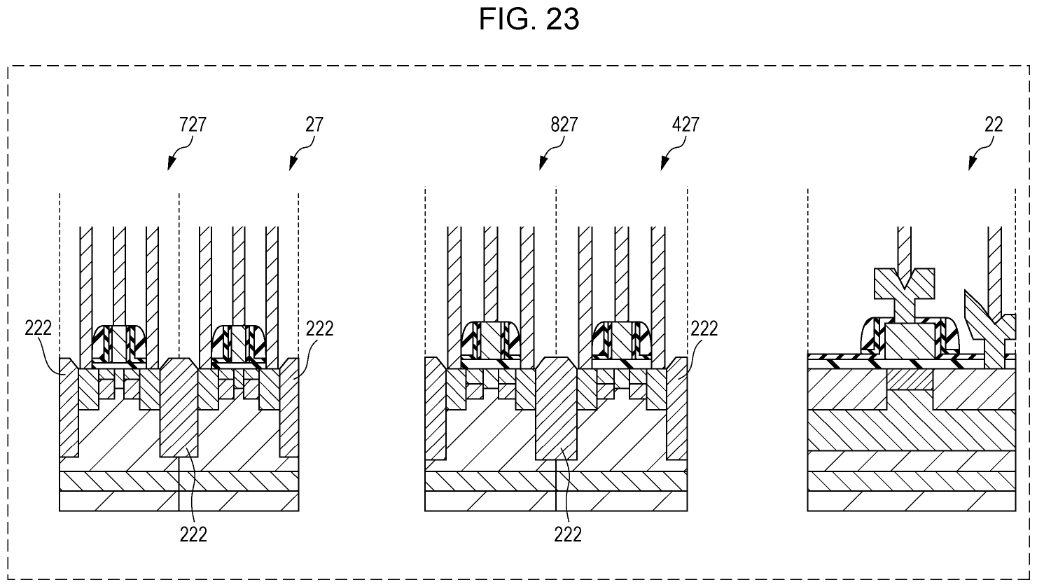

Specifically, the two first peripheral transistors 27 and 727 are transistors having polarities opposite to each other. In a plan view, the element isolation 222, which is the STI structure, is disposed between the two first peripheral transistors 27 and 727, more specifically, on a line segment connecting the two. As illustrated in FIG. 23, the STI structure may protrude upward from the surface of the first peripheral substrate portion.

The element isolation 222 may be an implantation isolation region.

In the examples of FIGS. 21 to 24, the second peripheral transistor 827 has similarities to the second peripheral transistor 427. Specifically, as with the second peripheral transistor 427, the second peripheral transistor 827 is an MIS transistor. As with the second peripheral transistor 427, the second peripheral transistor 827 includes a gate electrode 802, a source 813a, a drain 813b, extension diffusion layers 806a and 806b, pocket diffusion layers 807a and 807b, a channel region 803, a gate insulating film 801, offset spacers 809a and 809b, first sidewalls 808Aa and 808Ab, and second sidewalls 808Ba and 808Bb.

The second peripheral transistor 427 and the second peripheral transistor 827 are transistors having polarities opposite to each other. Specifically, the second peripheral transistor 427 is an N-channel transistor, while the second peripheral transistor 827 is a P-channel transistor. The second source 413a is n-type, while the source 813a is p-type. The second drain 413b is n-type, while the drain 813b is p-type. The second extension diffusion layer 406a is n-type, while the extension diffusion layer 806a is p-type. The second extension diffusion layer 406b is n-type, while the extension diffusion layer 806b is p-type. The second pocket diffusion layer 407a is p-type, while the pocket diffusion layer 807a is n-type. The second pocket diffusion layer 407b is p-type, while the pocket diffusion layer 807b is n-type. The channel region 403 is p-type, while the channel region 803 is n-type.

The ordinal number “second” may be used for the constituent elements of the second peripheral transistor 827. For example, the source 813a may be referred to as a second source. The drain 813b may be referred to as a second drain.

Just to be sure, the second peripheral region R3 is not essential. As a matter of course, the second peripheral transistors 427 and 827 are not essential. In the first peripheral region R2, at least one of the first peripheral transistor 27 or the first peripheral transistor 727 may be used for analog processing. In one specific example, in the first peripheral region R2, one first peripheral transistor is used for digital processing, while another first peripheral transistor is used for analog processing.

The description of the first peripheral transistor 27 and elements thereof can be employed for the description of the first peripheral transistor 727 and elements thereof, unless there is any inconsistency. The description of the second peripheral transistor 427 and elements thereof can be employed for the description of the second peripheral transistor 827 and elements thereof, unless there is any inconsistency. The description of the relationship between the first peripheral transistor 27, the second peripheral transistor 427, and the amplifier transistor 22 can be employed for the description of the relationship between the first peripheral transistor 727, the second peripheral transistor 827, and the amplifier transistor 22, unless there is any inconsistency.

For example, a gate length L₇₂₇ of the first peripheral transistor 727 may be shorter than a gate length L₂₂ of the amplifier transistor 22. The gate length L₇₂₇ of the first peripheral transistor 727 may be shorter than a gate length L₈₂₇ of the second peripheral transistor 827. The gate length L₈₂₇ of the second peripheral transistor 827 may be shorter than the gate length L₂₂ of the amplifier transistor 22. The extension diffusion layer 706a may be shallower than the source 713a and the drain 713b. The extension diffusion layer 706b may be shallower than the source 713a and the drain 713b. The extension diffusion layer 806a may be shallower than the source 813a and the drain 813b. The extension diffusion layer 806b may be shallower than the source 813a and the drain 813b. The extension diffusion layer 706a may contain a heavy conductive impurity and diffusion suppression type. The extension diffusion layer 706b may contain a heavy conductive impurity and diffusion suppression type. The extension diffusion layer 806a may contain nitrogen. The nitrogen in the extension diffusion layer 806a may be derived from ion implantation of nitrogen (N) ions or may be derived from implantation of nitrogen molecules N₂. The extension diffusion layer 806b may contain nitrogen. The nitrogen in the extension diffusion layer 806b may be derived from ion implantation of nitrogen (N) ions or may be derived from implantation of nitrogen molecules N₂.

As can be understood from the above description, in the imaging device, at least one of the extension diffusion layer 806a or the extension diffusion layer 806b of the second peripheral transistor 827, which is the N-channel transistor, may contain nitrogen. This nitrogen affects not only the impurity distribution in the second peripheral substrate portion but also the interfacial characteristics of the gate insulating film in the second peripheral transistor 827. This can improve the reliability of the imaging device. At least one of the extension diffusion layer 806a or the extension diffusion layer 806b containing nitrogen may be a so-called LDD diffusion layer.

In an example where at least one of the second extension diffusion layer 406a or the second extension diffusion layer 406b of the second peripheral transistor 427, which is the N-channel transistor, contains nitrogen, the extension diffusion layer 806a of the second peripheral transistor 827, which is the P-channel transistor, may contain or be free of nitrogen. In this example, the extension diffusion layer 806b of the second peripheral transistor 827, which is the P-channel transistor, may contain or be free of nitrogen.

In one example, the amplifier transistor 22, the second peripheral transistor 427, the second peripheral transistor 827, the first peripheral transistor 27, and the first peripheral transistor 727 are arranged in this order in a plan view. In another example, the amplifier transistor 22, the second peripheral transistor 827, the second peripheral transistor 427, the first peripheral transistor 727, and the first peripheral transistor 27 are arranged in this order in a plan view. The amplifier transistor 22, the second peripheral transistor 427, the second peripheral transistor 827, the first peripheral transistor 727, and the first peripheral transistor 27 may be arranged in this order in a plan view. The amplifier transistor 22, the second peripheral transistor 827, the second peripheral transistor 427, the first peripheral transistor 27, and the first peripheral transistor 727 may be arranged in this order in a plan view.

The items described with reference to FIGS. 21 to 24 can also be applied to the examples of FIGS. 13 to 17, unless there is any inconsistency.

The above description has been given of a front side illumination (FSI) imaging device as an example. However, the above description can also be applied to a back side illumination (BSI) imaging device.

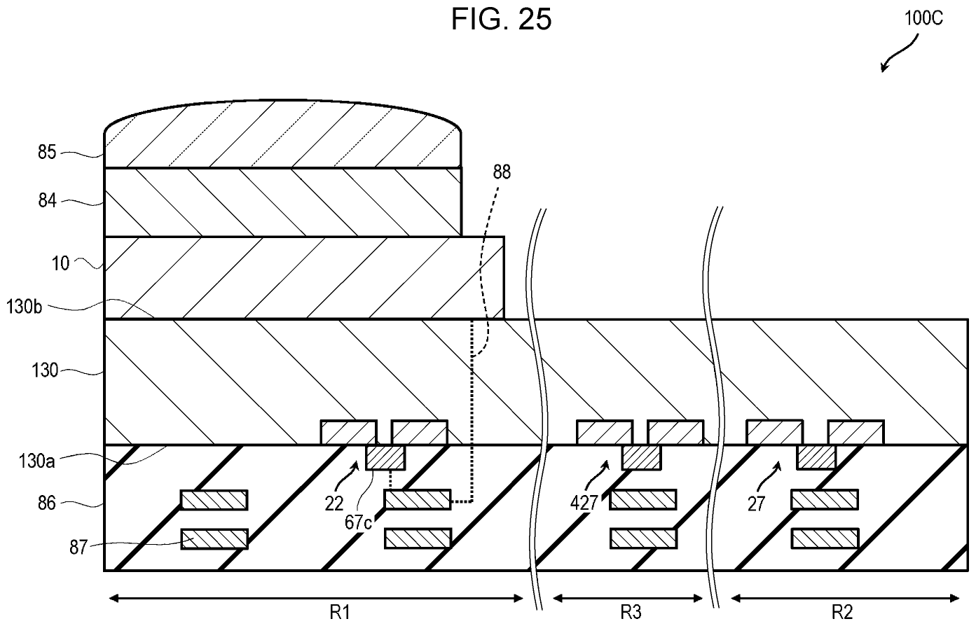

FIG. 25 is a schematic diagram of a back side illumination imaging device 100C according to an example.

In the imaging device 100C illustrated in FIG. 25, a semiconductor substrate 130 has a front surface 130a and a back surface 130b. The back surface 130b is the surface on which light is made incident. The front surface 130a is the surface opposite to the light incident side.

A photoelectric converter 10, a color filter 84, and an on-chip lens 85 are stacked in this order on the back surface 130b. In a typical example, the semiconductor substrate 130 and the photoelectric converter 10 are joined by bonding the photoelectric converter 10 to the polished back surface 130b. The color filter 84 and on-chip lens 85 may be omitted. At least one of between the photoelectric converter 10 and the color filter 84 or between the color filter 84 and the on-chip lens 85, an interlayer insulating film may be provided for the purpose of planarization, protection, and the like.

A wiring layer 86 is laminated on the front surface 130a. In the wiring layer 86, a plurality of wires 87 are provided in insulators. The plurality of wires 87 are used to electrically connect an amplifier transistor 22, a first peripheral transistor 27, and a second peripheral transistor 427 to their connection destinations. For example, the wire 87 constitutes part of an electric path 88 that electrically connects a pixel electrode 11 of the photoelectric converter 10 to a gate electrode 67c of the amplifier transistor 22. Specifically, in this example, the electric path 88 includes a through-silicon via (TSV) provided in the semiconductor substrate 130. FIG. 25 omits the illustration of the through-silicon via. In FIG. 25, the dotted lines representing the electric path 88 are schematic and are not intended to limit the position of the electric path 88 and the like. Cu—Cu connection may be employed instead of the TSV connection.

Although not illustrated in detail in FIG. 25, the amplifier transistor 22, the first peripheral transistor 27, and the second peripheral transistor 427 may have the features described with reference to FIGS. 1 to 24. The same applies to other elements such as the photoelectric converter 10. Specifically, in this example, the first peripheral transistor 27 and the second peripheral transistor 427 each include a source, a drain, an extension diffusion layer, a pocket diffusion layer, and the like. The semiconductor substrate 130 includes a support substrate 140.

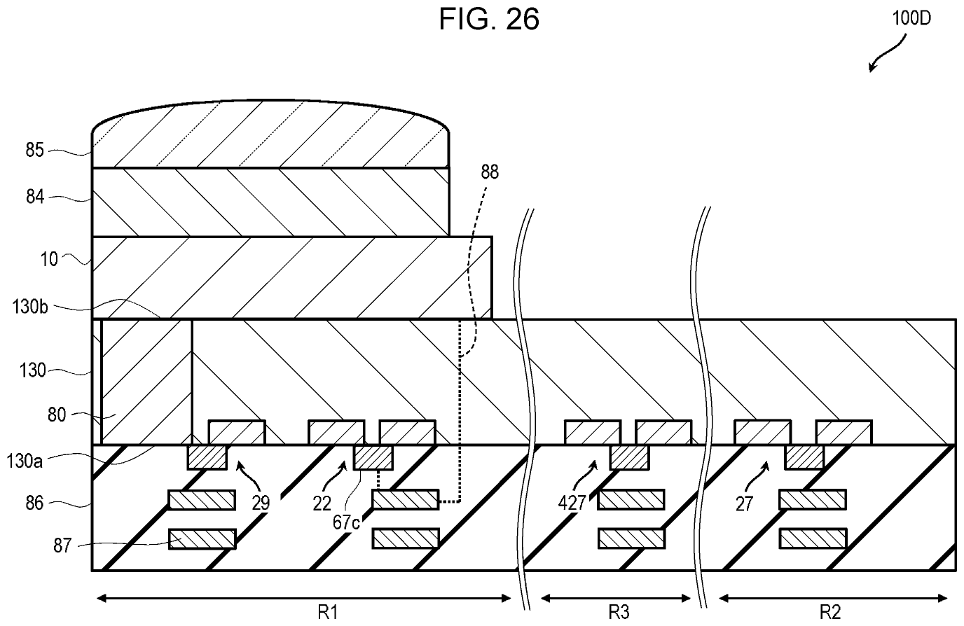

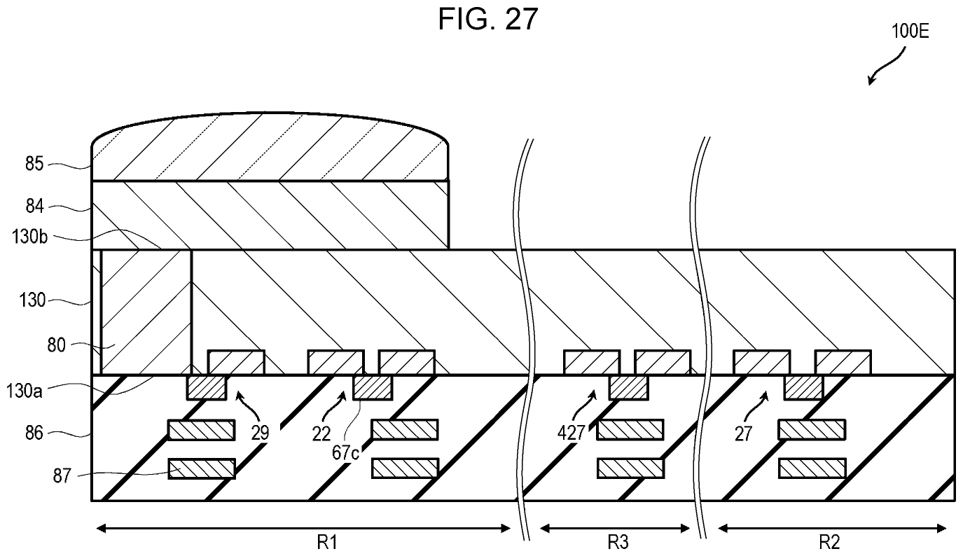

FIG. 26 is a schematic diagram of a back side illumination imaging device 100D according to another example.

The imaging device 100D illustrated in FIG. 26 includes the elements of the imaging device 100C illustrated in FIG. 25. The imaging device 100D further includes a photodiode 80 and a transfer transistor 29. The photodiode 80 and the transfer transistor 29 are provided in the semiconductor substrate 130. Specifically, the pixel region R1 has the photodiode 80 provided in the pixel substrate portion. As described above, the pixel substrate portion refers to a portion of at least one semiconductor substrate 130, which is positioned in the pixel region R1.

The photodiode 80 corresponds to a photoelectric converter, as with the photoelectric converter 10. The photodiode 80 generates signal charges by photoelectric conversion. The transfer transistor 29 transfers this signal charge to a charge storage region (not illustrated).

According to the back side illumination configuration illustrated in FIG. 26, the wires 87 in the wiring layer 86 do not block irradiation of the photodiode 80 with light from the on-chip lens 85 and the color filter 84 side. This enables efficient photoelectric conversion by the photodiode 80.

FIG. 27 is a schematic diagram of a back side illumination imaging device 100E according to another example.

The imaging device 100E illustrated in FIG. 27 includes some of the elements of the imaging device 100D illustrated in FIG. 26. The imaging device 100E illustrated in FIG. 27 includes no photoelectric converter 10.

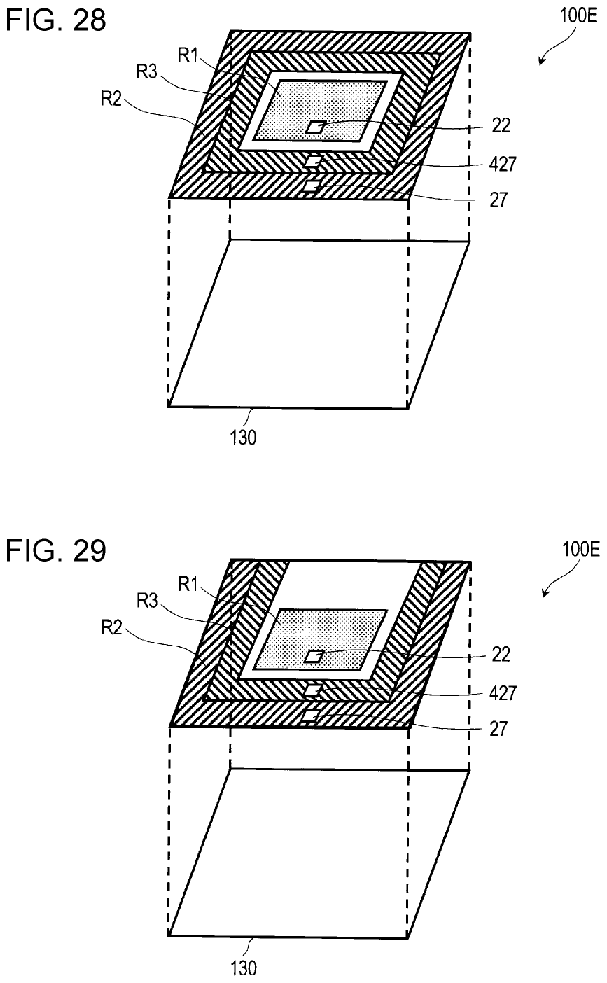

FIGS. 28 to 31 are schematic diagrams illustrating possible shapes of the pixel region R1, the first peripheral region R2, and the second peripheral region R3 in the imaging device 100E illustrated in FIG. 27.

In the example of FIG. 28, the second peripheral region R3 surrounds the pixel region R1 in a plan view. The first peripheral region R2 surrounds the second peripheral region R3 in a plan view. Specifically, in the example of FIG. 28, the second peripheral region R3 has a square shape outside the pixel region R1 in a plan view. The first peripheral region R2 has a square shape outside the second peripheral region R3 in a plan view.

In the example of FIG. 29, the second peripheral region R3 has a U-shape outside the pixel region R1 in a plan view. The first peripheral region R2 has a U-shape outside the second peripheral region R3 in a plan view.

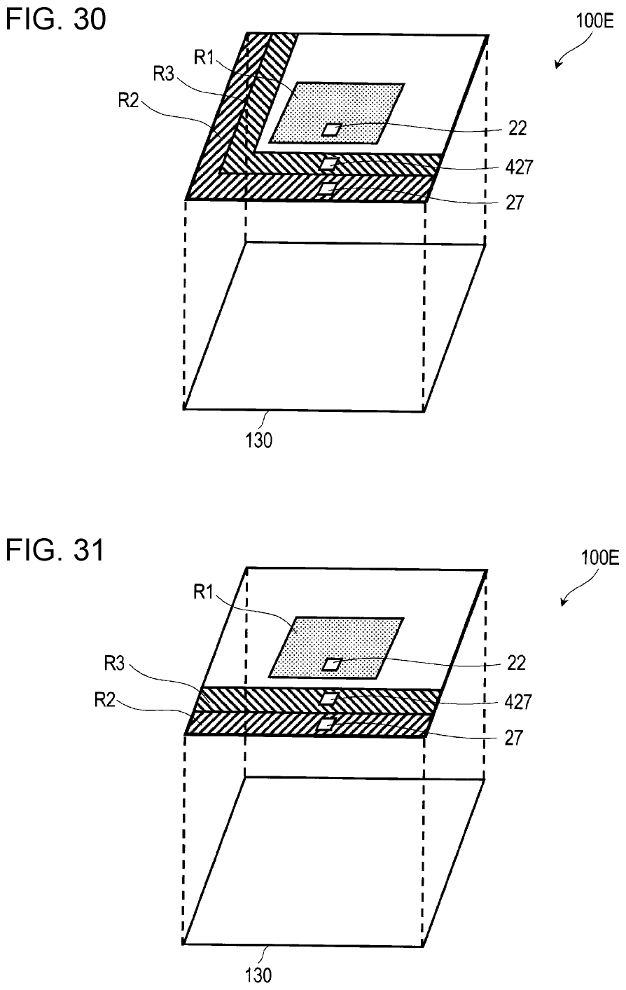

In the example of FIG. 30, the second peripheral region R3 has an L-shape outside the pixel region R1 in a plan view. The first peripheral region R2 has an L-shape outside the second peripheral region R3 in a plan view.

In the example of FIG. 31, the second peripheral region R3 extends straight outside the pixel region R1 in a plan view. The first peripheral region R2 extends straight outside the second peripheral region R3 in a plan view.

The shapes of the pixel region R1, first peripheral region R2, and second peripheral region R3 illustrated in FIGS. 28 to 31 are also applicable to the imaging devices 100C and 100D illustrated in FIGS. 25 and 26. These shapes are also applicable to the imaging devices 100A and 100B illustrated in FIGS. 1 to 24.

The above description has been given of an imaging device using a single semiconductor substrate as an example. The above description can also be applied to a so-called chip stack imaging device in which a plurality of semiconductor substrates are stacked on each other. The chip stack imaging device may also be referred to as a chip-stacked imaging device.

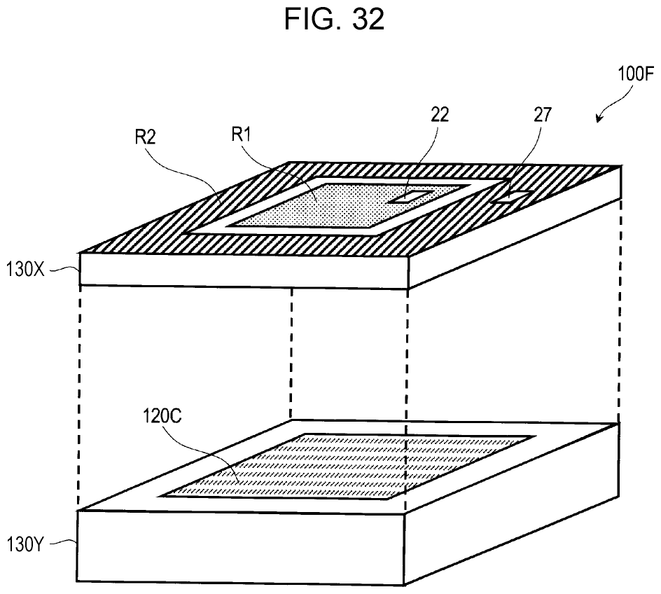

FIG. 32 is a schematic diagram of a chip stack imaging device 100F according to an example.

In the imaging device 100F illustrated in FIG. 32, a semiconductor substrate 130X and a semiconductor substrate 130Y are stacked on each other. The semiconductor substrate 130X is provided with a pixel region R1 and a first peripheral region R2. A peripheral circuit 120C is provided on the semiconductor substrate 130Y. The peripheral circuit 120C may include part or all of a circuit equivalent to a peripheral circuit 120A or peripheral circuit 120B.

Although not illustrated, at least one of TSV connection or Cu—Cu connection can be used for electrical connection between elements provided on the semiconductor substrate 130X and elements provided on the semiconductor substrate 130Y.

The pixel region R1 has an amplifier transistor 22. The first peripheral region R2 has a first peripheral transistor 27.

In the imaging device 100F, the first peripheral transistor 27 is a load transistor, for example. The pixel region R1 is connected to the load transistor through a vertical signal line 35. Specifically, the amplifier transistor 22 is connected to the load transistor through the vertical signal line 35.

In one specific example, the load transistor described above functions as a constant current source. A constant current determined by the load transistor flows through the amplifier transistor 22, the vertical signal line 35, and the load transistor in this order. The amplifier transistor 22 and the load transistor form a source follower.

Therefore, a voltage corresponding to a gate voltage of the amplifier transistor 22, that is, a voltage of a charge storage region Z appears on the vertical signal line 35. This state continues while the address transistor 24 is on. The load transistor may be included in the load circuit 45 illustrated in FIG. 2.

In the imaging device 100F, the first peripheral transistor 27 may be included in at least one of a comparator or a driver.

In the example of FIG. 32, the first peripheral transistor 27 may be either included or not included in the peripheral circuit 120C. In the example of FIG. 32, the second peripheral region R3 may be provided outside the first peripheral region R2.

In the examples of FIGS. 25 to 32, again, a first specific layer contains a heavy conductive impurity as a conductive impurity and further contains diffusion suppression type. This achieves an effect of suppressing diffusion. This makes it possible to suppress dark current in the pixel region R1 while suppressing performance degradation of the first peripheral transistor 27 caused by heat treatment.

In the examples of FIGS. 25 to 32, the pixel region R1, the first peripheral region R2, and the second peripheral region R3 may have the features described with reference to FIGS. 1 to 24. For example, the pixel region R1 may include an address transistor 24, a reset transistor 26, and the like, in addition to the amplifier transistor 22. The first peripheral region R2 may include a first peripheral transistor 727, in addition to the first peripheral transistor 27. The second peripheral region R3 may include a second peripheral transistor 827, in addition to the second peripheral transistor 427.

Other embodiments will be described below. Hereinafter, elements common to the embodiment already described and the embodiment to be subsequently described are denoted by the same reference numerals, and description thereof may be omitted. The descriptions of the respective embodiments can be applied to each other as long as they are not technically inconsistent. The respective embodiments may be combined with each other as long as they are not technically inconsistent.

### Embodiment 2

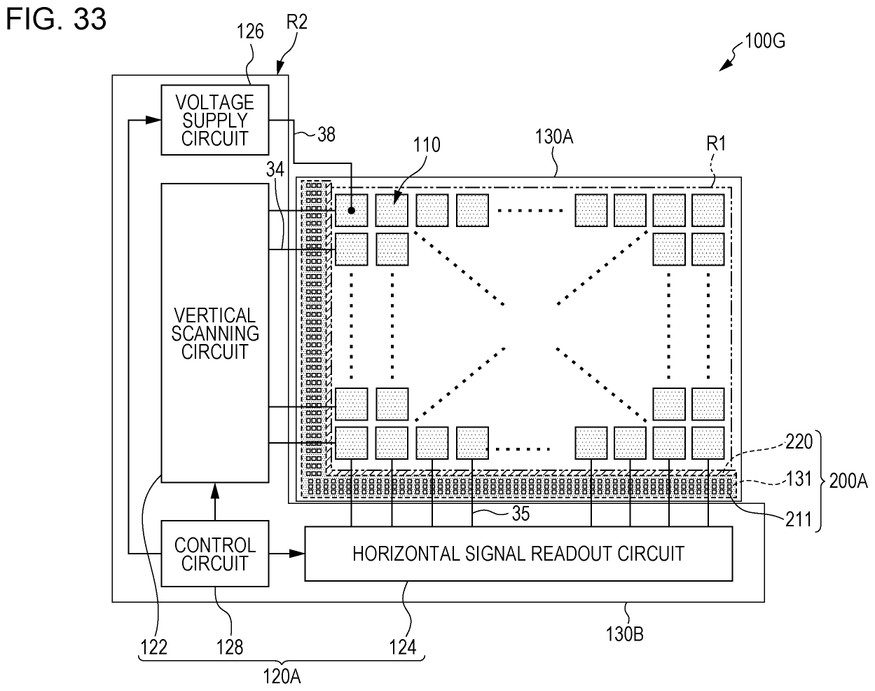

Embodiment 2 of the present disclosure will be described below with reference to FIGS. 33 to 56B. In Embodiment 2, the semiconductor substrate 130 is described as a semiconductor substrate 130A. The support substrate 140 is described as a support substrate 140A.

FIG. 33 schematically illustrates an exemplary configuration of an imaging device 100G according to Embodiment 2 of the present disclosure. A plurality of pixels 110 each include a photoelectric converter 10 as a photoelectric conversion structure and a readout circuit. The photoelectric converter 10 is supported by the semiconductor substrate 130A. The readout circuit is formed on the semiconductor substrate 130A and electrically connected to the photoelectric converter 10.

In the example illustrated in FIG. 33, a peripheral circuit 120A includes a vertical scanning circuit 122, a horizontal signal readout circuit 124, a voltage supply circuit 126, and a control circuit 128. In Embodiment 2, some or all of these circuits are formed on the semiconductor substrate 130B. As schematically illustrated in FIG. 33, the peripheral circuit 120A is positioned in a first peripheral region R2 provided on the semiconductor substrate 130B.

For convenience of explanation, FIG. 33 illustrates both the semiconductor substrates 130A and 130B. In practice, the semiconductor substrates 130A and 130B are stacked on each other. Specifically, the semiconductor substrates 130A and 130B are stacked with an interlayer insulating layer 90B interposed therebetween.

The imaging device 100G further includes a blocking region 200A provided outside the pixel region R1 in a plan view.

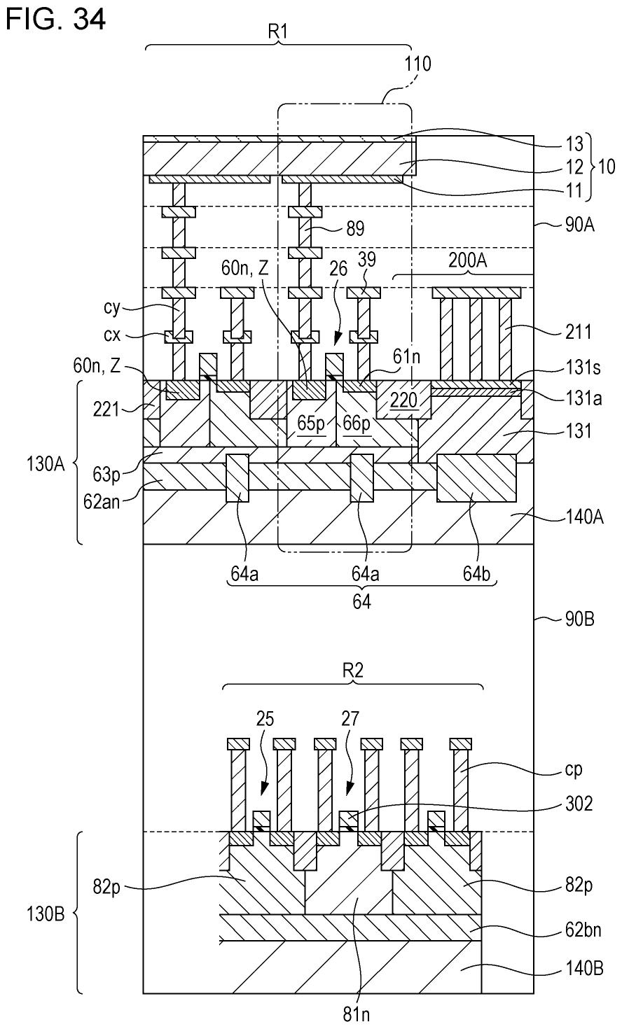

FIG. 34 is a schematic sectional view illustrating the pixel region R1, the first peripheral region R2, and the blocking region. FIG. 34 illustrates cross sections of two pixels as representatives of the plurality of pixels 110. The semiconductor substrates 130A and 130B are stacked on each other. Specifically, the semiconductor substrates 130A and 130B are stacked with the interlayer insulating layer 90B interposed therebetween.

The semiconductor substrate 130B may have features similar to those of the semiconductor substrate 130A. The same applies to a semiconductor substrate 130C to be described later.

The semiconductor substrate 130B has a support substrate 140B. The support substrate 140B may have features similar to those of the support substrate 140A. As with the support substrate 140A, for example, impurity layers and impurity regions positioned above the support substrate 140B may be typically formed by ion implantation of impurities into a film body obtained by epitaxial growth on the support substrate 140B. The same applies to a support substrate of the semiconductor substrate 130C. Hereinafter, a p-type silicon substrate is described as an example of the support substrate 140B.

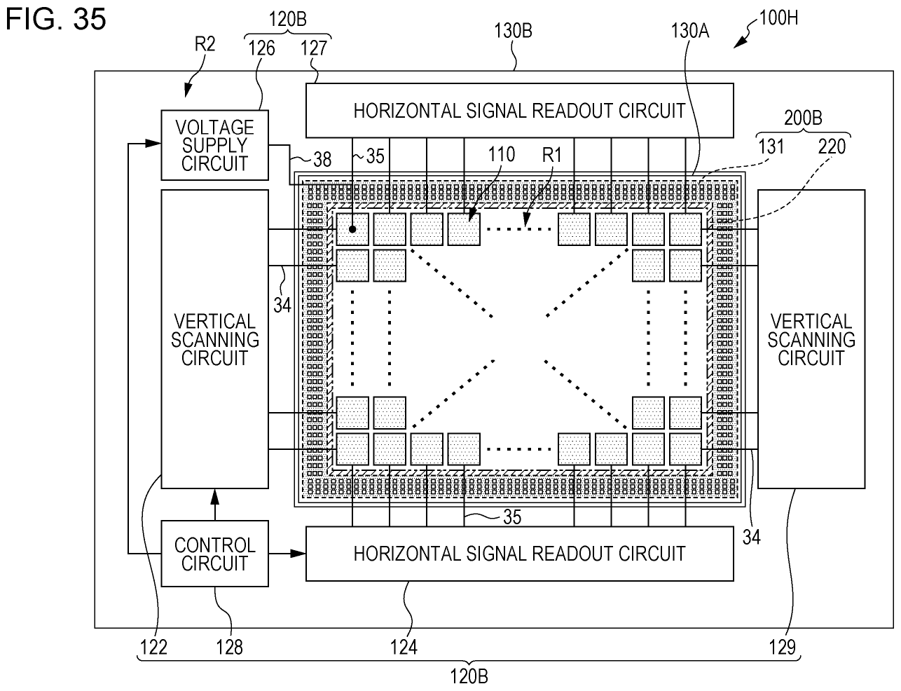

FIG. 35 illustrates another example of the shape of the blocking region. Compared to the imaging device 100G illustrated in FIG. 33, an imaging device 100H illustrated in FIG. 35 has a blocking region 200B that surrounds a pixel region R1 in a rectangular shape, instead of the blocking region 200A. Compared to the blocking region 200A described above, an impurity region 131 in the blocking region 200B surrounds the pixel region R1 in a seamless loop in a plan view. In this example, again, a plurality of contact plugs 211 are connected to the impurity region 131, as schematically illustrated in FIG. 35. In this example, an element isolation 220 in the blocking region 200B also surrounds the pixel region R1 in a seamless loop inside the impurity region 131. As in FIG. 33, FIG. 35 illustrates both semiconductor substrates 130A and 130B for convenience of explanation. In practice, the semiconductor substrate 130A and the semiconductor substrate 130B are stacked on each other. Specifically, the semiconductor substrates 130A and 130B are stacked with an interlayer insulating layer 90B interposed therebetween.

The blocking region 200B is formed in the semiconductor substrate 130A so as to have a shape surrounding the pixel region R1 including the plurality of arrays of pixels 110 in a plan view. This makes it possible to more effectively suppress the movement of charges between the charge storage regions of the pixels and the outside of the pixel region R1. It is not essential in the embodiment of the present disclosure that the blocking region surrounds the pixel region R1 in a seamless loop in a plan view. For example, the blocking region may include a plurality of portions each including the element isolation 220 and the impurity region 131 and arranged to surround the pixel region R1 as a whole. Such a configuration can also expect the same effect as in the case of providing a blocking region so as to surround the pixel region R1 in a seamless loop in a plan view. The blocking region 200B may be omitted.

### Transistors in Pixel Region and Peripheral Region

The transistors in the pixel region and the transistors in the peripheral region will be further described below with reference to FIGS. 36 to 43. FIGS. 36, 37, 38, 39, 40, 41, 42, and 43 are schematic perspective views illustrating transistors in the pixel region and peripheral region. FIGS. 36 to 43 omit illustration of the blocking regions 200A and 200B.

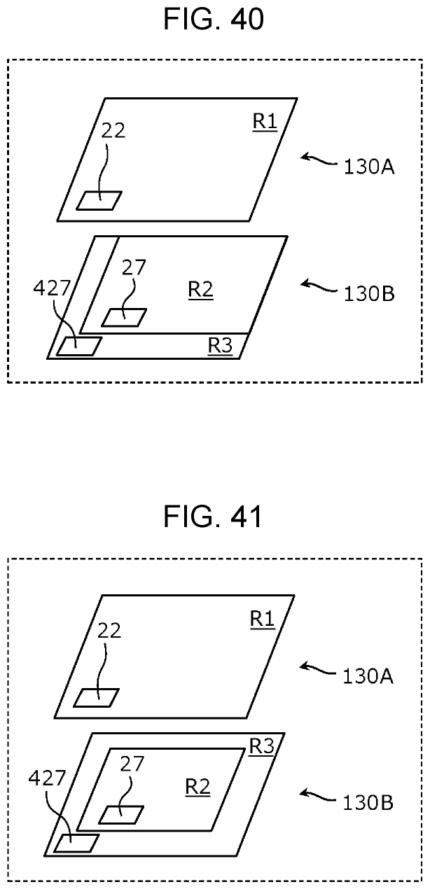

As illustrated in FIGS. 40 and 41, the imaging device may include a second peripheral region R3.

The pixel region R1 may be formed using one semiconductor substrate, and the first peripheral region R2 may be formed using another semiconductor substrate. The pixel region R1 may be formed using one semiconductor substrate, the first peripheral region R2 may be formed using another semiconductor substrate, and the second peripheral region R3 may be formed using yet another semiconductor substrate. The pixel region R1 may be formed using one semiconductor substrate, and the first peripheral region R2 and the second peripheral region R3 may be formed using another semiconductor substrate. The pixel region R1 and the second peripheral region R3 may be formed using one semiconductor substrate, and the first peripheral region R2 may be formed using another semiconductor substrate. In this embodiment, the imaging device may thus have a plurality of semiconductor substrates.

Hereinafter, the terms “pixel substrate portion”, “first peripheral substrate portion”, and “second peripheral substrate portion” may be used. The pixel substrate portion refers to a portion of a plurality of semiconductor substrates, which is included in the pixel region R1. The first peripheral substrate portion refers to a portion of the plurality of semiconductor substrates, which is included in the first peripheral region R2. The second peripheral substrate portion refers to a portion of the plurality of semiconductor substrates, which is included in the second peripheral region R3.

The pixel substrate portion may be included in one semiconductor substrate, the first peripheral substrate portion may be included in another semiconductor substrate, and the second peripheral substrate portion may be included in yet another semiconductor substrate. The pixel substrate portion may be included in one semiconductor substrate, and the first peripheral substrate portion and the second peripheral substrate portion may be included in another semiconductor substrate. The pixel substrate portion and the second peripheral substrate portion may be included in one semiconductor substrate, and the first peripheral substrate portion may be included in another semiconductor substrate.

In the examples of FIGS. 36 and 37, the first peripheral region R2 and the pixel region R1 are stacked on each other. The pixel region R1 is formed using a semiconductor substrate 130A. The first peripheral region R2 is formed using a semiconductor substrate 130B.

FIG. 36 schematically illustrates the amplifier transistor 22 in the pixel region R1 and the first peripheral transistor 27 in the first peripheral region R2 when the first peripheral region R2 has a rectangular shape in a plan view. FIG. 37 schematically illustrates the amplifier transistor 22 in the pixel region R1 and the first peripheral transistor 27 in the first peripheral region R2 when the first peripheral region R2 has a frame shape in a plan view. Specifically, in FIG. 37, the first peripheral region R2 has a square shape in a plan view. The first peripheral region R2 may have an L-shape or U-shape in a plan view.

As can be understood from the description with reference to FIGS. 33 to 37, the imaging device according to this embodiment includes the pixel region R1 and the first peripheral region R2. The pixel region R1 has the pixel substrate portion. The first peripheral region R2 has the first peripheral substrate portion. The pixel substrate portion and the first peripheral substrate portion are stacked on each other. The expression “the pixel substrate portion and the first peripheral substrate portion are stacked on each other” is intended to encompass both a configuration in which there is an element interposed between the pixel substrate portion and the first peripheral substrate portion and a configuration in which there is no element interposed between the pixel substrate portion and the first peripheral substrate portion. Typically, the pixel substrate portion and the first peripheral substrate portion are stacked with an insulating portion interposed therebetween. The insulating portion may correspond to the interlayer insulating layer 90B in FIG. 34.

An example of a situation where the technique using the first specific layer can contribute to the above performance improvement in Embodiment 2 will be described below.

In the imaging device according to this embodiment, the pixel substrate portion of the pixel region R1 and the first peripheral substrate portion of the first peripheral region R2 are stacked on each other. During the manufacturing process of such an imaging device, the first peripheral region R2 may be heated for the following reasons. First, the first peripheral region R2 may be heated by the heat supplied to form the first peripheral region R2. Second, when the first peripheral region R2 and the pixel region R1 are separately formed and then joined together, the first peripheral region R2 may be heated by heating for joining. Third, when heat treatment of the pixel region R1 is performed after forming a laminate structure including the first peripheral region R2 and the pixel region R1, the heat treatment may heat the first peripheral region R2. When the first peripheral transistor 27 in the first peripheral region R2 is heated, conductive impurities may diffuse. Such diffusion of conductive impurities may degrade the performance of the first peripheral transistor 27. The performance degradation of the first peripheral transistor 27 may degrade the performance of the imaging device as a whole. In one example of this embodiment, the first specific layer contains a heavy conductive impurity. With the large mass number of the heavy conductive impurity, the heavy conductive impurity hardly diffuses, making it unlikely for the as-implanted concentration profile immediately after implantation to be significantly changed by diffusion. The first specific layer includes a diffusion suppression type. The diffusion suppression type can contribute to suppressing the diffusion of conductive impurities. Both the diffusion suppressing effect achieved by the conductive impurity being the heavy conductive impurity and the diffusion suppressing effect achieved by the diffusion suppression type can suppress the performance degradation of the first peripheral transistor 27.

The heat treatment mentioned as the third reason why the first peripheral region R2 can be heated will be further described. The heat treatment can reduce defects in the pixel substrate portion in the pixel region R1. Reducing defects can suppress dark current in the imaging device. In the first peripheral region R2, on the other hand, the necessity of reducing defects is not necessarily high. It may be rather necessary in the first peripheral region R2 to prevent performance degradation of the first peripheral transistor 27 due to diffusion of conductive impurities caused by heat treatment. Such performance degradation is, for example, an unwanted change in threshold voltage of the first peripheral transistor 27.

In one example, the pixel region R1 has a photoelectric conversion layer 12. The photoelectric conversion layer 12, the pixel substrate portion, and the first peripheral substrate portion are stacked on each other. In a typical example, when fabricating the pixel region R1 having such a configuration, heat treatment as described above is performed. For this reason, the imaging device including the pixel region R1 having this configuration can achieve the above effect of suppressing dark current while preventing performance degradation of the first peripheral transistor 27.

In one example, the method for manufacturing an imaging device includes a third step and a fourth step in this order. In the third step, a laminate structure including a pixel substrate portion and a first peripheral substrate portion is fabricated. In the fourth step, the pixel substrate portion in the laminate structure is heated. In such a manufacturing method, the first peripheral substrate portion can also be heated by heating the pixel substrate portion. In this case, the above effect of suppressing the dark current while preventing performance degradation of the first peripheral transistor 27 can be achieved. In one specific example, heat treatment is performed in the fourth step to recover various crystal defects and defect levels in the pixel substrate portion, particularly in the vicinity of the charge storage portion. The first peripheral substrate portion can also be heated by such heating of the pixel substrate portion. Other manufacturing methods can also be used to manufacture the imaging device.

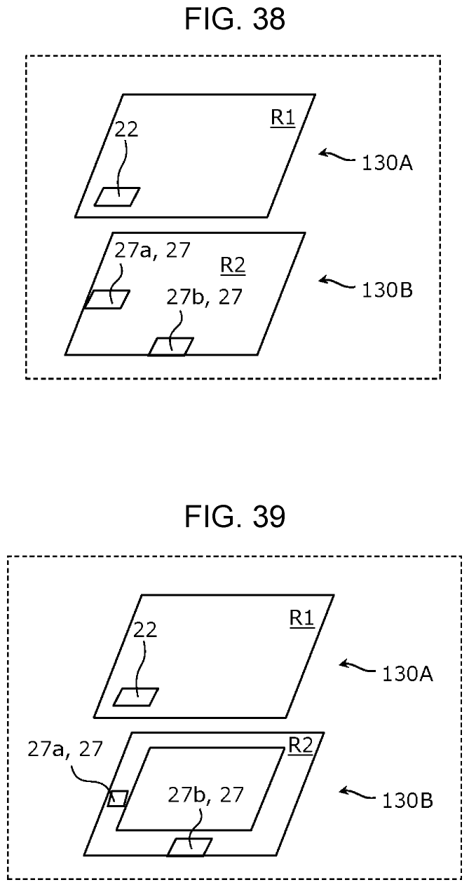

In the examples of FIGS. 38 and 39, the number of first peripheral transistors 27 in the first peripheral region R2 is more than one. The first peripheral region R2 and the pixel region R1 are stacked on each other. The pixel region R1 is formed using the semiconductor substrate 130A. The first peripheral region R2 is formed using the semiconductor substrate 130B.

FIG. 38 schematically illustrates the amplifier transistor 22 in the pixel region R1 and the plurality of first peripheral transistors 27 in the first peripheral region R2 when the first peripheral region R2 has a rectangular shape in a plan view. FIG. 39 schematically illustrates the amplifier transistor 22 in the pixel region R1 and the plurality of first peripheral transistors 27 in the first peripheral region R2 when the first peripheral region R2 has a frame shape in a plan view. Specifically, in FIG. 39, the first peripheral region R2 has a square shape in a plan view. The first peripheral region R2 may have an L-shape or U-shape in a plan view.

In the examples of FIGS. 38 and 39, the plurality of first peripheral transistors 27 are provided in the first peripheral region R2. The plurality of first peripheral transistors 27 include the first direction transistor 27 and the second direction transistor 27b.

As illustrated in FIGS. 40 and 41, the imaging device may include a second peripheral region R3. The second peripheral region R3 has a second peripheral transistor 427.

In the examples of FIGS. 40 and 41, the first peripheral region R2 and the pixel region R1 are stacked on each other. The second peripheral region R3 and the pixel region R1 are stacked on each other. The pixel region R1 is formed using the semiconductor substrate 130A. The first peripheral region R2 and the second peripheral region R3 are formed using the semiconductor substrate 130B. In a plan view, the second peripheral region R3 is positioned outside the first peripheral region R2. In the example of FIG. 40, the second peripheral region R3 has an L-shape in a plan view. In the example of FIG. 41, the second peripheral region R3 has a frame shape and surrounds the first peripheral region R2 in a plan view. Specifically, in FIG. 41, the second peripheral region R3 has a square shape in a plan view. The second peripheral region R3 may have a U-shape.

As can be understood from the above description, the imaging device according to the examples of FIGS. 40 and 41 includes the second peripheral region R3. The second peripheral region R3 has a second peripheral substrate portion and a second peripheral transistor 427. The second peripheral transistor 427 is provided in the second peripheral substrate portion. The first peripheral substrate portion and the second peripheral substrate portion are included in the semiconductor substrate 130B. In the examples of FIGS. 40 and 41, the second peripheral region R3 is positioned outside the first peripheral region R2 in a plan view.

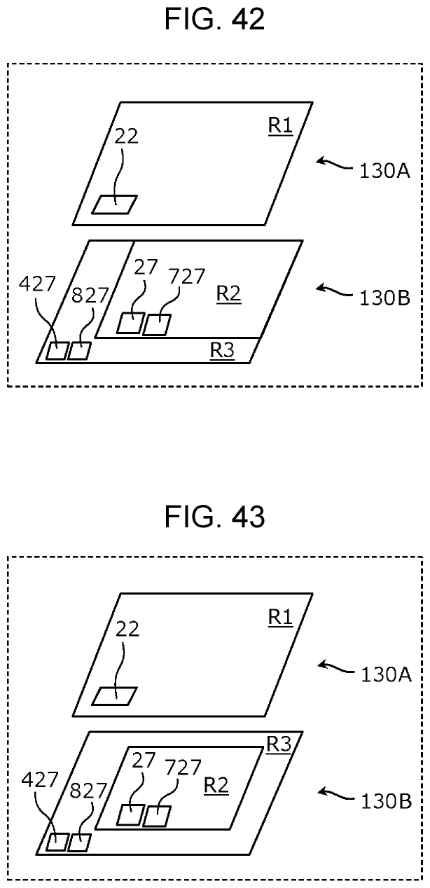

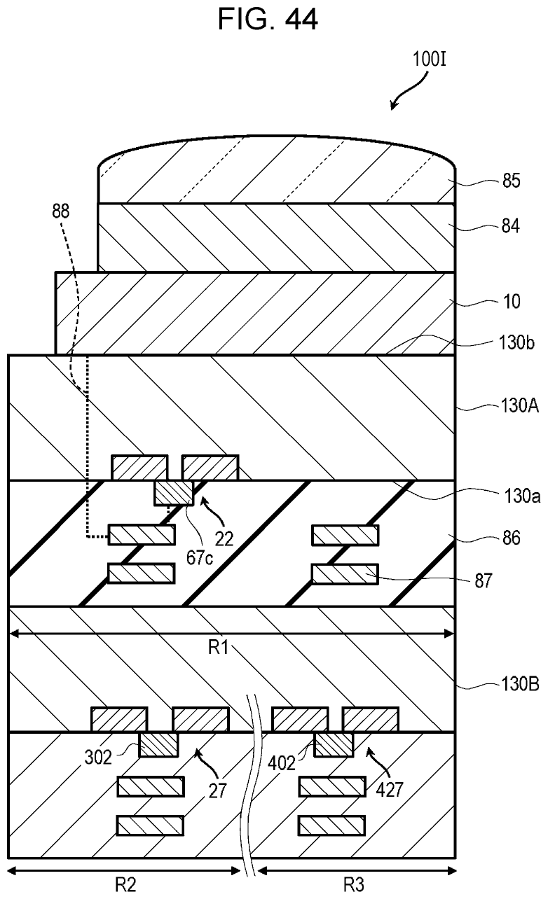

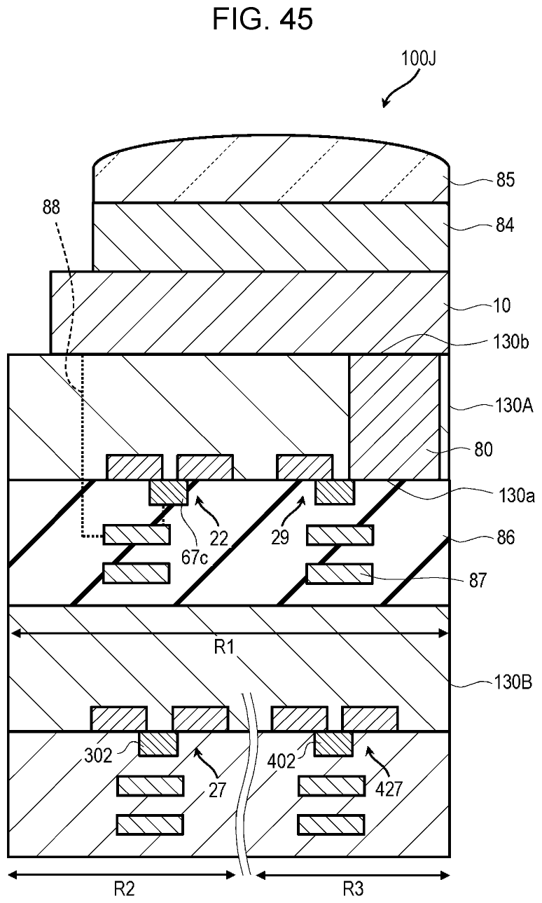

As a matter of course, transistors other than the transistors illustrated in FIGS. 40 and 41 may be provided. In examples illustrated in FIGS. 42 and 43, the first peripheral region R2 has a first peripheral transistor 27 and a first peripheral transistor 727. An element isolation 222 is provided between the first peripheral transistor 27 and the first peripheral transistor 727. The second peripheral region R3 has a second peripheral transistor 427 and a second peripheral transistor 827.

In a plan view, the second peripheral region R3 is positioned outside the first peripheral region R2. In the example of FIG. 42, the second peripheral region R3 has an L-shape in a plan view. In the example of FIG. 43, the second peripheral region R3 has a frame shape and surrounds the first peripheral region R2 in a plan view. Specifically, in FIG. 43, the second peripheral region R3 has a square shape in a plan view. The second peripheral region R3 may have a U-shape.

An element isolation 222 is provided between the second peripheral transistor 427 and the second peripheral transistor 827.

The items described with reference to FIGS. 42 and 43 can also be applied to the examples of FIGS. 36 to 39, unless there is any inconsistency.

The above description has been given of a front side illumination imaging device as an example. However, the above description can also be applied to a back side illumination imaging device.

FIG. 44 is a schematic diagram of a back side illumination imaging device 100I according to an example.

In the imaging device 100I illustrated in FIG. 44, a semiconductor substrate 130A has a front surface 130a and a back surface 130b. The back surface 130b is the surface on which light is made incident. The front surface 130a is the surface opposite to the light incident side.

A photoelectric converter 10, a color filter 84, and an on-chip lens 85 are stacked in this order on the back surface 130b. In a typical example, the semiconductor substrate 130A and the photoelectric converter 10 are joined by bonding the photoelectric converter 10 to the polished back surface 130b. The color filter 84 and on-chip lens 85 may be omitted. At least one of between the photoelectric converter 10 and the color filter 84 or between the color filter 84 and the on-chip lens 85, an interlayer insulating film may be provided for the purpose of planarization, protection, and the like.

A wiring layer 86 is laminated on the front surface 130a. In the wiring layer 86, a plurality of wires 87 are provided in insulators. The plurality of wires 87 are used to electrically connect an amplifier transistor 22, a first peripheral transistor 27, and a second peripheral transistor 427 to their connection destinations. For example, the wire 87 constitutes part of an electric path 88 that electrically connects a pixel electrode 11 of the photoelectric converter 10 to a gate electrode 67c of the amplifier transistor 22. Specifically, in this example, the electric path 88 includes a through-silicon via (TSV) provided in the semiconductor substrate 130A. FIG. 44 omits the illustration of the through-silicon via. In FIG. 44, the dotted lines representing the electric path 88 are schematic and are not intended to limit the position of the electric path 88 and the like. Cu—Cu connection may be employed instead of the TSV connection.

Although not illustrated in detail in FIG. 44, the amplifier transistor 22, the first peripheral transistor 27, and the second peripheral transistor 427 may have the features described above. The same applies to other elements such as the photoelectric converter 10. Specifically, in this example, the first peripheral transistor 27 and the second peripheral transistor 427 each include a source, a drain, an extension diffusion layer, a pocket diffusion layer, and the like. The semiconductor substrate 130A includes a support substrate 140A. The semiconductor substrate 130B includes a support substrate 140B.

FIG. 45 is a schematic diagram of a back side illumination imaging device 100J according to another example. In the example of FIG. 45, the pixel substrate portion for the pixel region R1 includes a photodiode 80.

The imaging device 100J illustrated in FIG. 45 includes the elements of the imaging device 100I illustrated in FIG. 44. The imaging device 100J further includes a photodiode 80 and a transfer transistor 29. The photodiode 80 and the transfer transistor 29 are provided in the semiconductor substrate 130A.

The photodiode 80 corresponds to a photoelectric converter, as with the photoelectric converter 10. The photodiode 80 generates signal charges by photoelectric conversion. The transfer transistor 29 transfers this signal charge to a charge storage region (not illustrated).

According to the back side illumination configuration illustrated in FIG. 45, the wires 87 in the wiring layer 86 do not block irradiation of the photodiode 80 with light from the on-chip lens 85 and the color filter 84 side. This enables efficient photoelectric conversion by the photodiode 80.

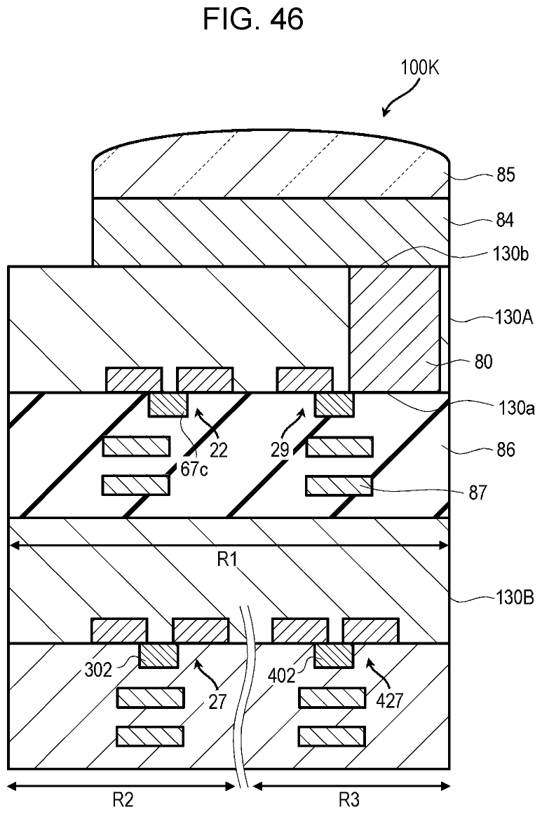

FIG. 46 is a schematic diagram of a back side illumination imaging device 100K according to another example.

The imaging device 100K illustrated in FIG. 46 includes some of the elements of the imaging device 100J illustrated in FIG. 45. The imaging device 100K illustrated in FIG. 46 includes no photoelectric converter 10.

FIGS. 47 to 50 are schematic diagrams illustrating possible shapes of the pixel region R1, the first peripheral region R2, and the second peripheral region R3 in the imaging device 100K illustrated in FIG. 46.

In the example of FIG. 47, the second peripheral region R3 surrounds the first peripheral region R2 in a plan view. Specifically, the second peripheral region R3 has a square shape outside the first peripheral region R2 in a plan view.

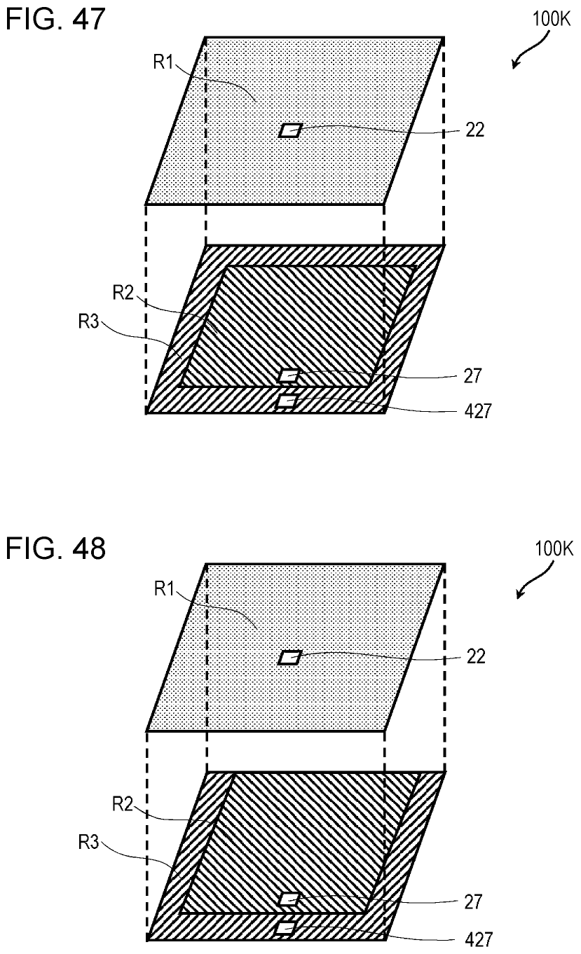

In the example of FIG. 48, the second peripheral region R3 has a U-shape outside the first peripheral region R2 in a plan view.

In the example of FIG. 49, the second peripheral region R3 has an L-shape outside the first peripheral region R2 in a plan view.

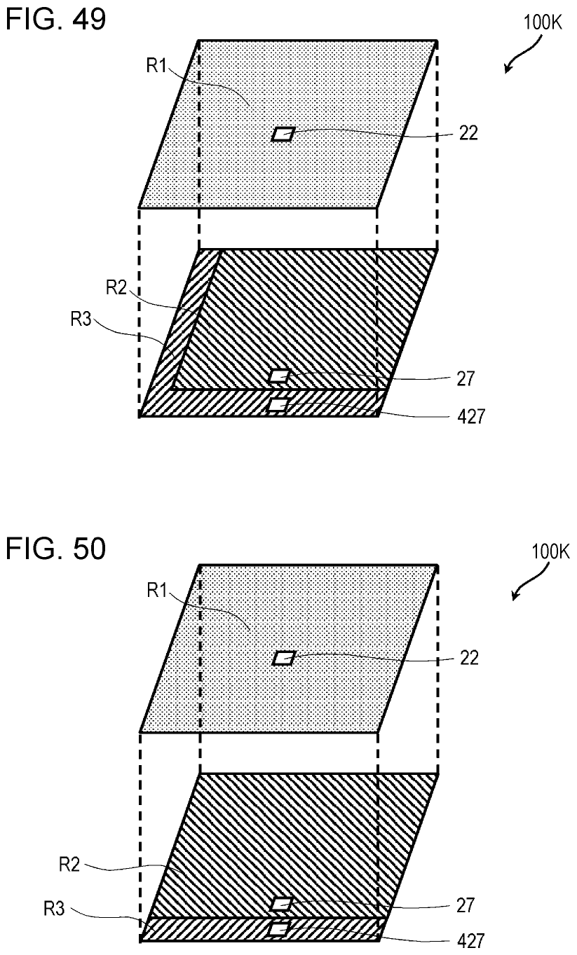

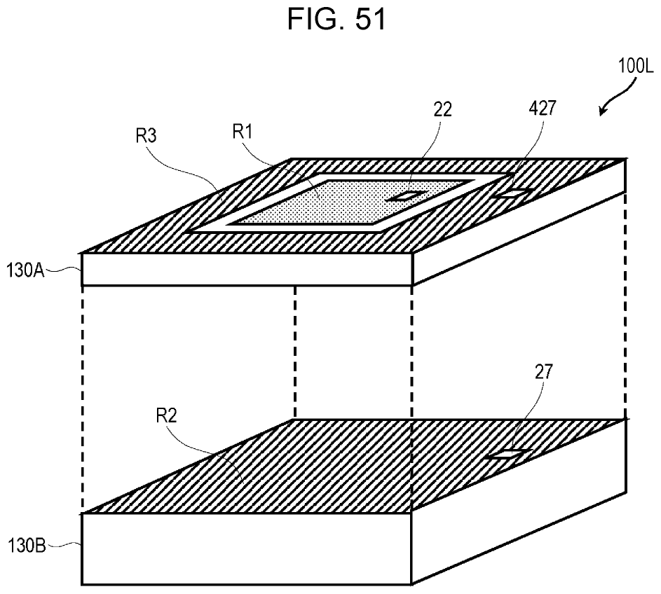

In the example of FIG. 50, the second peripheral region R3 extends straight outside the first peripheral region R2 in a plan view.

The shapes of the pixel region R1, first peripheral region R2, and second peripheral region R3 illustrated in FIGS. 47 to 50 are also applicable to the imaging devices 1001 and 100J illustrated in FIGS. 44 and 45. These shapes are also applicable to the imaging devices 100G and 100H illustrated in FIGS. 33 to 43.

As illustrated in FIG. 34 and the like, the imaging device can be a front side illumination imaging device. In an example of the front side illumination imaging device, the pixel substrate portion of the pixel region R1 is disposed above the first peripheral substrate portion of the first peripheral region R2. The gate electrode 302 of the first peripheral transistor 27 is positioned above the first peripheral substrate portion. The imaging device having such a configuration can be manufactured by a manufacturing method in which a laminate structure including a pixel substrate portion and a first peripheral substrate portion is fabricated and then the pixel substrate portion in the laminate structure is heated. This manufacturing method makes it easier to achieve the advantage that redistribution of conductive impurities is suppressed by the diffusion suppressing effect that emerges in the first peripheral region R2.

As illustrated in FIGS. 44 to 50 and the like, the imaging device can be a back side illumination imaging device. In an example of the back side illumination imaging device, the pixel substrate portion of the pixel region R1 is disposed above the first peripheral substrate portion of the first peripheral region R2. The gate electrode 302 of the first peripheral transistor 27 is positioned below the first peripheral substrate portion. The imaging device having such a configuration can be manufactured by a manufacturing method in which a laminate structure including a pixel substrate portion and a first peripheral substrate portion is fabricated and then the pixel substrate portion in the laminate structure is heated. This manufacturing method makes it easier to achieve the advantage that redistribution of conductive impurities is suppressed by the diffusion suppressing effect that emerges in the first peripheral region R2.

In one configuration example, the pixel region R1 has a contact plug ex. The contact plug cx is connected to the charge storage region Z. The contact plug cx and the charge storage region Z contain a predetermined impurity as a conductive impurity. The predetermined impurity is phosphorus, for example. Such a configuration can be obtained by a method for diffusing the predetermined impurity doped in the contact plug cx into the charge storage region Z by heating the pixel substrate portion of the pixel region R1. This heating can also heat the first peripheral substrate portion of the first peripheral region R2. This manufacturing method makes it easier to achieve the advantage that the redistribution of the conductive impurity is suppressed by the diffusion suppressing effect that emerges in the first peripheral region R2. This configuration can be employed in both the front side illumination imaging device and the back side illumination imaging device.

The front side illumination imaging device may have the following configuration. That is, in an example of the front side illumination imaging device, the pixel substrate portion of the pixel region R1 is disposed below the first peripheral substrate portion of the first peripheral region R2. The gate electrode 302 of the first peripheral transistor 27 is positioned above the first peripheral substrate portion. In this configuration, a transistor that can be manufactured by a low-temperature process to be described later can be employed as the first peripheral transistor 27, for example.

The back side illumination imaging device may have the following configuration. That is, in an example of the back side illumination imaging device, the pixel substrate portion of the pixel region R1 is disposed below the first peripheral substrate portion of the first peripheral region R2. The gate electrode 302 of the first peripheral transistor 27 is positioned below the first peripheral substrate portion. In this configuration, a transistor that can be manufactured by a low-temperature process to be described later can be employed as the first peripheral transistor 27, for example.

A configuration of FIG. 51 can also be adopted. In an imaging device 100L illustrated in FIG. 51, a semiconductor substrate 130A and a semiconductor substrate 130B are stacked on each other. A pixel region R1 and a second peripheral region R3 are provided using the semiconductor substrate 130A. A first peripheral region R2 is provided using the semiconductor substrate 130B.

Although not illustrated, at least one of TSV connection or Cu—Cu connection can be used for electrical connection between the elements provided on the semiconductor substrate 130A and the elements provided on the semiconductor substrate 130B.

The pixel region R1 has an amplifier transistor 22. The first peripheral region R2 has a first peripheral transistor 27. The second peripheral region R3 has a second peripheral transistor 427.

A pixel substrate portion of the pixel region R1 and a second peripheral substrate portion of the second peripheral region R3 are included in the semiconductor substrate 130A. In the example of FIG. 51, the second peripheral region R3 is positioned outside the pixel region R1 in a plan view.

In one example, the second peripheral transistor 427 is a load transistor in the imaging device 100L. The amplifier transistor 22 is connected to the load transistor through a vertical signal line 35.

In one specific example, the load transistor described above functions as a constant current source. A constant current determined by the load transistor flows through the amplifier transistor 22, the vertical signal line 35, and the load transistor in this order. The amplifier transistor 22 and the load transistor form a source follower. Therefore, a voltage corresponding to a gate voltage of the amplifier transistor 22, that is, a voltage of a charge storage region Z appears on the vertical signal line 35. This state continues while the address transistor 24 is on. The load transistor may be included in the load circuit 45 illustrated in FIG. 2.

In the imaging device 100L, the first peripheral transistor 27 may be included in at least one of a comparator or a driver.

In the examples of FIGS. 44 to 51, again, a first specific layer contains a heavy conductive impurity as a conductive impurity and further contains diffusion suppression type. This achieves an effect of suppressing diffusion. This makes it possible to suppress dark current in the pixel region R1 while suppressing performance degradation of the first peripheral transistor 27 caused by heat treatment.

In the examples of FIGS. 44 to 51, the pixel region R1, the first peripheral region R2, and the second peripheral region R3 may have the features described above. For example, the pixel region R1 may include an address transistor 24, a reset transistor 26, and the like, in addition to the amplifier transistor 22. The first peripheral region R2 may include a first peripheral transistor 727, in addition to the first peripheral transistor 27. The second peripheral region R3 may include a second peripheral transistor 827, in addition to the second peripheral transistor 427.

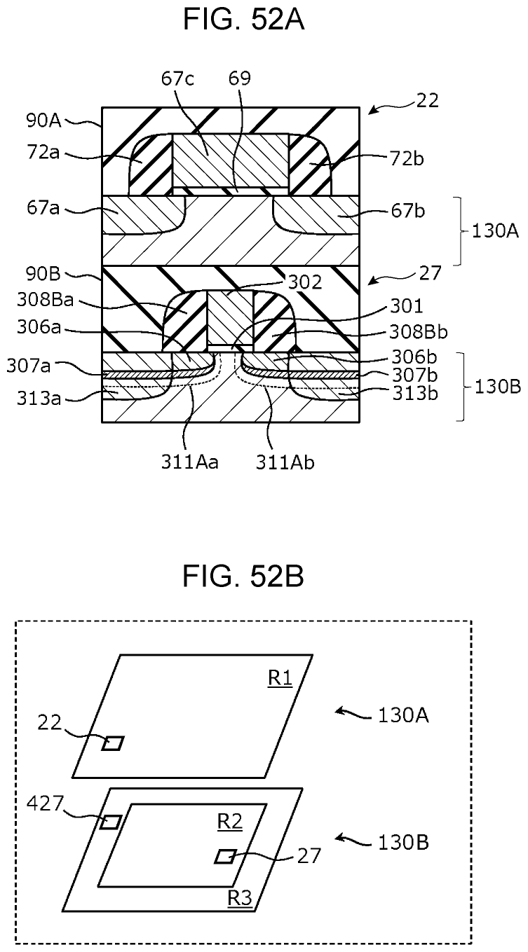

An imaging device according to a specific example of the present disclosure will be described below with reference to FIGS. 52A to 56B. FIGS. 52A to 56B omit illustration of a photoelectric conversion layer 12, a channel region, and the like. In FIGS. 52A, 53A, 54A, 55A, and 56A, solid lines or dotted lines in a semiconductor substrate 130A, 130B or 130C schematically represent boundaries between regions where impurities spread. The dotted line schematically represents the boundary between regions where the diffusion suppression type spreads. In FIGS. 52A, 53A, 54A, 55A, and 56A, the dotted lines are denoted by reference numerals 311Aa or 311Ab representing carbon-implanted layers, for illustrative purposes. An insulating portion may correspond to the interlayer insulating layers 90A to 90C described above.

FIG. 52A is a schematic sectional view of an imaging device according to a first specific example. FIG. 52B is a schematic perspective view of the imaging device according to the first specific example. FIG. 52A omits illustration of a second peripheral transistor 427. In the imaging device according to the first specific example, a pixel region R1 is formed using a first semiconductor substrate 130A. A first peripheral region R2 and a second peripheral region R3 are formed using a second semiconductor substrate 130B. The first peripheral region R2 is surrounded by the second peripheral region R3. In the first specific example, the second semiconductor substrate 130B, an interlayer insulating layer 90B that is the insulating portion, the first semiconductor substrate 130A, an interlayer insulating layer 90A as the insulation portion, and a photoelectric conversion layer 12 are stacked in this order. A pixel signal output section is provided near the periphery of the pixel region R1. This makes it possible to reduce the length of wiring that leads a pixel signal from the pixel region R1 to the second peripheral region R3. This is advantageous from the viewpoint of ensuring a transfer speed.

In a modification of the first specific example (not illustrated), a first semiconductor substrate 130A, an interlayer insulating layer 90A that is an insulating portion, a second semiconductor substrate 130B, an interlayer insulating layer 90B that is the insulating portion, and a photoelectric conversion layer 12 are stacked in this order. In this modification, a transistor that can be manufactured by a low-temperature process can be used as at least one selected from the group consisting of the first peripheral transistor 27 and second peripheral transistor 427. The low-temperature process can suppress the diffusion of conductive impurities compared to a high-temperature process, and thus can contribute to ensuring the performance of peripheral transistors. Examples of the transistor that can be manufactured by the low-temperature process include a silicon transistor, a germanium transistor, a carbon nanotube transistor, a transition metal dichalcogenide (TMD) transistor, an oxide semiconductor transistor, and the like. Examples of oxide semiconductors for the oxide semiconductor transistor include IGZO containing In-Ga—Zn-O, IAZO containing In—Al—Zn—O, ITZO containing In—Sn—Zn—O, and the like. Examples of the TMD transistor include a molybdenum sulfide (MoS₂) transistor, a tungsten sulfide (WS₂) transistor, and the like. When using a silicon transistor, a low-temperature diffusion process such as solid phase epitaxial regrowth (SPER) can also be used, in which an amorphized diffusion layer is regrown in the solid phase at a temperature of about 400° C. to 650° C.

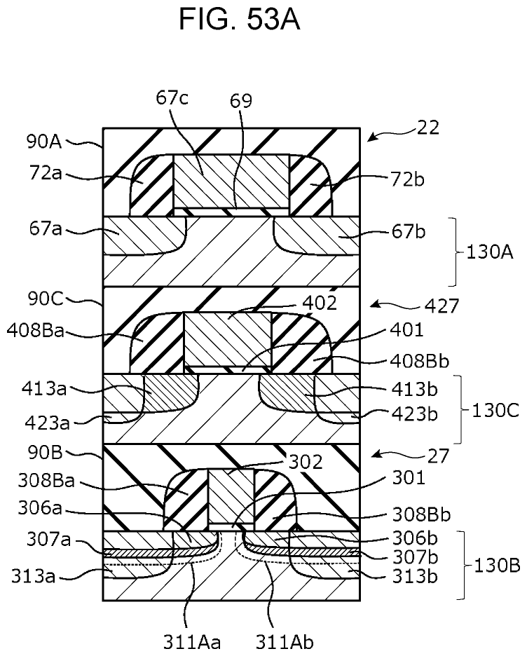

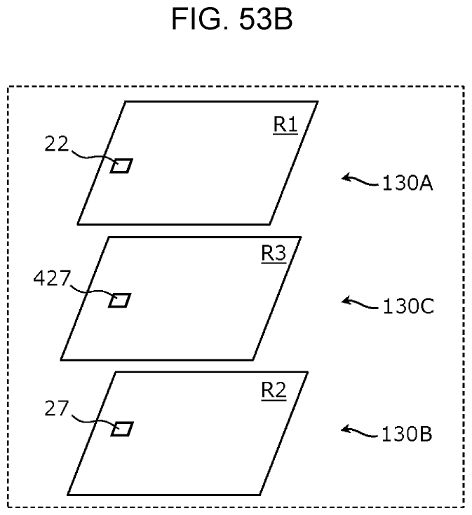

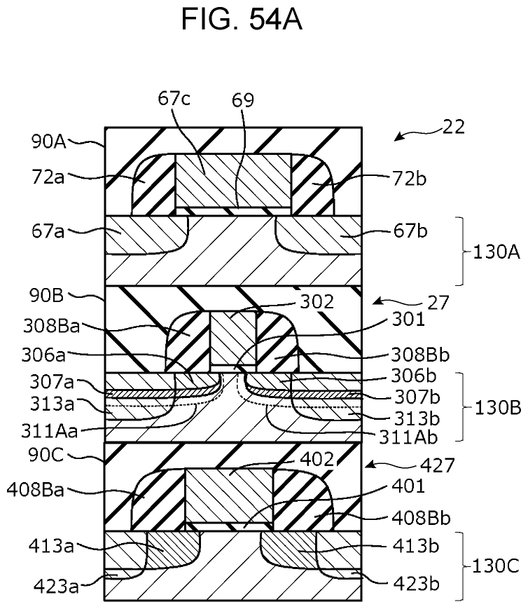

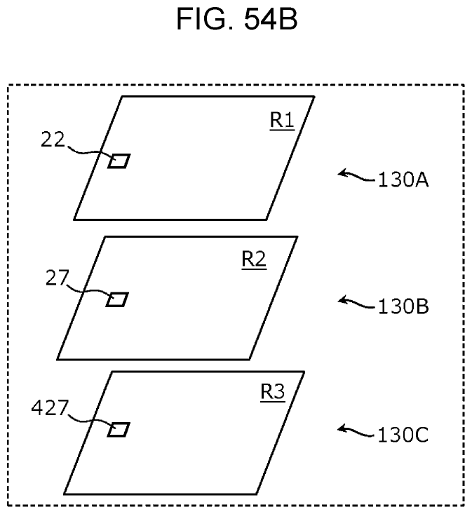

FIG. 53A is a schematic sectional view of an imaging device according to a second specific example. FIG. 53B is a schematic perspective view of the imaging device according to the second specific example. FIG. 54A is a schematic sectional view of an imaging device according to a third specific example. FIG. 54B is a schematic perspective view of the imaging device according to the third specific example. In the imaging devices according to the second and third specific examples, a pixel substrate portion for a pixel region R1, a first peripheral substrate portion for a first peripheral region R2, and a second peripheral substrate portion for a second peripheral region R3 are stacked on each other. In the second and third specific examples, the pixel region R1 is formed using a first semiconductor substrate 130A. The first peripheral region R2 is formed using a second semiconductor substrate 130B. The second peripheral region R3 is formed using a third semiconductor substrate 130C. The pixel substrate portion, the first peripheral substrate portion, and the second peripheral substrate portion are isolated by an insulating film or the like, and are electrically connected through plugs or the like, for example, so that signals can be communicated.

In the second specific example illustrated in FIGS. 53A and 53B, the first peripheral substrate portion for the first peripheral region R2, the second peripheral substrate portion for the second peripheral region R3, and the pixel substrate portion for the pixel region R1 are stacked in this order. The second semiconductor substrate 130B, the third semiconductor substrate 130C, and the first semiconductor substrate 130A are stacked in this order. A second peripheral transistor 427 in the second peripheral region R3 has a gate length longer than that of a first peripheral transistor 27 in the first peripheral region R2. This makes it easier to secure a distance of the first peripheral transistor 27 from the pixel region R1. The first peripheral transistor 27 has a relatively short gate length and is susceptible to noise. Therefore, noise from the first peripheral transistor 27 is less likely to affect the pixel characteristics. The second peripheral transistor 427 having a relatively long gate length is also easily brought closer to the pixel region R1. This makes it easier to secure the transfer speed of the signal charges from the pixel region R1 to the second peripheral transistor 427.

Specifically, in the second specific example, the second semiconductor substrate 130B, an interlayer insulating layer 90B that is an insulating portion, the third semiconductor substrate 130C, an interlayer insulating layer 90C that is the insulating portion, the first semiconductor substrate 130A, an interlayer insulating layer 90A that is the insulating portion, and a photoelectric conversion layer 12 are stacked in this order.

In the third specific example illustrated in FIGS. 54A and 54B, the second peripheral substrate portion for the second peripheral region R3, the first peripheral substrate portion for the first peripheral region R2, and the pixel substrate portion for the pixel region R1 are stacked in this order. The third semiconductor substrate 130C, the second semiconductor substrate 130B, and the first semiconductor substrate 130A are stacked in this order. A first peripheral transistor 27 in the first peripheral region R2 has a first extension diffusion layer with a shallow junction depth. In the first extension diffusion layer with a shallow junction depth, the characteristics of the first peripheral transistor 27 vary easily when the conductive impurities are diffused by heat. In the third specific example, however, the second peripheral region R3, the first peripheral region R2, and the pixel region R1 are stacked in this order. This makes it possible to form the second peripheral region R3, the first peripheral region R2, and the pixel region R1 in this order in the manufacturing process of the imaging device. This can prevent the heat generated when forming the second peripheral region R3 from reaching the first peripheral region R2. This makes it possible to suppress the redistribution of the conductive impurities contained in the first extension diffusion layer, and to prevent variations in characteristics of the first peripheral transistor 27.

Specifically, in the third specific example, the third semiconductor substrate 130C, an interlayer insulating layer 90C that is an insulating portion, the second semiconductor substrate 130B, an interlayer insulating layer 90B that is the insulating portion, the first semiconductor substrate 130A, an interlayer insulating layer 90A that is the insulating portion, and a photoelectric conversion layer 12 are stacked in this order.

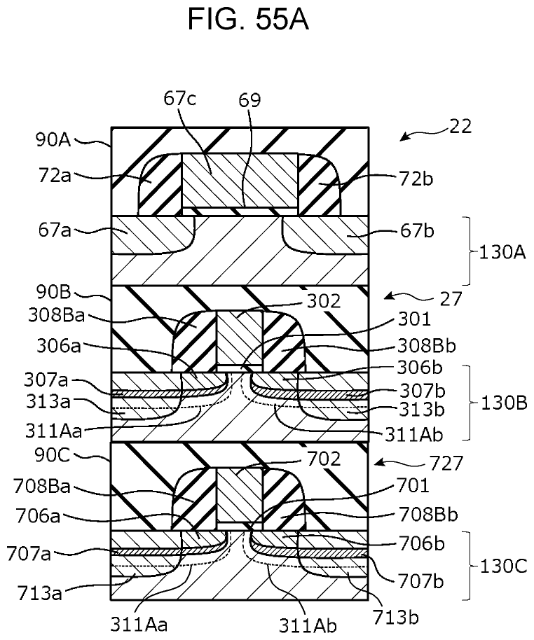

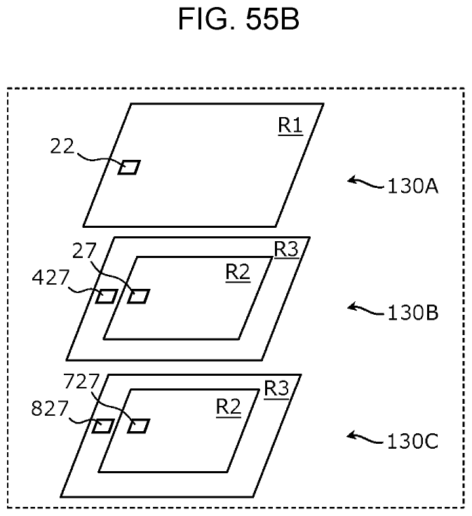

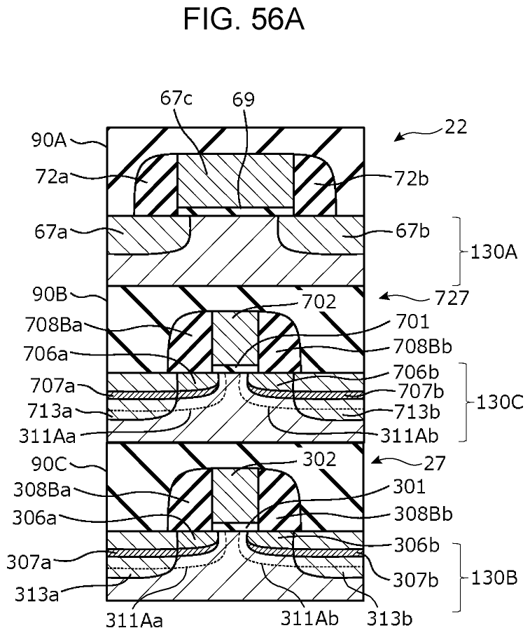

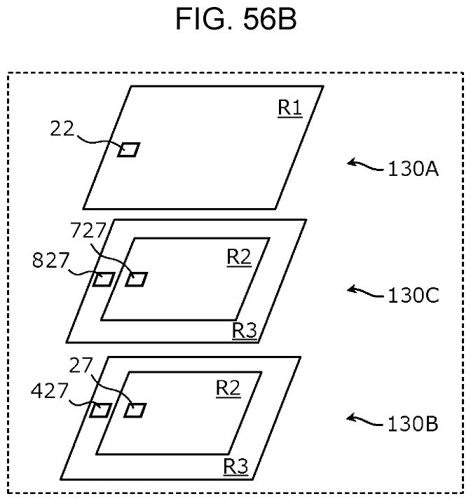

FIG. 55A is a schematic sectional view of an imaging device according to a fourth specific example. FIG. 55B is a schematic perspective view of the imaging device according to the fourth specific example. FIG. 56A is a schematic sectional view of an imaging device according to a fifth specific example. FIG. 56B is a schematic perspective view of the imaging device according to the fifth specific example. In the imaging devices according to the fourth and fifth specific examples, a pixel substrate portion for a pixel region R1 is included in a first semiconductor substrate 130A. A first peripheral substrate portion for a first peripheral region R2 and a second peripheral substrate portion for a second peripheral region R3 each have a portion included in a second semiconductor substrate 130B. A first peripheral transistor 27 and a second peripheral transistor 427, which are N-channel transistors, are provided on the second semiconductor substrate 130B. The first peripheral substrate portion for the first peripheral region R2 and the second peripheral substrate portion for the second peripheral region R3 each have a portion included in a third semiconductor substrate 130C. A first peripheral transistor 727 and a second peripheral transistor 827, which are P-channel transistors, are provided on the third semiconductor substrate 130C. The first semiconductor substrate 130A, the second semiconductor substrate 130B, and the third semiconductor substrate 130C are stacked on each other. Specifically, for both the second semiconductor substrate 130B and the third semiconductor substrate 130C, the second peripheral region R3 is positioned outside the first peripheral region R2 in a plan view. More specifically, for both the second semiconductor substrate 130B and the third semiconductor substrate 130C, the second peripheral region R3 has a frame shape surrounding the first peripheral region R2 in a plan view. As illustrated in FIG. 55B, the imaging device according to the fourth specific example has a portion in which the first peripheral transistor 727 as the P-channel transistor, the first peripheral transistor 27 as the n-channel transistor, and an amplifier transistor 22 are stacked in this order. As illustrated in FIG. 56B, the imaging device according to the fifth specific example has a portion in which the first peripheral transistor 27 as the N-channel transistor, the first peripheral transistor 727 as the p-channel transistor, and an amplifier transistor 22 are stacked in this order. As illustrated in FIGS. 55A and 56A, in the imaging devices according to the fourth and fifth specific examples, first pocket diffusion layers 307a and 307b are provided in the first peripheral transistor 27, and pocket diffusion layers 707a and 707b are provided in the first peripheral transistor 727. It is also possible to omit the pocket diffusion layer by suppressing the short-channel effect of the transistors using a low-temperature process.

In the fourth and fifth specific examples, the N-channel transistor and the P-channel transistor are provided on different semiconductor substrates. This configuration makes it easier to optimize the process steps such as the stacking order of the semiconductor substrates in consideration of a change in thermal stability due to the diffusion of p-type impurities and a change in thermal stability due to the diffusion of n-type impurities. In the fourth and fifth specific examples, the N-channel transistor and the P-channel transistor are provided on stacked different semiconductor substrates, rather than on a single semiconductor substrate extending on the same plane. This configuration makes it easier to reduce the area of a CMOS circuit. For example, this configuration makes it possible to form a CMOS in which an NFET and a PFET are vertically stacked, such as a complementary FET (CFET). This makes it easier to reduce the area of the CMOS circuit. The vertical stacking means stacking along the thickness direction of the semiconductor substrate. It is also possible to provide the first peripheral transistor and the second peripheral transistor on different semiconductor substrates. This makes it much easier to reduce the area.

Specifically, in the fourth and fifth specific examples, the first peripheral transistor 27 is provided in the first peripheral region R2 in the second semiconductor substrate 130B. The second peripheral transistor 427 is provided in the second peripheral region R3 in the second semiconductor substrate 130B. The first peripheral transistor 727 is provided in the first peripheral region R2 in the third semiconductor substrate 130C. The second peripheral transistor 827 is provided in the second peripheral region R3 in the third semiconductor substrate 130C. The first peripheral transistor 27 is an N-channel transistor and its operating voltage is a first voltage. The second peripheral transistor 427 is an N-channel transistor and its operating voltage is a second voltage. The first peripheral transistor 727 is a P-channel transistor and its operating voltage is the first voltage. The second peripheral transistor 827 is a P-channel transistor and its operating voltage is the second voltage. The first voltage is lower than the second voltage. The first voltage is, for example, 1.2 V. The second voltage is, for example, 3.3 V.

The transistors may contain boron (B) as a p-type impurity. The transistors may contain arsenic (As) as an n-type impurity. Boron (B) is more prone to transient enhanced diffusion than arsenic (As). In the fifth specific example illustrated in FIGS. 56A and 56B, the second semiconductor substrate 130B, the third semiconductor substrate 130C, and the first semiconductor substrate 130A are stacked in this order. Therefore, in the fifth specific example, the third semiconductor substrate 130C having the p-type impurity can be formed after the second semiconductor substrate 130B having the n-type impurity are formed. This prevents the heat generated when forming the second semiconductor substrate 130B from reaching the first peripheral transistor 727 and second peripheral transistor 827, which are the P-channel transistors. This configuration is advantageous from the viewpoint of suppressing the transient enhanced diffusion of conductive impurities.

In the fourth specific example illustrated in FIGS. 55A and 55B, on the other hand, the third semiconductor substrate 130C, the second semiconductor substrate 130B, and the first semiconductor substrate 130A are stacked in this order. Adopting this configuration makes it easier to take advantage of the effect of suppressing the transient enhanced diffusion that occur in the first specific layer.

In the first to fifth specific examples, the first specific layer may be provided in both the first peripheral transistor 27 and the second peripheral transistor 427, or may be provided in only one of them. The second specific layer may be provided in both the first peripheral transistor 727 and the second peripheral transistor 827, or may be provided in only one of them. The second specific layer may be provide in neither of the first peripheral transistor 727 and the second peripheral transistor 827.

Various modifications can be applied to the techniques according to the present disclosure. An imaging device according to another specific example has a portion in which an amplifier transistor 22, a first peripheral transistor 27 as an N-channel transistor, and a first peripheral transistor 727 as a p-channel transistor are stacked in this order. For example, the pocket diffusion layers 707a and 707b in the first peripheral transistor 727 and the pocket diffusion layers 807a and 807b in the second peripheral transistor 827 can be omitted. The blocking regions 200A and 200B can also be omitted. A silicide layer may be formed on the drain, source, and gate electrode of the first peripheral transistor 27.

The features of the second peripheral region R3 may be applied to the first peripheral region R2. For example, the features of the second peripheral transistors 427 and 827 may be applied to the first peripheral transistors 27 and 727.

The features of the first peripheral region R2 may be applied to the second peripheral region R3. For example, the features of the first peripheral transistors 27 and 727 may be applied to the second peripheral transistors 427 and 827. As illustrated in FIGS. 53A and 54A, the second peripheral transistors 427 and 827 may have a source 423a and a drain 423b deeper than the LDD outside the sidewall.

The imaging device can also be described as follows. Specifically, the imaging device includes a support substrate, a film body, and a transistor. The film body is provided above the support substrate. The film body has a low-concentration layer and a conductive impurity layer. The low-concentration layer includes the upper surface of the film body. The conductive impurity concentration of the film body is lower than the conductive impurity concentration of the support substrate. The conductive impurity layer is positioned below the low-concentration layer. The conductive impurity layer contains conductive impurities. A transistor includes the low-concentration layer and the conductive impurity layer in this order from top to bottom. The transistor has an impurity concentration profile in a region along a straight line extending in the depth direction of the film body through the low-concentration layer and the conductive impurity layer. In the impurity concentration profile, the concentration of the conductive impurities reaches a peak at a position deeper than the upper surface of the film body.

Specifically, the transistor may be a pixel transistor. The transistor may be a first peripheral transistor. The transistor may be a second peripheral transistor. The conductive impurity layer may be a pixel specific layer. The conductive impurity layer may be a first specific layer. The conductive impurity layer may be a second specific layer. The film body may have a single crystal structure. The conductive impurity layer may have a heavy conductive impurity. In the impurity concentration profile in the region along the straight line extending in the depth direction of the film body through the low-concentration layer and the conductive impurity layer, the concentration of the heavy conductive impurity may reach a peak at a position deeper than the upper surface of the film body. The conductive impurity layer may be a first specific layer, a second specific layer, or a pixel specific layer.

For example, this method for manufacturing an imaging device includes a fifth step and a sixth step. In the fifth step, a film body is formed by epitaxial growth. In the sixth step, a conductive impurity layer is formed by implanting conductive impurities into the film body.

The imaging device according to the present disclosure is useful for image sensors, digital cameras, and the like, for example. The imaging device according to the present disclosure can be used for a medical camera, a robot camera, a security camera, a camera mounted on a vehicle, and the like, for example.

What is claimed is:

1. An imaging device comprising:
a pixel region including a pixel substrate portion and a pixel transistor positioned in the pixel substrate portion; and
a first peripheral region that includes a first peripheral substrate portion and at least one first peripheral transistor positioned in the first peripheral substrate portion, and that communicates a signal with the pixel region, wherein
the at least one first peripheral transistor includes a first specific layer positioned in the first peripheral substrate portion, and
the first specific layer contains a heavy conductive impurity that is a p-type impurity having an atomic number greater than or equal to an atomic number of gallium or that is an n-type impurity having an atomic number greater than or equal to an atomic number of arsenic.

2. The imaging device according to claim 1, wherein
a concentration profile of the heavy conductive impurity in a region along a straight line extending in a depth direction of the first peripheral substrate portion through the first specific layer has a peak at a position deeper than an upper surface of the first peripheral substrate portion.

3. The imaging device according to claim 1, wherein
the first peripheral substrate portion includes
a support substrate and
a film body positioned above the support substrate,
the film body includes
the first specific layer and
a low-concentration layer that is positioned above the first specific layer, that has an upper surface of the film body, and that has a conductive impurity concentration lower than a conductive impurity concentration of the support substrate, and
the at least one first peripheral transistor includes the low-concentration layer and the first specific layer in sequence from top to bottom.

4. The imaging device according to claim 1, wherein
the heavy conductive impurity includes at least one selected from the group consisting of gallium, indium, antimony, and bismuth.

5. The imaging device according to claim 1, wherein
the at least one first peripheral transistor and the pixel transistor each include a gate, and
a gate length of the at least one first peripheral transistor is shorter than a gate length of the pixel transistor.

6. The imaging device according to claim 1, wherein
the pixel transistor includes a pixel gate insulating film,
the at least one first peripheral transistor includes a first peripheral gate insulating film, and
the first peripheral gate insulating film is thinner than the pixel gate insulating film.

7. The imaging device according to claim 1, wherein
the at least one first peripheral transistor includes a gate, a channel region positioned below the gate, a first source, a first drain, a first extension diffusion layer, and a first pocket diffusion layer,
the first extension diffusion layer is adjacent to the first source or the first drain and is shallower than the first source and the first drain,
the first pocket diffusion layer is adjacent to the first source or the first drain, and
at least one selected from the group consisting of the channel region, the first extension diffusion layer, the first pocket diffusion layer, the first source, and the first drain includes the first specific layer.

8. The imaging device according to claim 1, wherein
the first specific layer contains at least one selected from the group consisting of carbon, nitrogen, and fluorine.

9. The imaging device according to claim 1, wherein
the first specific layer contains at least one selected from the group consisting of germanium, silicon, and argon.

10. The imaging device according to claim 1, wherein
the pixel region includes a charge storage region being an impurity region that stores a charge generated by photoelectric conversion,
the pixel transistor includes a gate and a channel region positioned below the gate, and
a concentration of carbon in the first specific layer is higher than a concentration of carbon in the charge storage region or a concentration of carbon in the channel region.

11. The imaging device according to claim 1, wherein
the first specific layer includes an end-of-range defect.

12. The imaging device according to claim 1, wherein
the first specific layer includes a first segregation portion in which the heavy conductive impurity is segregated in a depth direction of the first peripheral substrate portion,
the pixel region includes a charge storage region being an impurity region that stores a charge generated by photoelectric conversion, and
the first segregation portion is shallower than the charge storage region.

13. The imaging device according to claim 1, wherein
the at least one first peripheral transistor includes two first peripheral transistors,
the first peripheral region includes a shallow trench isolation structure,
the shallow trench isolation structure isolates the two first peripheral transistors,
the shallow trench isolation structure has a trench, and
a range in which the heavy conductive impurity is distributed in the first specific layer of at least one of the two first peripheral transistors is a range shallower than a bottom of the trench.

14. The imaging device according to claim 1, wherein
the pixel transistor includes a gate, a channel region positioned below the gate, and a pixel specific layer that is positioned in the pixel substrate portion and that contains the heavy conductive impurity, and
the channel region includes the pixel specific layer.

15. The imaging device according to claim 1, further comprising:
a second peripheral region including a second peripheral substrate portion and a second peripheral transistor positioned in the second peripheral substrate portion, wherein
the signal is communicated between the first peripheral region and the pixel region through the second peripheral region,
the at least one first peripheral transistor includes a first source, a first drain, and a first extension diffusion layer,
the first extension diffusion layer is adjacent to the first source or the first drain and is shallower than the first source and the first drain,
the second peripheral transistor includes a second source, a second drain, and a second extension diffusion layer,
the second extension diffusion layer is adjacent to the second source or the second drain and is shallower than the second source and the second drain,
a concentration of a conductive impurity in the second extension diffusion layer is lower than a concentration of a conductive impurity in the first extension diffusion layer,
the second extension diffusion layer is deeper than the first extension diffusion layer,
the at least one first peripheral transistor, the second peripheral transistor, and the pixel transistor each include a gate,
a gate length of the at least one first peripheral transistor is shorter than a gate length of the second peripheral transistor, and
a gate length of the pixel transistor is longer than the gate length of the second peripheral transistor.

16. The imaging device according to claim 15, wherein
the pixel transistor further includes a channel region positioned below the gate of the pixel transistor,
the second peripheral transistor further includes a second specific layer that is positioned in the second peripheral substrate portion and that contains a conductive impurity,
when at least one type of impurity that suppresses transient enhanced diffusion of the conductive impurity is defined as a diffusion suppression type,
the diffusion suppression type includes at least one selected from the group consisting of carbon, nitrogen, and fluorine,
a concentration of the diffusion suppression type in the first specific layer is higher than a concentration of the diffusion suppression type in the second specific layer, and
a concentration of carbon in the second specific layer is higher than a concentration of carbon in the channel region of the pixel transistor.

17. The imaging device according to claim 15, wherein
the second peripheral transistor further includes a channel region positioned below the gate of the second peripheral transistor, a second pocket diffusion layer, and a second specific layer that is positioned in the second peripheral substrate portion and that contains the heavy conductive impurity,
the second peripheral transistor is an N-channel transistor, and
at least one selected from the group consisting of the channel region, the second extension diffusion layer, the second pocket diffusion layer, the second source, and the second drain of the second peripheral transistor includes the second specific layer.

18. The imaging device according to claim 15, wherein
the at least one first peripheral transistor further includes a first peripheral gate insulating film,
the second peripheral transistor further includes a second peripheral gate insulating film,
the first peripheral gate insulating film is thinner than the second peripheral gate insulating film,
the pixel transistor further includes a pixel gate insulating film, and
the pixel gate insulating film is thicker than the second peripheral gate insulating film.

19. The imaging device according to claim 1, wherein
the first peripheral region is positioned outside the pixel region,
the pixel substrate portion and the first peripheral substrate portion are included in a single semiconductor substrate,
the at least one first peripheral transistor is a load transistor, and
the pixel region is connected to the load transistor through a vertical signal line.

20. The imaging device according to claim 1, wherein
the pixel substrate portion and the first peripheral substrate portion are stacked on each other.

21. A method for manufacturing an imaging device according to claim 1, the method comprising:
forming a film body by epitaxial growth; and
forming the first specific layer by implanting the heavy conductive impurity into the film body.

22. An imaging device comprising:
a support substrate;
a film body positioned above the support substrate; and
a pixel transistor, wherein
the film body includes
a low-concentration layer including an upper surface of the film body and having a conductive impurity concentration lower than a conductive impurity concentration of the support substrate, and
a conductive impurity layer that is positioned below the low-concentration layer and that contains a conductive impurity,
the pixel transistor includes the low-concentration layer and the conductive impurity layer in sequence from top to bottom, and
a concentration profile of the conductive impurity in a region along a straight line extending in a depth direction of the film body through the low-concentration layer and the conductive impurity layer has a peak at a position deeper than the upper surface of the film body.

23. The imaging device according to claim 22, wherein
the conductive impurity layer contains a heavy conductive impurity that is a p-type impurity an atomic number of which is equal to or greater than an atomic number of gallium or that is an n-type impurity an atomic number of which is equal to or greater than an atomic number of arsenic.

24. A method for manufacturing an imaging device according to claim 22, the method comprising:
forming the film body by epitaxial growth; and
forming the conductive impurity layer by implanting the conductive impurity into the film body.
